(19) United States
(12) Patent Application Publication
(10) Pub. No.: US 2012/0063223 A1
(43) Pub. Date: Mar. 15, 2012

(54) Most compact flotox-based combo NVM design without sacrificing EEPROM endurance cycles for 1-die data and code storage

(75) Inventors: Peter Wung Lee, Saratoga, CA (US); Fu-Chang Hsu, San Jose, CA (US)

(73) Assignee: Aplus Flash Technology, Inc.

(21) Appl. No.: 13/199,785

(22) Filed: Sep. 9, 2011

Related U.S. Application Data
(60) Provisional application No. 61/403,187, filed on Sep. 9, 2010.

(51) Int. Cl. G11C 16/10; G11C 16/04

(52) U.S. Cl. 365/185.02; 365/185.29; 365/185.05; 365/185.18

(57) ABSTRACT

Disclosed is a low-cost hybrid storage solution that allows Code like sector-alterable NOR and Data like block-alterable NAND and byte-alterable EEPROM being integrated on a same die. The disclosed combo NVM design of the present invention is a truly Data-oriented NVM design that allows 2T-EEPROM to integrate both 0.5T-NAND and 1T-NOR without sacrificing any EEPROM's byte-write performance in the same die. The invention provides several new embodiment sets of preferable bias conditions of Program, Program-Inhibit, Erase and Erase-Inhibit for operating bit-write, byte-write, sector-write and page-write for several preferable Flotox-based EEPROM, NOR and NAND or combo NVM arrays that include types of shared SL, 8-pair BLs and SLS, with or without GBL, normally Erased Vt and Programmed Vt, or the reversed Erased-Vt or Programmed-Vt, etc. Further disclosed is a flexible X-decoder design to allow the flexible selection of pages to be erased to save erase time. Also disclosed is using on-chip negative voltage for FT's gate along with the less positive HV applied to FTs' channel region for same write performance but with the benefits of channel length reduction in cell and less BVDS electric requirement in peripheral devices for more scalable manufacturing process.

This application claims priority to U.S. Provisional Patent Application Ser. No. 61/403,187, filed Sep. 9, 2010, which is owned by a common assignee, and which is herein incorporated by reference in its entirety.

### CROSS-REFERENCE TO RELATED APPLICATIONS

This application is related to the following US patent applications:
AP08-004, titled “NAND Based NMOS NOR Flash Memory Cell, a NAND Based NMOS NOR Flash Memory Array, and a Method of forming a NAND Based NMOS NOR Flash Memory Array”, utility Ser. No. 12/387,771, utility filing date May 7, 2009,
AP08-001, titled “An Integrated SRAM and FLOTOX EEPROM Memory Device”, utility Ser. No. 12/319,241, utility filing date Jan. 5, 2009,
AP09-004, titled “A Novel High Speed Two Transistor/Two Bit NOR Read Only Memory”, utility Ser. No. 12/804,156, utility filing date Jul. 15, 2010, and
AP09-011, titled “A Novel Cell Array for Highly-Scalable, Byte-Alterable, Two-Transistor FLOTOX EEPROM Non-Volatile Memory”, utility Ser. No. 12/930,022, utility filing date Dec. 23, 2010,
   which are assigned to the same assignee. The contents of these applications are hereby incorporated by reference in their entirety.

### BACKGROUND OF INVENTION

1. Introduction of the Field of Invention

The present presentation relates to design an ultimate universal, low-cost, highly compact combo non-volatile memory (NVM) that preferably integrates three mainstream NVM memories in one silicon IC chip. These three NVM memories include NAND, NOR and EEPROM and are fundamentally using the same storage cell structure as well as the write schemes but being respectively optimized with the most-compact cell and array sizes. Typically, three NVMs have targeted three different storage markets and technologies are not compatible. The NAND memory is made of the smallest 0.5T stack-gate cell structure and has been extensively used as an Extreme High Density (EHD) block-alterable Data storage with a slow serial read of 200 uS in unit of 512 KB page. On the contrary, NOR is made of 1T ETOX cell structure and is used as a Medium High Density (MHD) sector-alterable Code storage with a fast random read below 100 nS in unit of byte or word. Unlike NAND and NOR, EEPROM memory is based on 2T Flotox technology and is broadly used as a byte-alterable Data storage with a slow serial read in Standalone design but fast random read in embedded EEPROM applications.

In the past years, the market NVM trend strongly demands a low-cost hybrid storage solution that allows Code and Data being integrated on a same die. Many prior arts have been disclosed to claim the achievement of realizing the Ultimate Universal NVM design. But most of the designs were virtually based on Flash technology, which has wide varieties in cell structure, program and erase scheme and manufacturing process today. None of them were based on the mainstream 2T Floating gate Tunnel oxide (Flotox) EEPROM technology. As a result, when EEPROM's strict spec requiring 1M P/E cycles in unit of byte for 10-year product cycle, none of those Flash-based combo NVM chip can meet the criteria now and for-seeable future. In other words, those Flash-based combo prior art design is more Code-oriented design, rather than the Byte-alterable Data-oriented solution. It should be noted that EHD stands for Extreme High Density such as Gb, while MHD means Medium High Density such as 4 Mb-32 Mb. Most EEPROM memory density today is below 1 Mb.

As a consequence, a Byte-alterable and Data oriented combo NVM design of the present invention will meet the above market needs, in which NAND and NOR are designed with the acceptable P/E cycles and read speed, while EEPROM design would truly meet 1M endurance cycles in unit of byte and page. Three NVM memories in one die means NAND, NOR and EEPROM are using the same floating-gate cell structure, same Fowler-Nordheim (FN) program and erase schemes, thus the same process flow. In this invention, EEPROM keeps 2T cell, NOR keeps 1T cell, while NAND is kept like 0.5T cell. It purely uses new set of bias conditions of program and erase of circuit technique to integrate three incompatible ones in one die without any process change.

The Data-oriented combo chip design means NAND and NOR have to use the existing Flotox-based EEPROM cell and process to design on the same chip without degrading any EEPROM quality and performance, due to an extremely high data changing rate in many practical applications. The change of single byte-data of EEPROM is traditionally referred as a byte-write operation. The real byte-write operation is divided into two steps. The first step is to carry out a byte-erasure operation and then followed by executing a second-step of a byte-program. Typically, a byte-erasure operation is designed to apply a +16.0V to cell's gate and 0V to cell's channel of the floating-gate transistor in the selected byte. With said biased voltages, a FN-tunneling effect on EEPROM cell will be induced, thus increasing all eight cells' Vt to a value above +2.0V. Electrically, the Vt of +2.0V is cited as VtH, which is electrically designed to be a non-conduction state storing a binary data of “1” in a byte-read operation. The reason of cell's Vt increase in the selected byte after a successful byte-erasure is because the required number of electrons have been successfully injected into their floating-gate storage layer from their respective channel region due to the occurrence of a FN-tunneling effect.

By contrast, a byte-program operation is designed to apply a +16V to the selected cells' floating-gate channel region along with their gates biased at 0V to induce a reverse FN tunneling. How many cells' channels are coupled to a 16V programmed BL voltage is depending on the number of cells selected for data change from “1” to “0” during byte-program operation. In normal byte-program operation, the number of EEPROM bits selected for a data change varies flexibly from 1 to 8 in a selected byte. A successful byte-program operation will decrease the selected cells' Vt from a high-erased value of +2.0V, VtH, to a lower value below −2.0V, which is the conduction state, storing a binary data of “0” and referred as “VtL.” After byte-program, the stored electrons in the selected cells are being expelled out from their respective floating-gate layer to their channel regions. A completion of a successful byte-write operation means the EEPROM cells in a selected byte have gone through both successful byte-erase and byte-program operations, regardless of their initial Vt such as VtH or VtL. Both byte-erasure and byte-program operations are employing the low-current FN channel tunneling scheme and are performed in unit of a byte, which is citied as byte-alterable EEPROM. In addition, many sets of sector-erase, page-erase and program conditions are also proposed in the present invention.

As explained above, in order to achieve 1M P/E cycles for the single selected byte with stringent criteria not to affect the rest of (N−1) bytes in the same selected page, a unique EEPROM array with an extra bit line, GBL, is extensively used for the past 30 years. The purpose of this adding GBL is to provide a separate common gate voltage for eight cells of each select byte of EEPROM. In such unique byte organization of EEPROM array, the common gate of eight cells of each byte would become an independent electric node. As a result, the HV of 16V applied to the common gate of each byte can be independently selected for erase, and rest of N−1 byte in the same page would not be disturbed, thus the Vt of the unselected cells in the remaining (N−1) unselected bytes would remain unaffected and remain the same in reliability. This added bitline needs to have one CG-ST transistor. The width and type of the CG-ST transistor is usually bigger than single cell's width pitch due to Native device is chosen to pass higher voltage of 16V-Vt to the common CG gate due to less Vt in native device.

The pitch of this added GBL typically takes a room larger than 2 BL-pitch, thus 25% increase in x-dimension on a single byte layout that just needs eight BLs.

The ultimate goal of this invention is set to completely remove this extra large-overhead of GBL but still maintain no erase and program disturbances to the rest of (N−) bytes in the same select page so that 1M endurance cycles can still be achieved for the desired small cell array. In addition, another novel technique of the present invention is to have a pair of dedicated SL and BL for each EEPROM cell running in parallel vertically in Y-direction to further reduce the EEPROM pitch in Y-dimension. As a result, the final EEPROM cell array size can potentially be reduced by total 40% so that the die cost of this invention can be largely reduced by about 20% by this pure circuit innovation without any process changes.

The ultimate goal of this invention is set to completely remove this extra large-pitch GBL but still maintain no erase and program disturbances to the rest of (N−) bytes in the same select WL so that 1M endurance cycles can still achieved for the small cell array size. In addition, another novel technique of the present invention is to have a pair of dedicated SL and BL for each EEPROM cell running in parallel in y direction to further reduce the EEPROM pitch in Y-dimension. As a result, the final EEPROM cell array size can be further reduced by 50% so that the die cost of this invention can be largely reduced by about 30% by this pure circuit innovation without any process changes.

2. Simple Description of Drawings, Tables and Figures

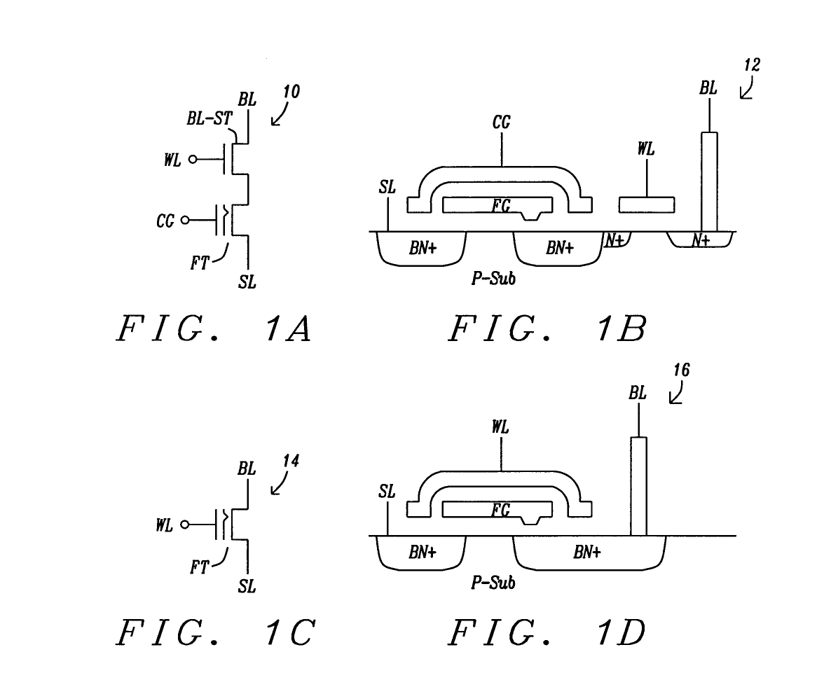

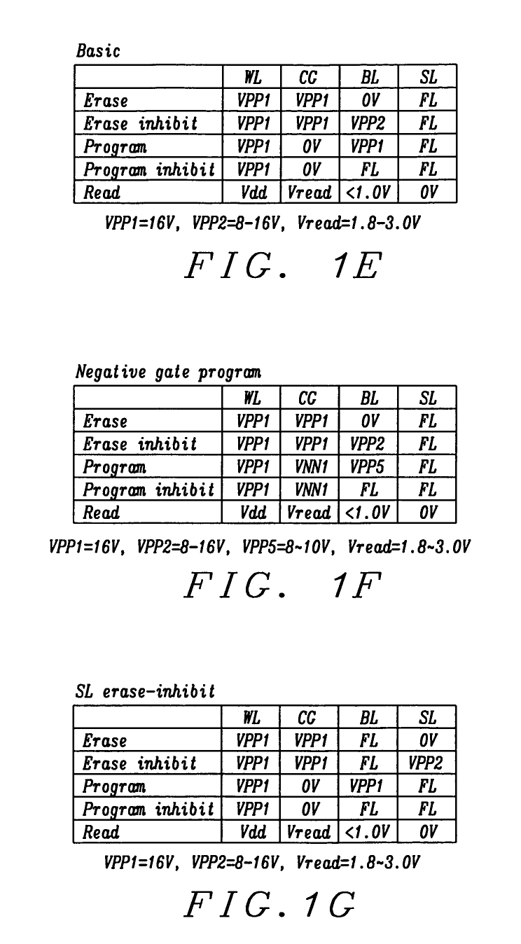

FIG. 1A, 10, shows a Flotox-based 2T EEPROM cell circuit of the prior and the present invention. It comprises of two HV NMOS transistors such as 1-poly BL-ST transistor and 2-poly floating-gate FT transistor. The top BL-ST transistor is called the Bitline-Select transistor and is used to protect the bottom FT storage cell from being disturbed when 16V is applied to BL during the program operation. The source of FT is denoted as SL, and the drain of BL-ST is denoted as BL. The gate of BL-ST is denoted as WL, while the gate of FT is denoted as CG. Note, WL stands for wordline and CG stands for Control-gate of the floating-transistor.

FIG. 1B, 12, shows the cross-sectional view of the 2T EEPROM cell shown in FIG. 1A. The CG on top is formed by Poly2 layer. The floating-gate layer of FT is made of Poly1. The gate of BL-ST can be made of either Poly1 or Poly2 and the decision of selection is fully subject to the preferable process. A deep Buried N+ (BN) layer is formed to surround the tunneling window at the drain side of the FT transistor for longer life of P/E endurance cycles. Similarly, another BN+ layer is also formed at the source side of FT to make sure no electric disconnection of SL to the source node of FT below FG. All BL-ST and FT transistors are formed on top of P-substrate.

FIG. 1C, 14, shows a Flotox-based 1T NOR cell circuit of the present invention. It comprises of one HV 2-poly floating-gate FT transistor only without a BL-ST transistor as shown in FIG. 1A. Without BL-ST transistor placed on top of FT, FT storage cell will not be protected from being disturbed when 16V is applied to BL during the program operation. Therefore a bias condition to reduce the BL program disturb is proposed by the present invention. The source of FT is also denoted as SL, and the drain of FT is denoted as BL along with the gate of FT is denoted as WL.

The FIG. 1D, 16, shows the cross-sectional view of the 1T NOR cell shown in FIG. 1C. The FT cell of FIG. 1D is exactly identical to the FT of FIG. 1A but the drain node of BL layer is directly connected BL instead.

FIG. 1E shows a set of regular positive bias conditions for operating the single 2T EEPROM cell shown in FIG. 1A. The bias conditions are disclosed for five key operations such as Erase, Erase-Inhibit, Program, Program-Inhibit and Read. The bias conditions have to be properly coupled to four key nodes of each 2T EEPROM cell for the preferable operations. The four nodes include WL, CG, BL and SL with P-substrate being tied to ground level. The Inhibit voltage is preferably coupled from BL.

FIG. 1F shows a set of bias conditions for operating the single 2T EEPROM cell shown in FIG. 1A. But the negative HV VNN1 and positive VVP1 and VPP2 and VPP5 are combined for another program scheme of the present invention. The bias conditions are also disclosed for five key operations such as Erase, Erase-Inhibit, Program, Program-Inhibit and Read. The bias conditions have to be properly coupled to four key nodes of each 2T EEPROM cell for the preferable operations. The four nodes include WL, CG, BL and SL with P-substrate being tied to ground level.

FIG. 1G shows another set of regular positive bias conditions for operating the single 2T EEPROM cell shown in FIG. 1A. The bias conditions are disclosed for five key operations such as Erase, Erase-Inhibit, Program, Program-Inhibit and Read. The bias conditions have to be properly coupled to four key nodes of each 2T EEPROM cell for the preferable operations. The four nodes include WL, CG, BL and SL with P-substrate being tied to ground level.

The major difference between FIG. 1G from FIG. 1E is the preferable Inhibit voltage is coupled from SL instead of the present invention.

FIG. 1H shows further another set of regular positive bias conditions for operating the single 2T EEPROM cell shown in FIG. 1A.

The major difference between FIG. 1H from FIG. 1E is the preferable program and erase operations are reversed. The erase Vt become is VtL but the program VVt becomes VtH of the present invention.

FIG. 1I shows further another set of regular positive bias conditions for operating the single 2T EEPROM cell shown in FIG. 1A.

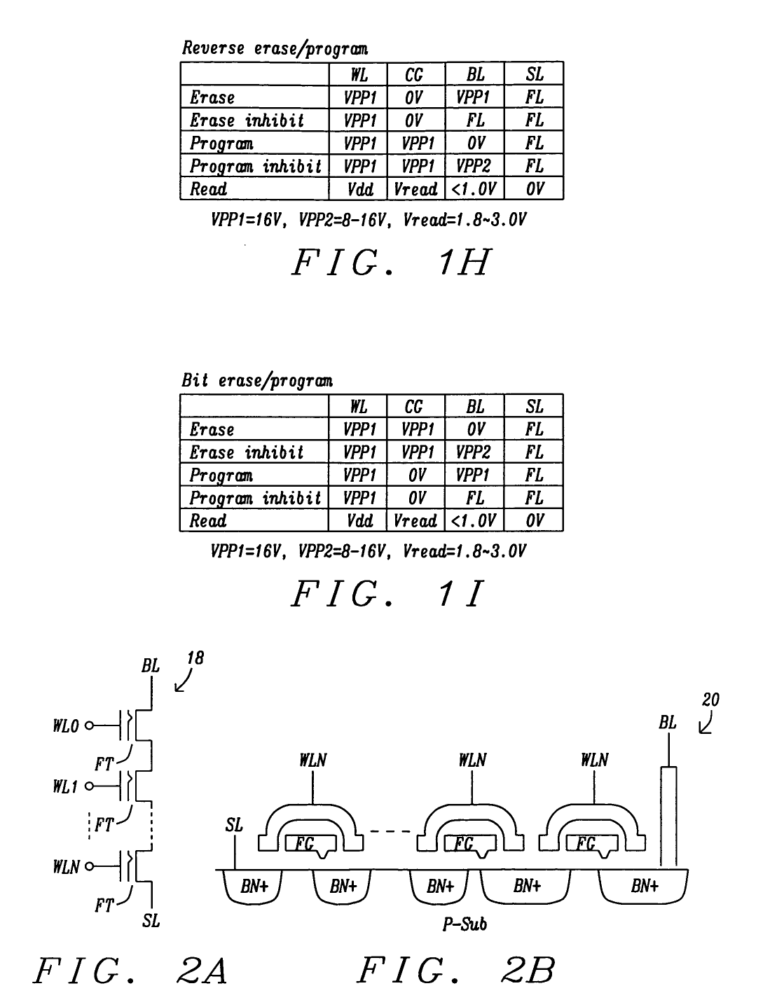

The major difference between FIG. 1I from FIG. 1E is the preferable program and erase operations are performed in unit of bit as oppose to the erase operation in unit of byte shown on FIGS. 1E, 1B, 1C and 2A.

FIG. 2A, 18, shows a Flotox-based NAND string cell circuit of the present invention. The NAND string comprises of N Flotox-based 2-poly FTs connected in series with the top node denoted as BL and the source node denoted as SL. Unlike the traditional NAND string, the top and bottom BL-ST transistors are not required. Each gate of FTn is connected to the corresponding WLn. Whole N FT transistors are formed on top of P-substrate.

The FIG. 2B, 20, shows the cross-sectional view of the 1T NOR cell shown in FIG. 2A. The FT cell of FIG. 2B is made exactly identical to the FT of FIG. 1A but the drain node of BL layer is directly connected BL instead.

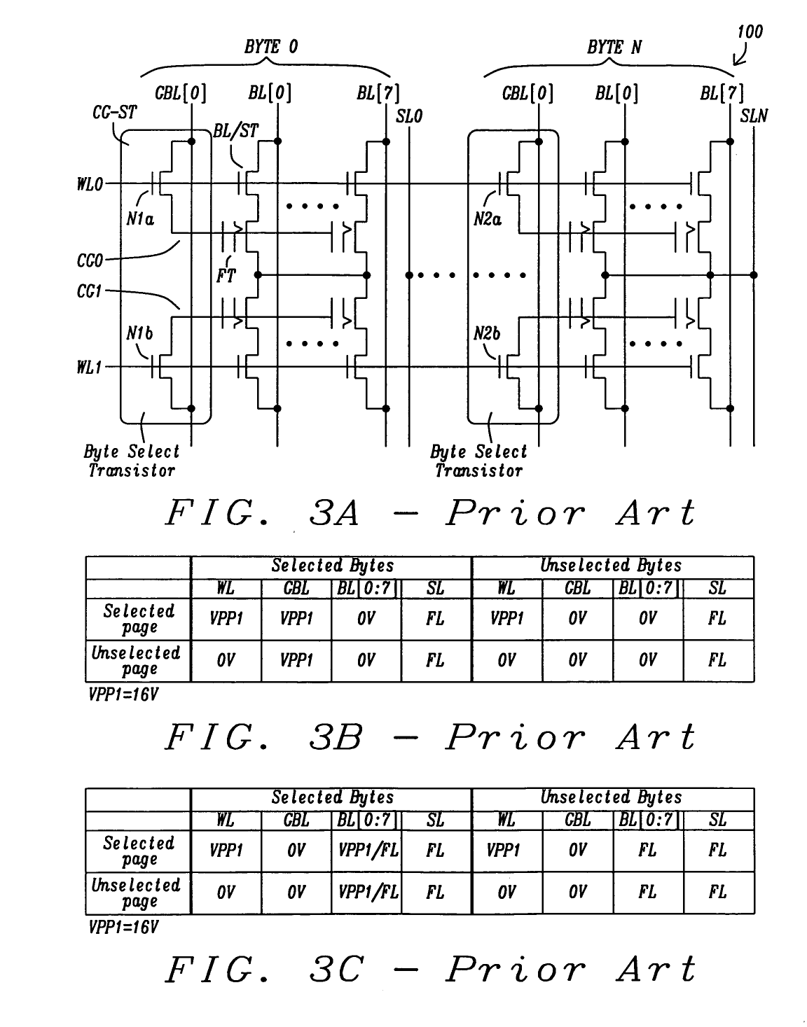

FIG. 3A, 100, shows a pair of 2-page circuits of the traditional 2T FLOTOX-based EEPROM cell array. Each page comprises of (N+1) bytes and each byte is sharing one common SL. In this prior-art EEPROM array organization, the (N+1) independent bytes of each WL layout are being cascaded in X-direction and (N+1) independent SLs that is connected to the common source nodes of all bytes running in Y-direction.

In addition to eight (8) regular BLs in byte layout, an extra BL, which is called as GBL, is added to the left column with an extra Select Transistor, N1a or N1b. The purpose of the GBL is to provide the required but separate gate voltage, CGn, for each selected byte without disturbance to the unselected byte's gate voltage. The overhead of this added GBL is typically larger than 2BL pitch in X-dimension of the cell size. Plus a dedicated SL is also added in the byte at the right column. As a result, the traditional EEPROM byte's effective byte size has been increased by at least 3 BLs out from 8 regular BLs. As a result, the byte size increases by ⅜, which is about 40% area penalty.

FIG. 3B shows a set of bias conditions for the selected byte and the unselected bytes in the same selected WL during the FN erase operation for FIG. 3A, the traditional 2T Flotox-based EEPROM cell array. The bias conditions are set to be different for one selected byte and the remaining unselected bytes on the same WL so that the least program and erase disturbance can be achieved for maintaining longer endurance cycles.

As opposite to FIG. 3B, FIG. 3C shows another set of bias conditions for the selected byte and the unselected bytes in the same selected WL during the FN program operation for FIG. 3A, the traditional 2T Flotox-based EEPROM cell array. The bias conditions are set to be different for one selected byte and the remaining unselected bytes on the same WL so that the least program and erase disturbance can be achieved for maintaining longer endurance cycles.

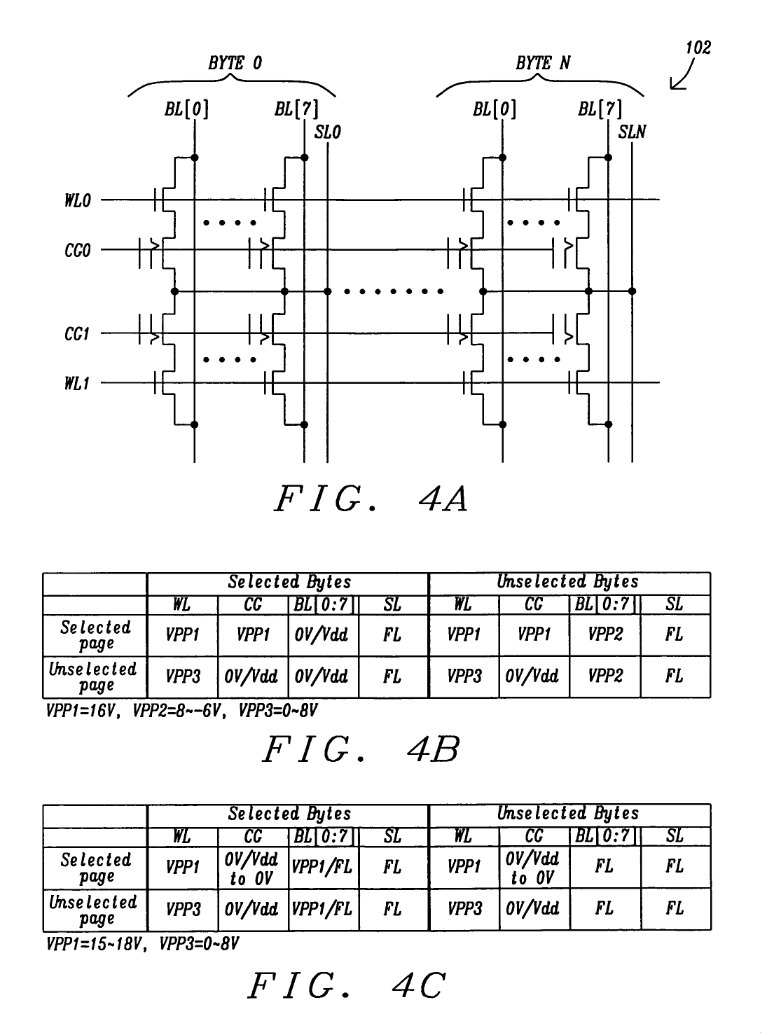

FIG. 4A, 102, shows a pair of 2-page circuits of another 2T FLOTOX-based EEPROM cell array of the present invention. Each page comprises of (N+1) bytes and each byte is sharing one common vertical SL. Similarly to the prior art of EEPROM cell array, in this novel EEPROM array organization, each page has (N+1) independent bytes with a layout being cascaded in X-direction and (N+1) independent SLs that is connected to the common source nodes of all bytes running in Y-direction.

Unlike FIG. 3A, no extra GBL, VSS BL are required in addition to the regular eight (8) regular BLs in the byte layout. Since GBL is no longer needed, thus the additional Select Transistor, N1a or N1b, is removed. As a result, any single byte of EEPROM layout just needs eight BLs. The whole page of EEPROM array is now consists of multiple bytes cascade in x-direction. All the gates of select transistors are connected to one signal WLn, and all the control gates of EEPROM cell are connected together to CGN without select transistors. One big advantage is the gate voltage of CGN has been increased about 2.0V because the Vt drop of N1a is eliminated. As a result, the higher gate voltage of CGN would have faster erase time.

FIG. 4B shows a set of bias conditions for the selected byte and the unselected bytes in the same selected WL during the FN erase operation for FIG. 4A, the 2T Flotox-based EEPROM cell array of the present invention. The bias conditions are set to be different for one selected byte and the remaining unselected bytes on the same WL so that the least program and erase disturbance can be achieved for maintaining longer endurance cycles.

As opposite to FIG. 4B, FIG. 4C shows another set of bias conditions for the selected byte and the unselected bytes in the same selected page during the FN program operation for FIG. 4A, the 2T Flotox-based EEPROM cell array of the present invention. The bias conditions are set to be different for one selected byte and the remaining N unselected bytes on the same WL so that the least program and erase disturbance can be achieved.

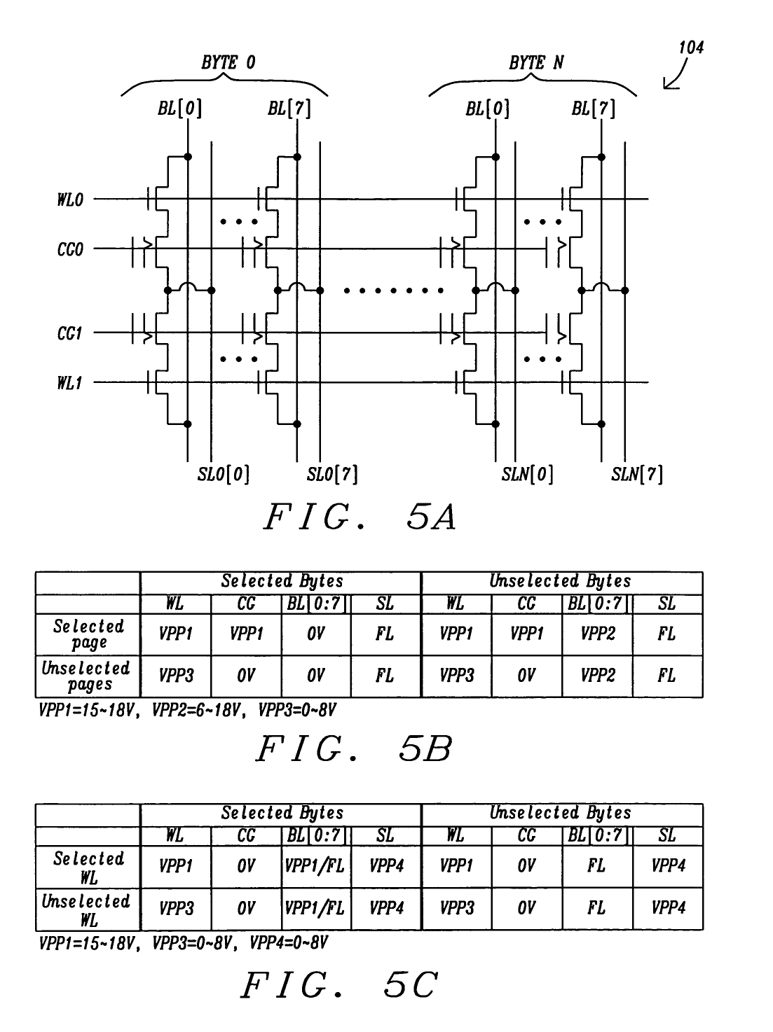

FIG. 5A, 104, also shows a pair of 2-page circuits but each byte does not share one common SL of 2T FLOTOX-based EEPROM cell array of the present invention as oppose to the EEPROM arrays shown in both FIG. 3A and FIG. 4A.

Similarly to the prior art of EEPROM cell array, in this EEPROM array organization, each page has (N+1) independent bytes with a layout being cascaded in X-direction and (N+1) independent SLs that is connected to the common source nodes of all bytes running in Y-direction.

Unlike FIG. 4A, each EEPROM cell has a dedicated pair of BL and SL. No individual SL of any cell in a single byte would be connected to a common SL. As a result, each EEPROM byte consists of eight (8) pairs of BLs and SLs. No GBL and SL are required. In addition, the added eight SLs do not have the area overhead because the large EEPROM byte pitch providing some room for adding eight metal lines of SLs. As a result, any single byte of EEPROM layout just needs eight BLs and SLS but within eight EEPROM cells' pitch in X-direction.

Like FIG. 4A, the whole page of EEPROM array now consists of multiple bytes cascade in x-direction. All the gates of select transistors in a page are connected to one signal WLn, and all the control gates of EEPROM cell are connected together to CGN without any select transistor. Similarly to FIG. 4A, one big advantage is the gate voltage of CGN has been increased about 2.0V because the Vt drop of N1a is being eliminated. As a result, the higher gate voltage of CGN would have faster erase time.

FIG. 5B shows a set of bias conditions for the selected byte and the unselected bytes in the same selected WL during the FN erase operation for FIG. 5A, the 2T Flotox-based EEPROM cell array of the present invention. The bias conditions are set to be different for one selected byte and the remaining unselected bytes on the same WL so that the least program and erase disturbance can be achieved for maintaining longer endurance cycles.

As opposite to FIG. 5B, FIG. 5C shows another set of bias conditions for the selected byte and the unselected bytes in the same selected page during the FN program operation for FIG. 5A, the 2T Flotox-based EEPROM cell array of the present invention. The bias conditions are set to be different for one selected byte and the remaining unselected bytes on the same WL so that the least program and erase disturbance can be achieved.

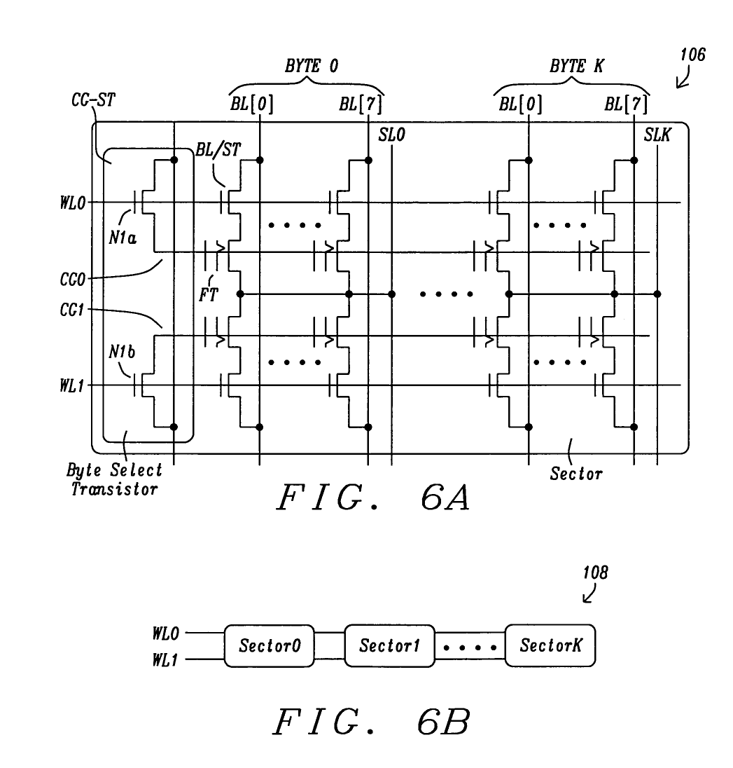

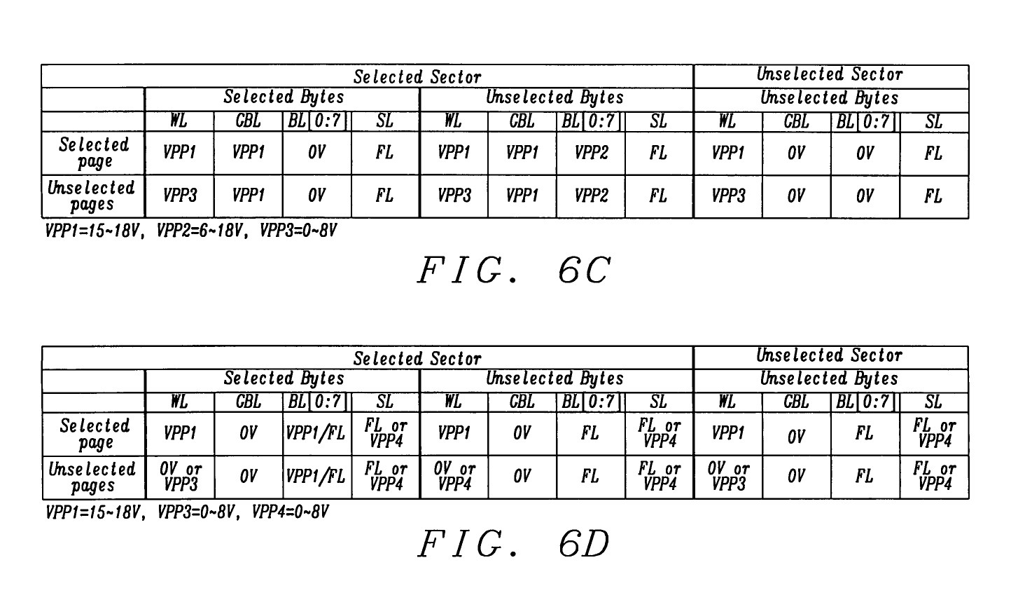

FIG. 6A, 106, EEPROM array architecture is the derivative of FIG. 4A when memory density is increased by enlarging the page length in X-direction. The EEPROM array of FIG. 6A is proposed to achieve the same P/E cycle performance as the one shown in FIG. 4A.

The total number of bytes in this larger page size is increased from (K+1) bytes in FIG. 4A to (K+1)×(N+1) bytes shown in FIG. 6A. Each (K+1) operation should be same as the (N+1) bytes in FIG. 4A. Thus the detailed description is skipped here for simpler explanation of the present invention.

FIG. 6B shows a large page with (k+1) sectors.

Similar to FIG. 1H, FIG. 6C shows a set of bias conditions for the selected byte and the unselected bytes in the same selected but larger page size during the FN erase operation for FIG. 6A, the 2T Flotox-based EEPROM cell array of the present invention. The bias conditions are set to be different for one selected byte in the selected sector and the remaining unselected bytes on the same selected sectors or the remaining unselected sectors of the larger page so that the least program and erase disturbance can be achieved for maintaining longer endurance cycles.

As opposite to FIG. 6C, FIG. 6D shows another set of bias conditions for the selected byte and the unselected bytes in the selected sector or unselected sectors of the same selected larger page during the FN program operation for FIG. 6A, the 2T Flotox-based EEPROM cell array of the present invention. The bias conditions are set to be different for one selected byte and the remaining unselected bytes on the same selected sectors or unselected sectors of the same selected larger WL page size so that the least program and erase disturbance can be achieved.

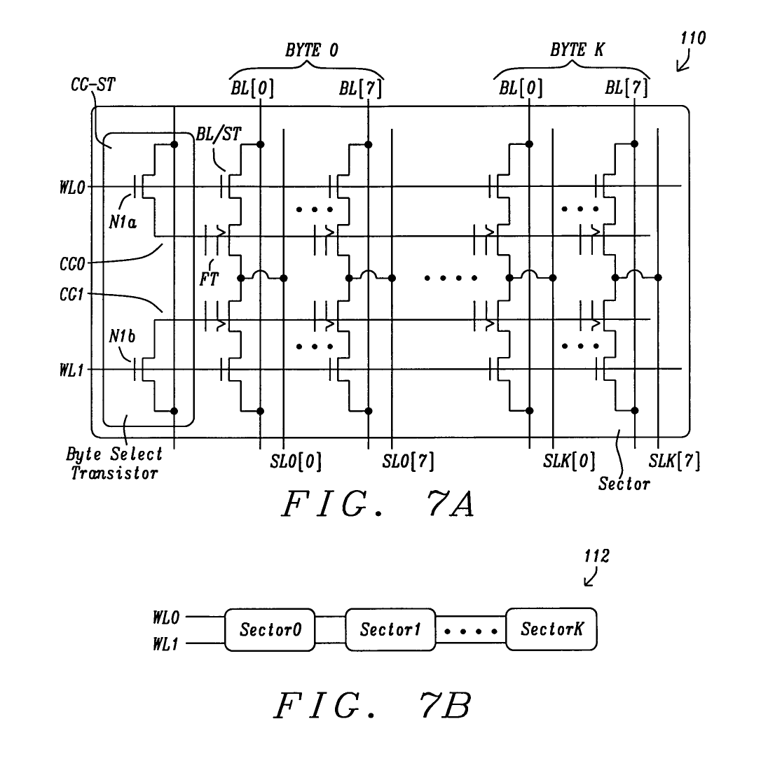

FIG. 7A, 110, EEPROM array architecture is the derivative of FIG. 6A. The EEPROM array of FIG. 6A should have the same P/E cycle performance as the one shown in FIG. 5A.

The total number of bytes in this larger page size is increased from (K+1) bytes in FIG. 5A to (K+1)×(N+1) bytes shown in FIG. 7A. Each (K+1) operation should be same as the (N+1) bytes in FIG. 4A. Thus the detailed description is skipped here for simpler explanation of the present invention.

FIG. 7B shows a large page with [K+1] Sectors according the circuit of FIG. 7A.

Similar to FIG. 5B, FIG. 7C shows a set of bias conditions for the selected byte and the unselected bytes in the same selected but larger page size during the FN erase operation for FIG. 7A, the 2T Flotox-based EEPROM cell array of the present invention. The bias conditions are set to be different for one selected byte in the selected sector and the remaining unselected bytes on the same selected sectors or the remaining unselected sectors of the larger page so that the least program and erase disturbance can be achieved for maintaining longer endurance cycles.

As opposite to FIG. 7C, FIG. 7D shows another set of bias conditions for the selected byte and the unselected bytes in the selected sector or unselected sectors of the same selected larger WL page during the FN program operation for FIG. 7A, the 2T Flotox-based EEPROM cell array of the present invention. The bias conditions are set to be different for one selected byte and the remaining unselected bytes on the same selected sectors or unselected sectors of the same selected larger WL page size so that the least program and erase disturbance can be achieved.

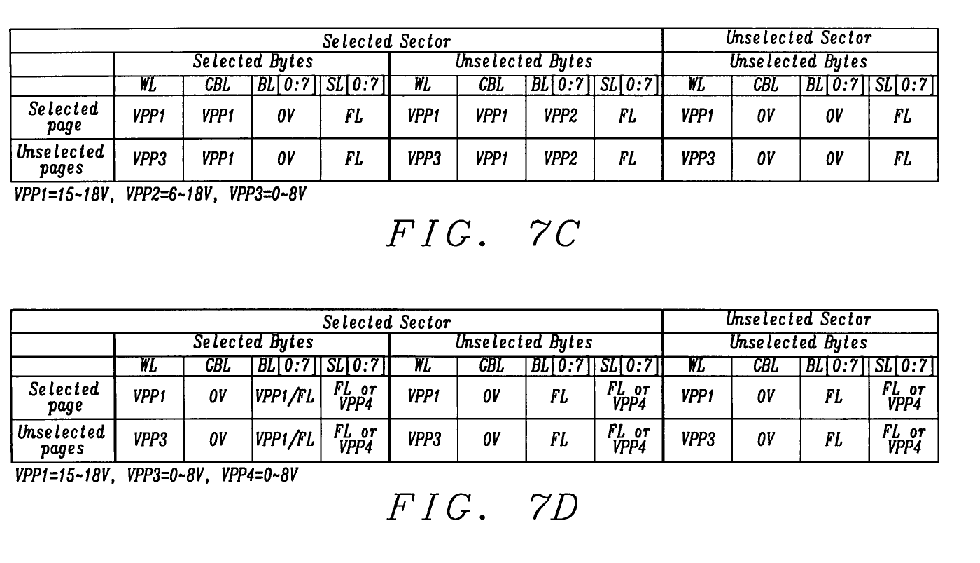

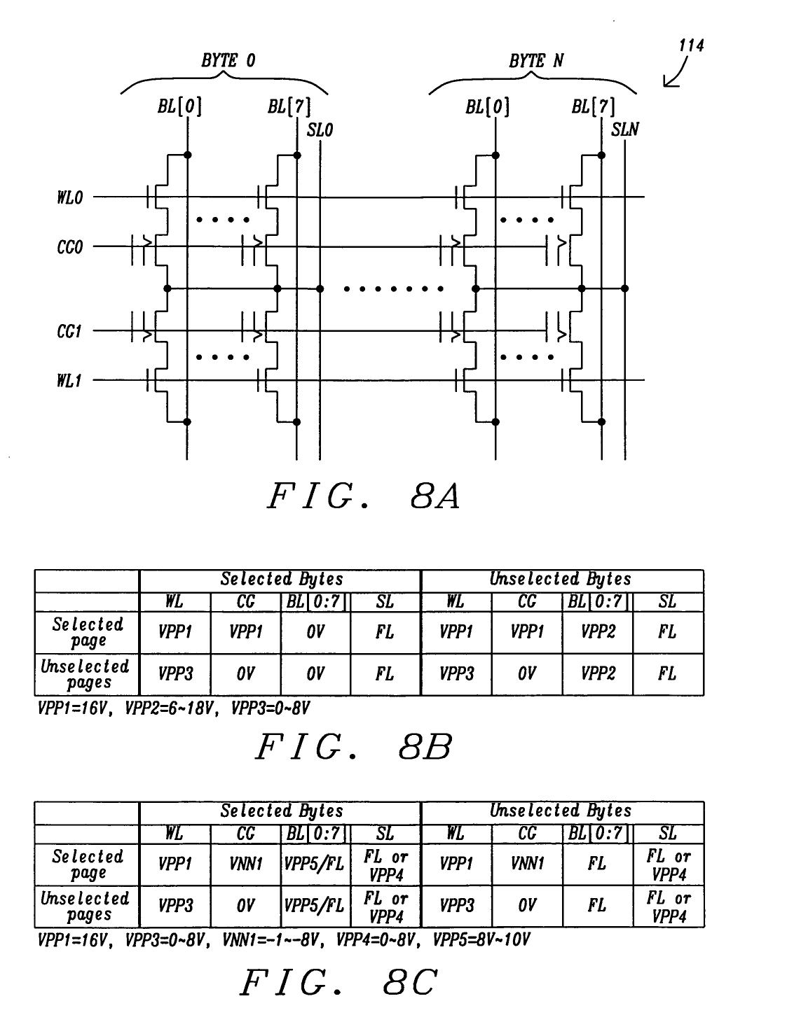

FIG. 8A, 114, is like FIG. 4A shows a similar pair of 2-page circuits of another 2T FLOTOX-based EEPROM cell array of the present invention. Each page comprises of (N+1) bytes and each byte is sharing one common SL. Similarly to the prior art of EEPROM cell array, in this novel EEPROM array organization, each WL has (N+1) independent bytes with a layout being cascaded in X-direction and (N+1) independent SLs that is connected to the common source nodes of all bytes running in Y-direction.

The difference between FIG. 4A and FIG. 8A is the FN program bias condition. In FIG. 4A, only the positive HV were used for both FN program and FN erase operations, regardless of in unit of byte or page. But In FIG. 8A, a novel medium negative HV is proposed for the FN page program. In traditional FN program, the gate is biased at 0V along with 0V for BL for the unselected programmed bits and at HV of 15V for the selected programmed bits. Since 15V needs to be applied to the drain nodes of the selected cells, the big voltage drop across between the drain node and source nodes during FN program operation would prohibit the EEPROM cell's channel length from being scaling down. As opposite to the traditional approach, a negative MHV is applied to the gate, thus the HV program voltage on the drain node of the selected programmed cells can be reduced to achieve the same FN tunneling effect. As a result, the cell's channel length can be further reduced and the BL programmed disturbance is also reduced. Plus, the EEPROM chip can generate the required negative voltage between −3.0V to −7.0V without a need of triple P-well (TPW) HV NMOS devices in the peripheral area.

Like FIG. 4B, the FIG. 8B shows a similar set of positive-only HV bias conditions for the selected byte and the unselected bytes in the same selected WL during the FN erase operation for FIG. 8A, the 2T Flotox-based EEPROM cell array of the present invention. The bias conditions are set to be different for one selected byte and the remaining unselected bytes on the same WL so that the least program and erase disturbance can be achieved for maintaining longer endurance cycles.

As opposite to FIG. 8B, FIG. 8C shows another new set of bias conditions of both positive and negative HV combination for the selected byte and the unselected bytes in the same selected WL during the FN program operation for FIG. 8A, the 2T Flotox-based EEPROM cell array of the present invention. Similarly, like FIG. 4C, the new bias conditions of FIG. 8C are set to be different for one selected byte and the remaining (N) unselected bytes on the same WL so that the least program and erase disturbance can be achieved.

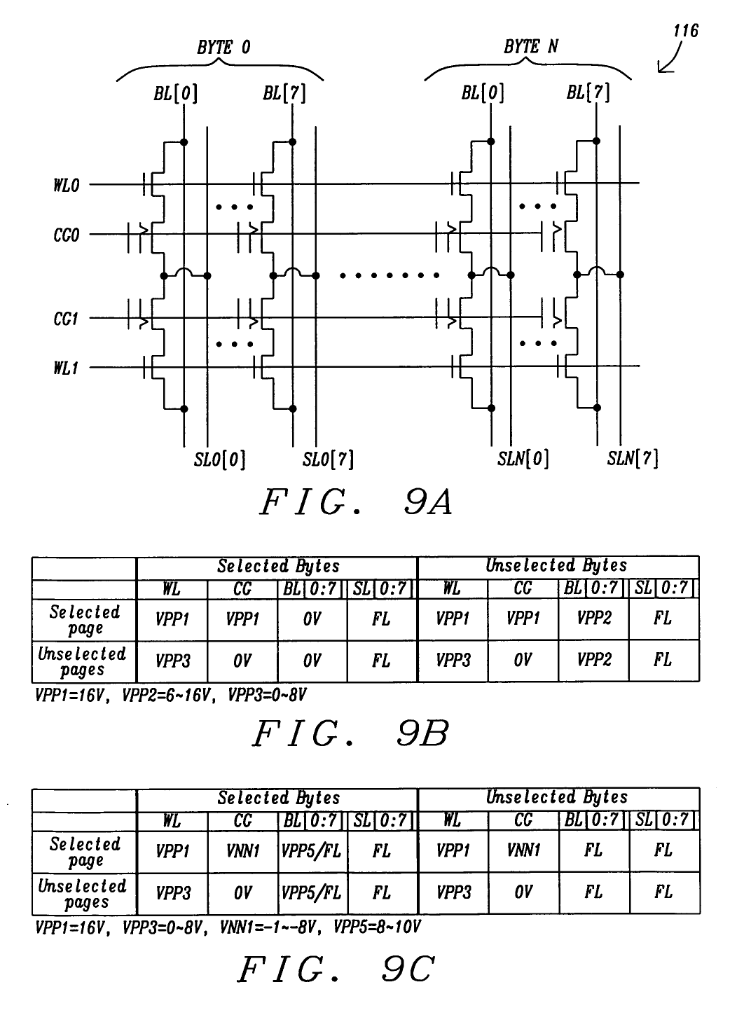

FIG. 9A, 116, is like FIG. 5A shows a similar pair of 2-page circuits of another 2T FLOTOX-based EEPROM cell array of the present invention. Each page comprises of (N+1) bytes and each byte is sharing one common SL. Similarly to the prior art of EEPROM cell array, in this novel EEPROM array organization, each page has (N+1) independent bytes with a layout being cascaded in X-direction and (N+1) independent SLs that is connected to the common source nodes of all bytes running in Y-direction.

The difference between FIG. 5A and FIG. 9A is the FN program bias condition. In FIG. 5A, only the positive HV were used for both FN program and FN erase operations, regardless of in unit of byte or page. But In FIG. 9A, a novel medium negative HV is proposed for the FN page program. In traditional FN program, the gate is biased at 0V along with 0V for BL for the unselected programmed bits and at HV of 15V for the selected programmed bits. Since 15V needs to be applied to the drain nodes of the selected cells, the big voltage drop across between the drain node and source nodes during FN program operation would prohibit the EEPROM cell's channel length from being scaling down. As opposite to the traditional approach, a negative MHV is applied to the gate, thus the HV program voltage on the drain node of the selected programmed cells can be reduced to achieve the same FN tunneling effect. As a result, the cell's channel length can be further reduced and the BL programmed disturbance is also reduced. Plus, the EEPROM chip can generate the required negative voltage between −3.0V to −7.0V without a need of triple P-well (TPW) HV NMOS devices in the peripheral area.

Like FIG. 5B, the FIG. 9B shows a similar set of positive-only HV bias conditions for the selected byte and the unselected bytes in the same selected page during the FN erase operation for FIG. 8A, the 2T Flotox-based EEPROM cell array of the present invention. The bias conditions are set to be different for one selected byte and the remaining unselected bytes on the same page so that the least program and erase disturbance can be achieved for maintaining longer endurance cycles.

As opposite to FIG. 9B, FIG. 9C shows another new set of bias conditions of both positive and negative HV combination for the selected byte and the unselected bytes in the same selected page during the FN program operation for FIG. 9A, the 2T Flotox-based EEPROM cell array of the present invention. Similarly, like FIG. 5C, the new bias conditions FIG. 9C are set to be different for one selected byte and the remaining (N) unselected bytes on the same WL so that the least program and erase disturbance can be achieved.

FIG. 10A, 118, is a derivative of FIG. 4A. It shows a similar pair of 2-page circuits of another 2T FLOTOX-based EEPROM cell array of the present invention. Each page comprises of (N+1) bytes and each byte is sharing one common SL. Similarly to the prior art of EEPROM cell array, in this novel EEPROM array organization, each WL has (N+1) independent bytes with a layout being cascaded in X-direction and (N+1) independent SLs that is connected to the common source nodes of all bytes running in Y-direction.

The difference between FIG. 4A and FIG. 10A is the FN erase bias condition. In FIG. 4A, the BL erase and BL erase inhibit voltage are coupled from eight BLs. On the contrary, in FIG. 10A, the erase and erase inhibit voltages of respective selected bytes and unselected bytes are coupled from the respective SLs. In this embodiment of the bias conditions, HV on the WLn used in FIG. 4A, is not used in FIG. 10A. Thus the control signals for erase operation in FIG. 10A is simpler than FIG. 4A.

Like FIG. 4B, the FIG. 10B shows a similar set of positive-only HV bias conditions for the selected byte and the unselected bytes in the same selected WL during the FN erase operation for FIG. 10A, the 2T Flotox-based EEPROM cell array of the present invention. The bias conditions are set to be different for one selected byte and the remaining unselected bytes on the same WL so that the least program and erase disturbance can be achieved for maintaining longer endurance cycles.

As opposite to FIG. 10B, FIG. 10C shows another new set of bias conditions of positive only HV for the selected byte and the unselected bytes in the same selected WL during the FN program operation for FIG. 10A, the 2T Flotox-based EEPROM cell array of the present invention. Similarly, like FIG. 4C, the new bias conditions FIG. 10C are set to be different for one selected byte and the remaining (N) unselected bytes on the same WL so that the least program and erase disturbance can be achieved.

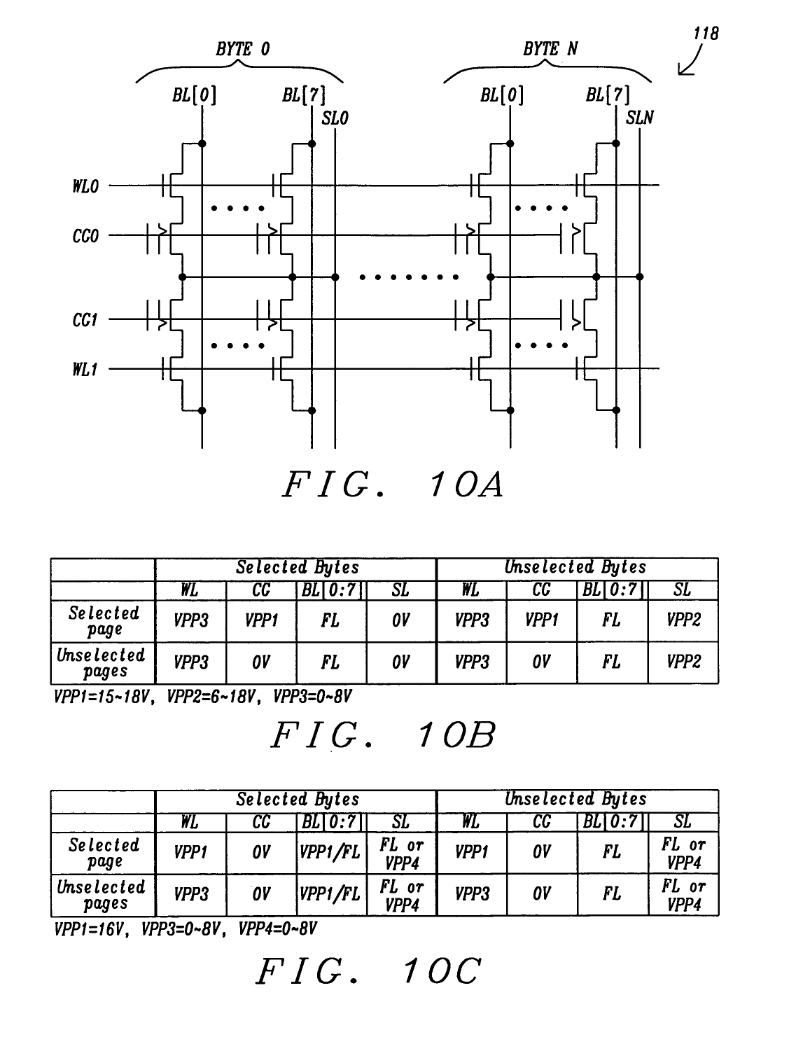

FIG. 11A is the derivative of FIG. 5A. It shows a similar pair of 2-page circuits of another 2T FLOTOX-based EEPROM cell array of the present invention. Both FIG. 10A and FIG. 11A contain (N+1) bytes. The difference is the FIG. 10A's array share one common SL for each byte (8 BLs, 1SL), while FIG. 11A's array's each BL has one individual SL (8BLs, 8SLs).

In FIG. 11A the FN erase and FN program are reversed. In other words, the erase Vt becomes the program Vt. Similarly, the program Vt becomes the erase Vt of FIG. 11A.

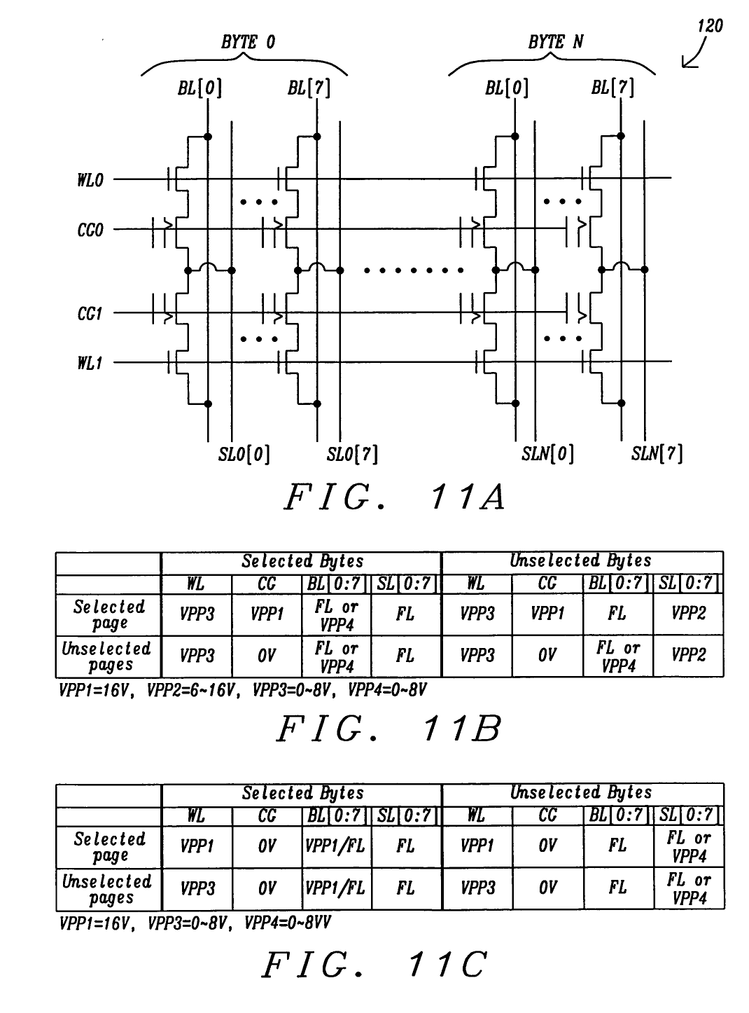

FIG. 12A is the derivative embodiment of FIG. 11A but the FN erase and FN program operations are performed in unit of single bit, rather than in unit of single byte or page. Since this is write operation in unit of bit, which is the minimum size of data, thus the terms of traditional erase and program can be swapped arbitrarily without causing problem. In the traditional byte-alterable EEPROM, erase is performed in unit of eight bits. All data of eight bits are erased to VtH of “1”, regardless of initial Vts of each bit in a single byte. The way to change the initial eight-bit data of either “1” or “0” has gone through a middle value of erase data which is “1” and then becomes “0” for the selective programmed bits and stay “1” for non-programmed bits. The FN erase is done on eight bits collectively and simultaneously but FN program is done on bit-by-bit base.

Unlike the traditional byte-alterable EEPROM, FIG. 12A discloses a novel method to allow bit alterable. In this case, any single bit or any number of bits can be selected for erase and program. The whole bit-write operation is divided into two steps.

The first step is to do the bit-erase to increase cells' Vt to VtH of any number of the selected bits in the selected sector or page. After this bit-erase, those cells with initial “0” data but selected to be erased would be changed to final “1” data when bit-erase is successfully performed. But those cells with initial “0” data but are not selected for erase would stay unchanged.

The FIGS. 12B and 10c are to show the reversed bias conditions of reversed FN erase and program operations to achieve the reversed Vts of the present invention in the preferable EEPROM cell array that has no shared SL in every byte of EEPROM array of the present invention. The erased Vt is set to be negative of about −2.0V and the programmed Vt is set to be positive of around +2.0V.

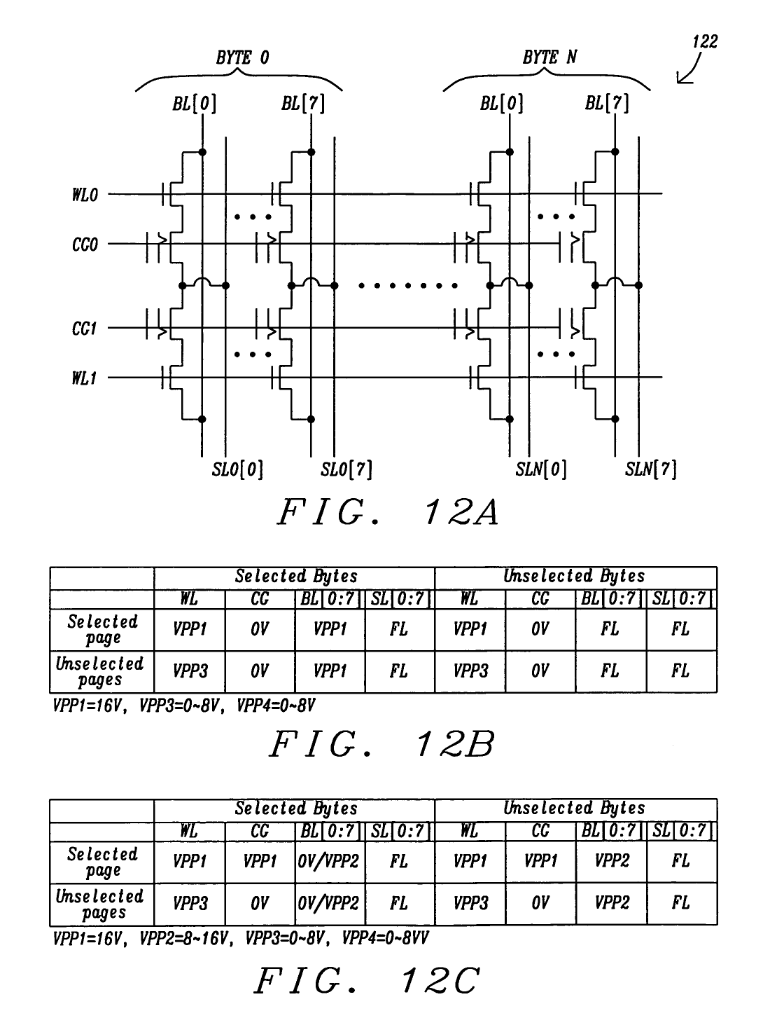

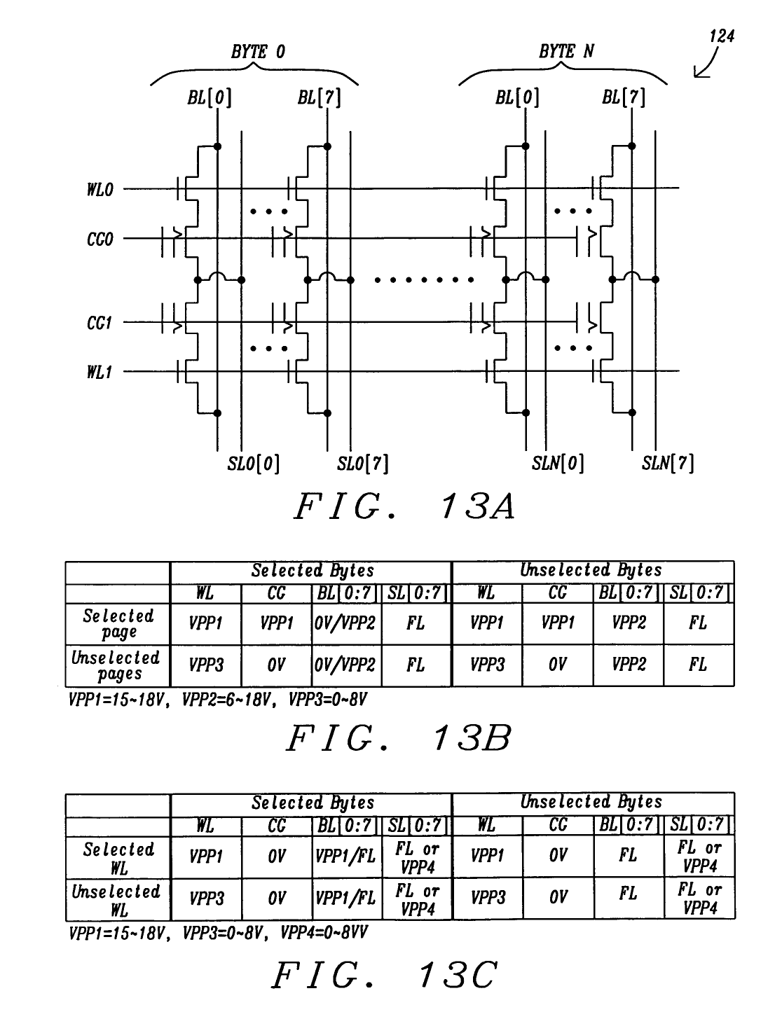

FIG. 13B shows the set of preferable bit-erase and bit-erase Inhibit conditions. There are four combinations of select and unselected cells in the EEPROM array.
a) The gates (CG), channels (BL) and sourceline (SL), of the selected cells in the selected bytes in the same select page have to be biased at VPP1 and 0V respectively, where VPP1=16V.
b) The gates (CG), channels (BL) and sourceline (SL), of the unselected cells in the unselected bytes but in the same selected page have to be biased at VPP2 and 0V respectively, where VPP2=8-16V. The voltage drop ΔV across tunnel-window layer of the selected program cells in the selected page varies with a value of 0-8V, which is acceptable in keeping great endurance cycles.
c) The gates (CG), channels (BL) and sourceline (SL), of the unselected cells in the unselected bytes in the same unselect pages have to be biased at VPP3 and 0V respectively, where VPP3=4-8V.

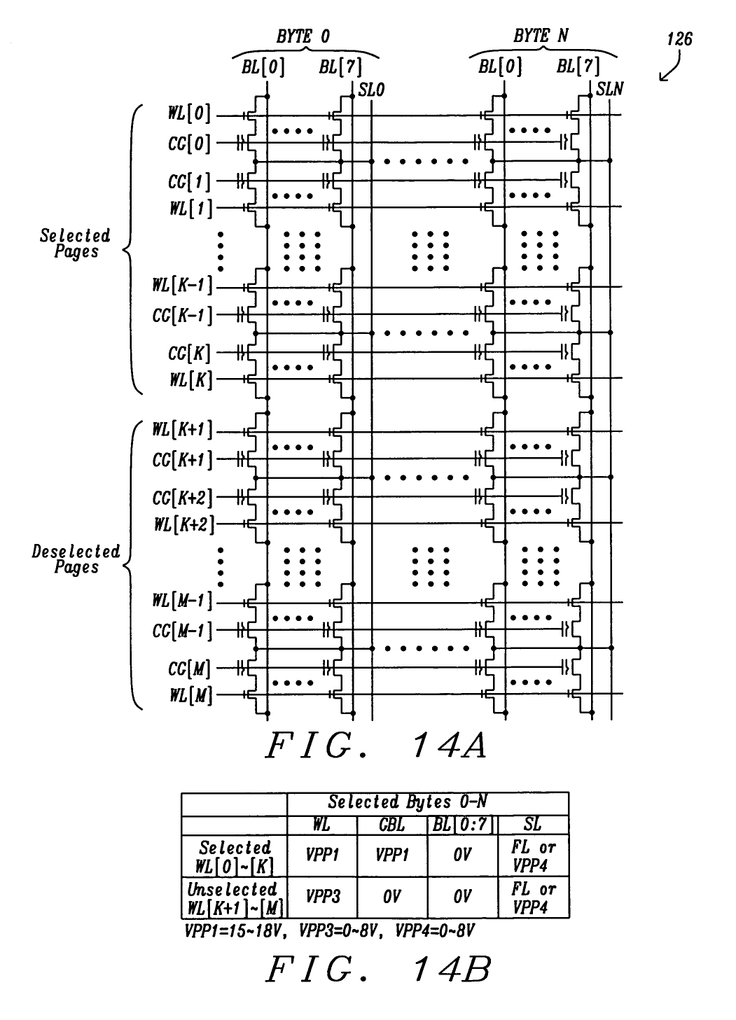

FIG. 14A shows the preferable EEPROM array comprising of multiple [K+1] pages arranged in y-direction of the present invention. Each page comprises of (N+1) bytes cascaded in x-direction. The page circuit is based on the circuit of FIG. 4A without any overheads of extra GBLs but share SLs of the present invention. The goal of this new EEPROM array is set to achieve the same 1M P/E cycles in unit of byte as the traditional EEPROM array requiring one GBL per each byte.

The erase operation of this novel EEPROM array can be flexibly performed in any desired pages with same time due to the small current consumption during the FN page erase operation. As a result, the erase time can be greatly reduced in unit of flexible number of pages.

FIG. 14B shows a preferable set of bias voltage condition for flexibly erasing the selected [K+1] pages without inducing any severe Vt disturbance to the rest of EEPROM cells in the unselected pages in the same EEPROM memory array.

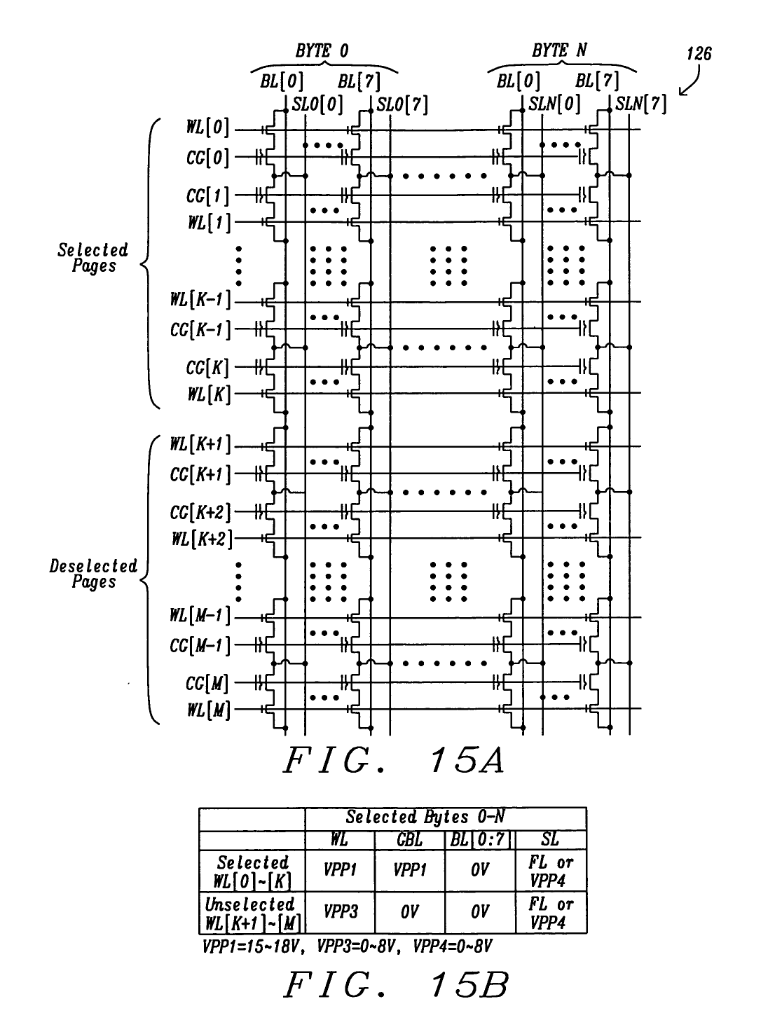

FIG. 15A shows another preferable EEPROM array of the present invention and it is the derivative of FIG. 14A but each byte cells do not share the common SL. Similarly to FIG. 14A, this new array comprises of multiple pages arranged in y-direction. And each page comprises of {N+1} bytes cascaded in x-direction without having a shared SL in each byte.

FIG. 15B discloses a preferable bias condition for flexibly erasing any number of selected blocks and pages without inducing the disturbance to the unselected pages and blocks to drastically reduce the erase time. The fundamental page circuit of FIG. 15A comprises of the circuit of FIG. 5A.

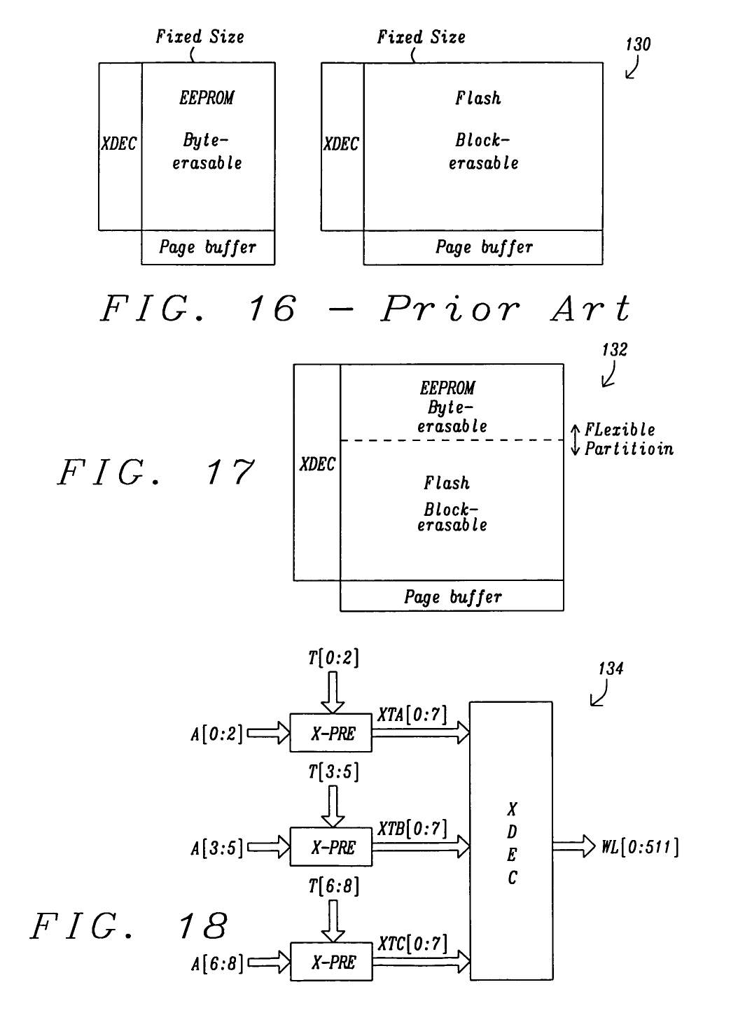

FIG. 16 prior art shows two NVM memory blocks comprising of the traditional hybrid Flotox-based EEPROM and Flotox-based Flash memory arrays within one chip. FIG. 16 prior art is the conventional way that EEPROM array contains GBL for byte-alteration and Flash array does not contain GBL. So EEPROM and Flash array's x-direction pitches are different. They cannot be combined into one array. They remain as two separated memory blocks as shown in FIG. 16 prior art.

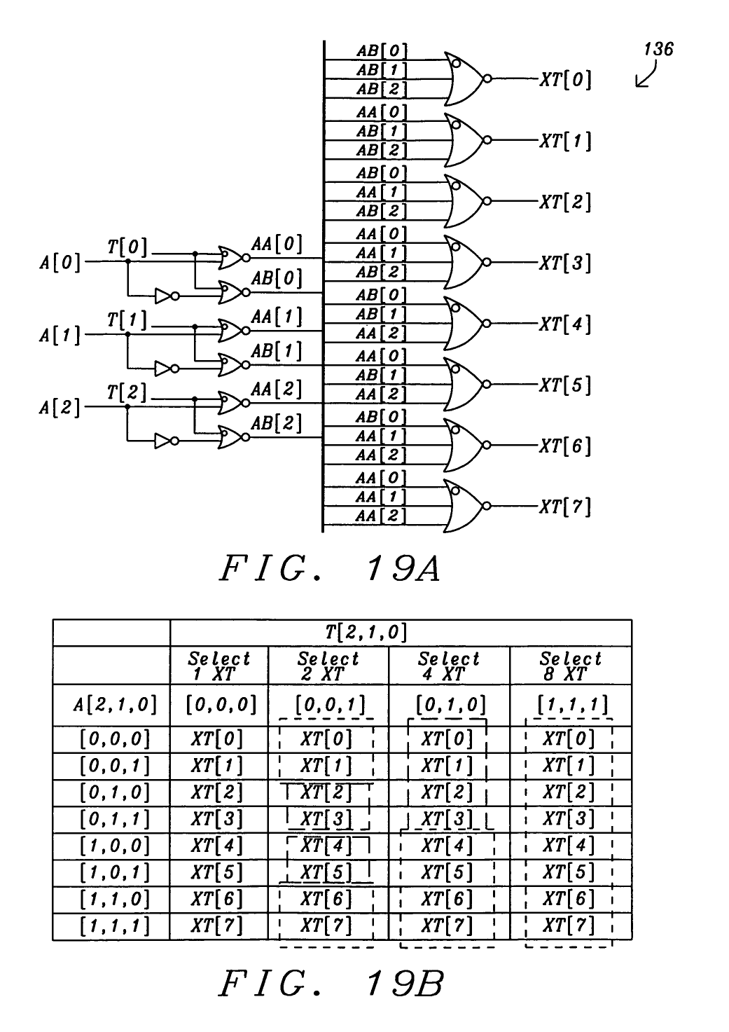

FIG. 17 shows another two NVM memory blocks comprising of the preferable hybrid Flotox-based EEPROM and Flotox-based Flash memory arrays within one chip of the present invention. Typically, for every byte of single page of EEPROM array of the present invention, no need to add one GBL for the byte-alterable data storage. Similarly, the page Flash array does not have GBL either for block-alterable code storage, thus the byte pitch of flash is smaller than EEPROM. As a result, EEPROM memory density and Flash density are separately fixed for respective memory sizes. Even the page buffer design has to be separated into two for respective EEPROM and Flash memories. There is no flexibility of memory density of respective EEPROM and Flash.

Unlike the traditional EEPROM array, every single byte of each page of EEPROM array of the present invention does not need one GBL for byte-alterable data storage as the page of Flash array for the block-alterable code storage. As a result, the byte pitch of Flash is kept identical with the byte-pitch of EEPROM of the present invention. Therefore, in physical array layout, EEPROM and Flash memory can be placed on top of each other with perfect match in x-direction. No need of two separate memory blocks for respective EEPROM and Flash in same chip. Furthermore, one unified page buffer fitting in the array x-pitch can be shared by both EEPROM and Flash memories.

Since there is no difference in real physical layout for EEPROM and Flash for respective byte-alterable data and block-alterable storages, a flexible memory partition for EEPROM and Flash can be achieved of the present invention.

FIG. 18 shows one exemplary circuit block of X-decoder of hybrid Flotox-based EEPROM and Flash arrays for data and code storages on one chip. There are nine (9) address inputs such as A0-A8 and 512 row outputs of WL[00:511]. The X-decoder has three (3) pre-decoders, X-PRE.

FIG. 19A shows one exemplary circuit block of X-PRE decoder of hybrid Flotox-based EEPROM and Flash arrays for data and code storages on one chip. The three inputs are A[0], A[1] and A[2]. The eight (8) outputs are XT[0]-XT[7].

FIG. 19B shows one exemplary logic values to allow the selection of the flexible numbers of WLs or pages.

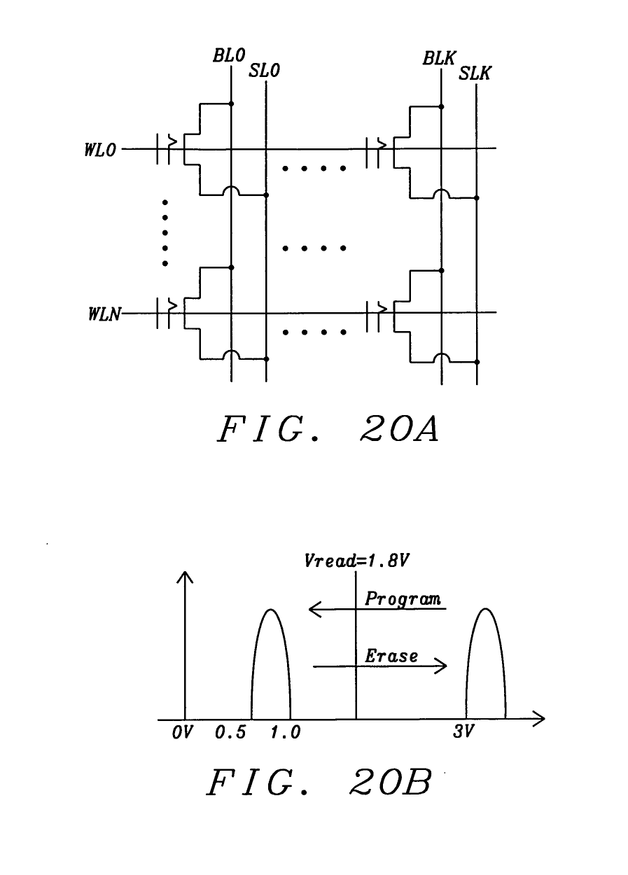

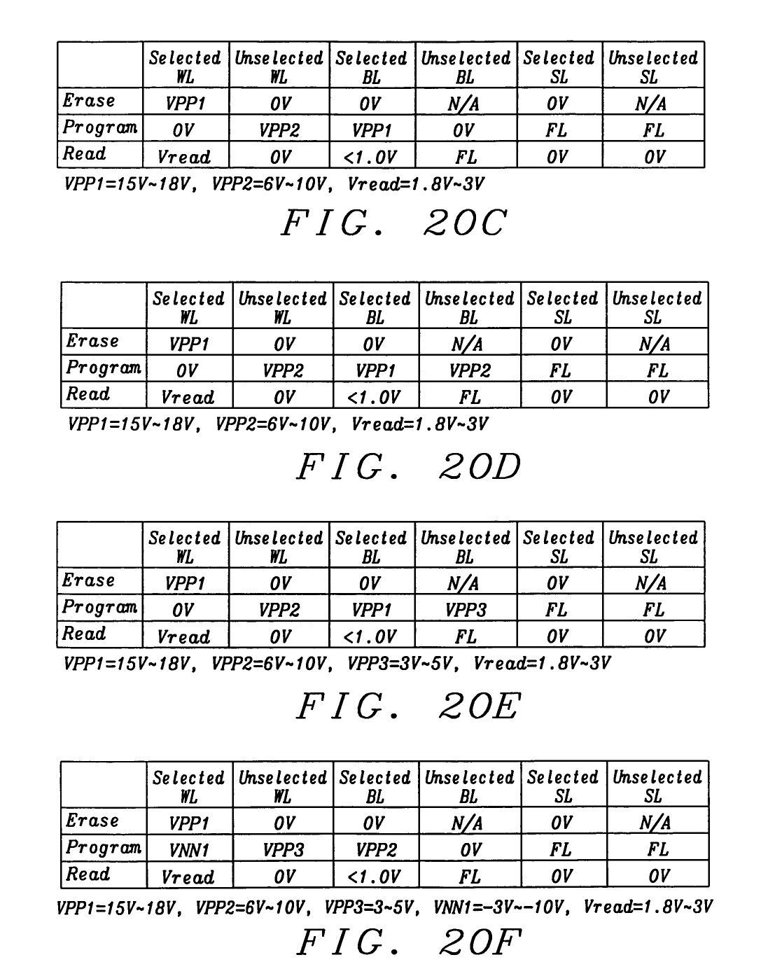

FIG. 20A shows an embodiment of the circuit 1T Flotox-based NOR array of the present invention.

FIG. 20B shows the preferable graph of 1T1b NOR's two Vt distributions.

FIG. 20C shows a preferable set of biased voltage conditions of Erase, Program and Read operations of the Selected and Unselected of the 1T1b Flotox-based NOR cells of the present invention.

FIG. 20D shows another set of biased conditions for the selected and unselected Erase, program and read operations as seen in FIG. 20C.

FIG. 20E further shows another set of biased conditions for the selected and unselected Erase, program and read operations as seen in FIG. 20C and FIG. 20D.

FIG. 20F shows another preferable set of program, erase and read operations of the 1T1b NOR cell array of the present invention.

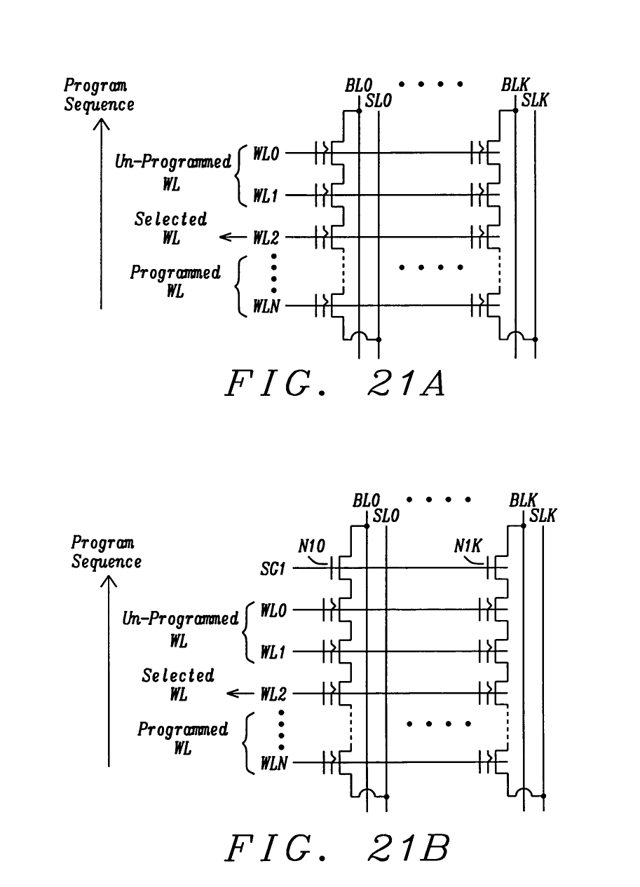

FIG. 21A shows the 0.5T Flotox-based NAND array of the present invention.

FIG. 21B shows another preferable NAND array which is comprised of a plurality of similar N+1 NAND strings by adding only one top selected transistor.

FIG. 21C further shows another embodiment of preferable NAND string that comprised of a plurality of similar N+1 NAND strings by adding only one top and one bottom selected transistors, N1K and N2K.

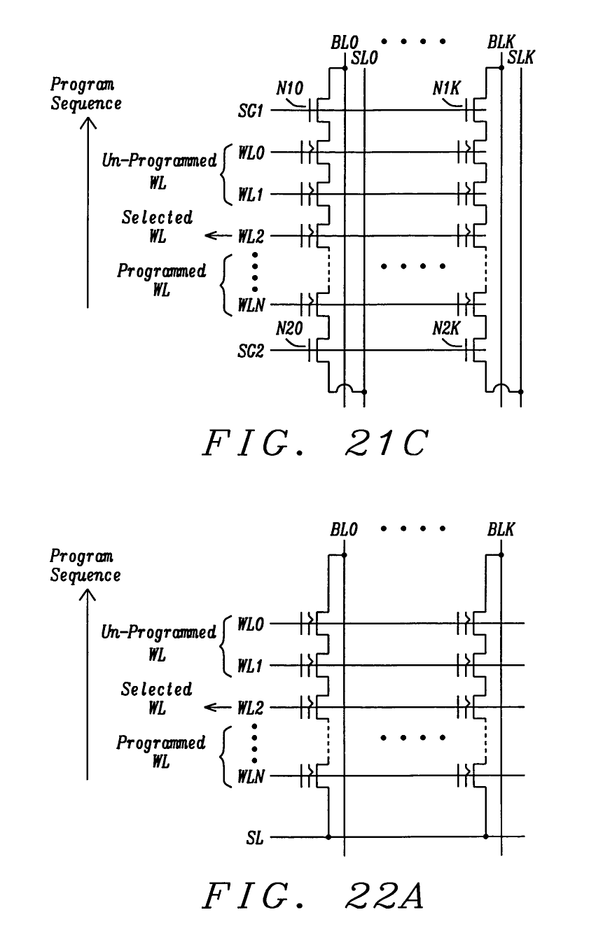

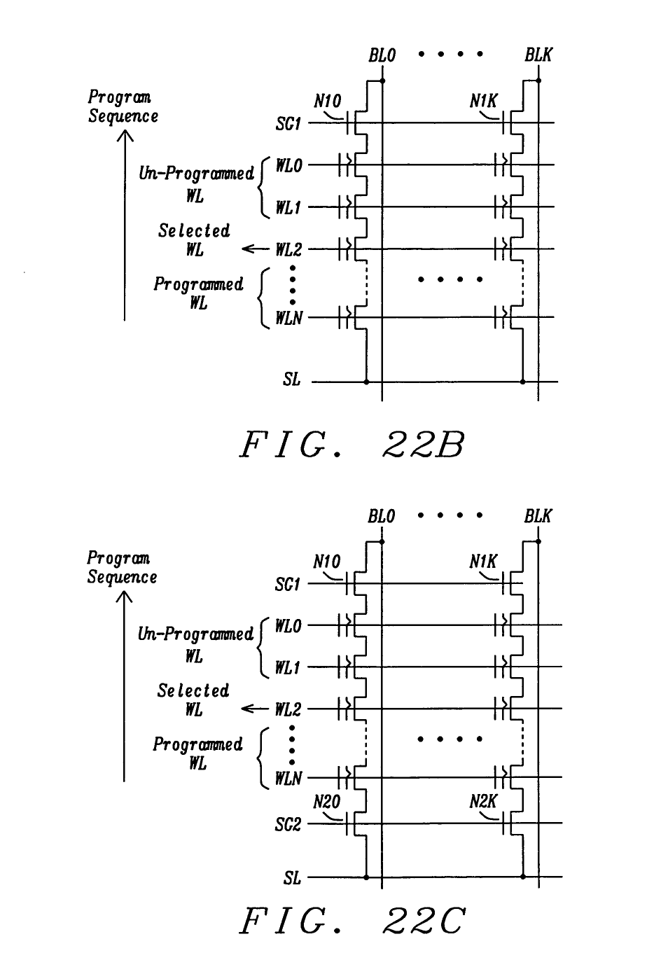

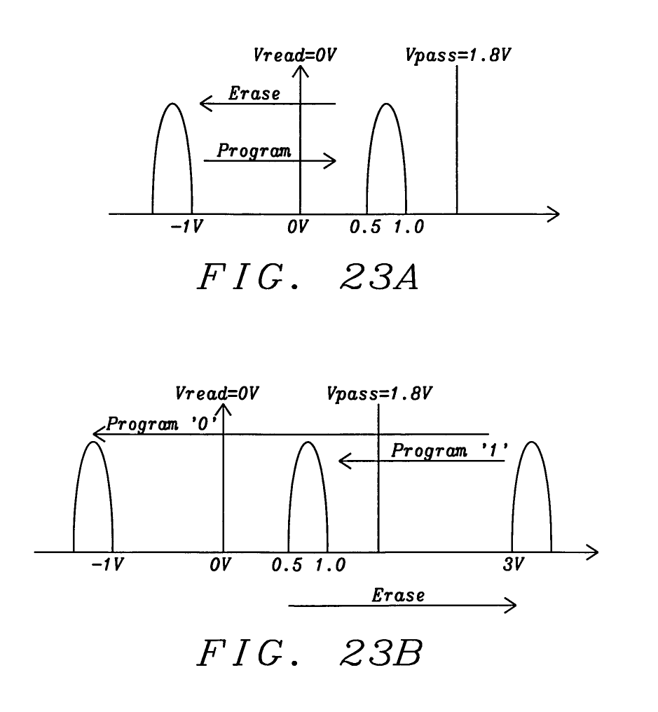

FIG. 22A shows another embodiment of the NAND string array of the present invention.

FIG. 22B shows a further embodiment of the NAND string array of the present invention.

FIG. 22C shows another NAND string but adding one top and one bottom Select transistors, N1K and N2K.

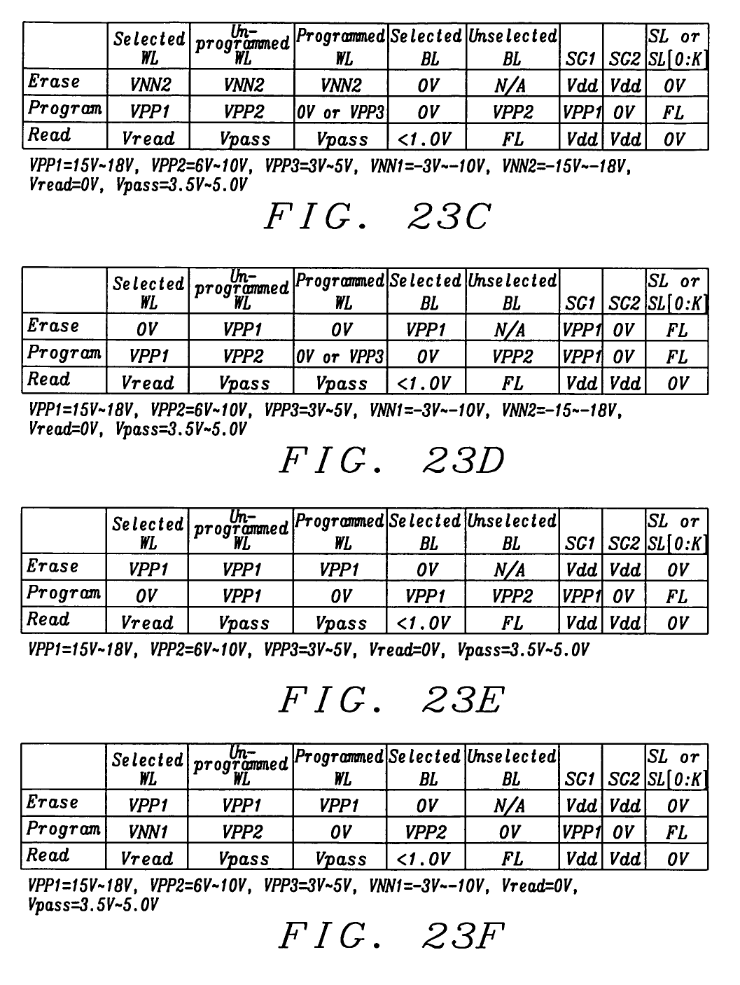

FIG. 23A shows the preferable NAND cell's Vt in NAND string of the present invention.

FIG. 23B shows the reverse program and erase Vt from FIG. 23A.

FIG. 23C shows the bias conditions for 1^{st} Vt distribution according to FIG. 23A.

FIG. 23D shows another bias conditions for 1^{st} Vt distribution according to FIG. 23A.

FIG. 23E shows another bias conditions for the 2^{nd} Vt distribution according to FIG. 23B.

FIG. 23F shows another bias conditions for 2^{nd} Vt distribution according to FIG. 23B.

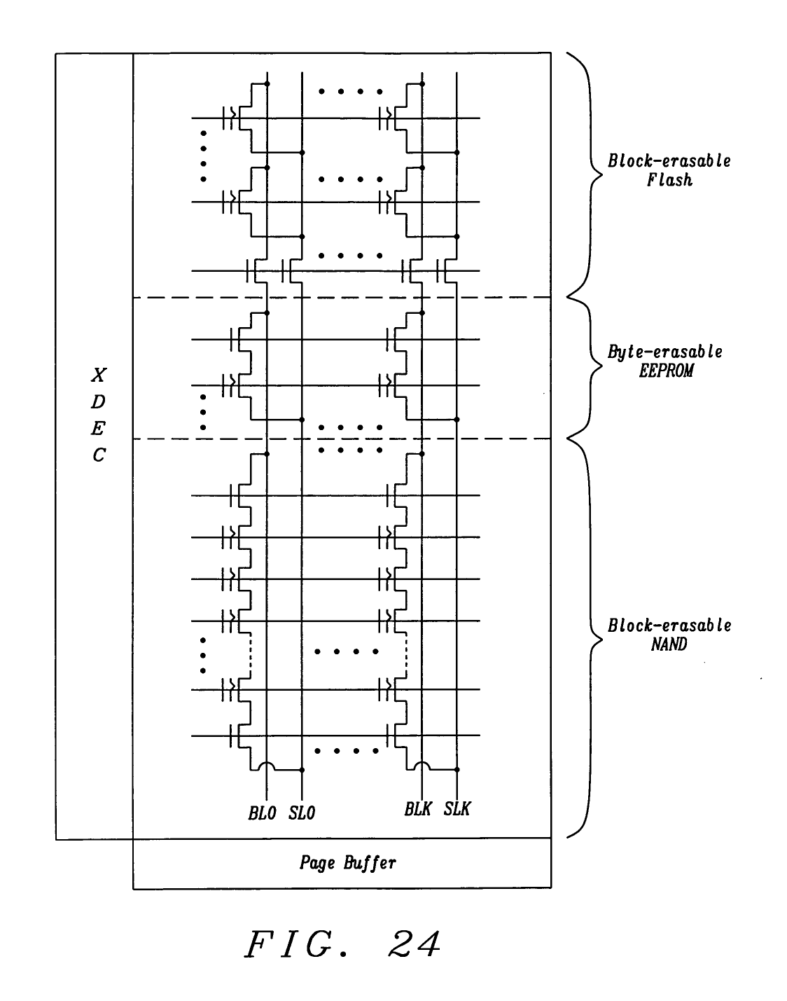

FIG. 24 shows a combo flotox-based NOR array that comprises of 1T1b NOR, 2T1b EEPROM and N+2 T NAND string of the present invention.

### SUMMARY OF THE INVENTION

The first (1^{st}) object of this invention discloses a novel 2T FLOTOX-based EEPROM cell array structure, which is preferably formed by removing a HV ST transistor and GBL physically from each byte but keep a common source node for eight cells of the traditional EEPROM cell array for byte size reduction. The byte layout area reduction does not sacrifice the P/E endurance performance performed in unit of byte and page for those high changing rate of data storage application.

The second (2^{nd}) object of this invention similarly discloses a novel 2T FLOTOX-based EEPROM cell array structure, which is preferably formed by removing a HV ST transistor and GBL and common SL physically from each byte to eliminate the voltage drop happening to the common CG of the select byte. The traditional common SL is preferably replaced by eight pairs of BLs and SLs for more reliable programming of the traditional EEPROM cell array plus no GBL is for byte size reduction. Like 1^{st} objective, the byte layout area reduction does not sacrifice the P/E endurance performance performed in unit of byte and page for those high changing rate of data storage application.

The third (3^{rd}) object of this invention discloses a novel set of positive erase and erase inhibit bias voltage combinations for WLs, CGs, BLs and SLs for the selected and unselected bytes in the selected page (or WL) and unselected pages (or WLs) of the preferable 2T FLOTOX-based EEPROM cell array structures without GBL of the present invention. The preferable erase and erase voltages are coupled directly from BLs to the selected cells' channel regions along with the floating of selected SLs to effectively reduce the voltage drop between gate and channel of EEPROM cells so that FN-tunneling effect would not happen or drastically reduced. Like the traditional EEPROM, the desired erase Vt is set to be positive about +2.0V.

The fourth (4^{th}) object of this invention discloses a novel set of positive program and program inhibit bias voltage combinations for WLs, CGs, BLs and SLs for the selected and unselected bytes in the selected page (WL) and unselected pages (WLs) of the preferable 2T FLOTOX-based EEPROM cell array structures without GBL of the present invention. The preferable erase and erase voltages are coupled directly from BLs to the selected cells' channel regions along with the floating of selected SLs to effectively reduce the voltage drop between gate and channel of EEPROM cells so that FN-tunneling effect would not happen or drastically reduced. Like the traditional EEPROM, The desired erase Vt is set to be −2.0V that is negative below 0V.

The fifth (5^{th}) object of this invention discloses a novel set of positive erase and erase inhibit bias voltage combinations for WLs, CGs, BLs and SLs for the selected and unselected bytes in the selected page (or WL) and unselected pages (or WLs) of the preferable 2T FLOTOX-based EEPROM cell array structures without GBL of the present invention. But unlike the 3^{rd} objective, the preferable erase and erase inhibit voltages are coupled directly from SLs to the selected cells' channel regions along with the floating of selected SLs to effectively reduce the voltage drop between gate and channel of EEPROM cells so that FN-tunneling effect would not happen or drastically reduced. Like the traditional EEPROM, The desired erase Vt is set to be positive about +2.0V.

The sixth (6^{th}) object of this invention discloses a novel set of positive program and program inhibit bias voltage combinations for WLs, CGs, BLs and SLs for the selected and unselected bytes in the selected page (WL) and unselected pages (WLs) of the preferable 2T FLOTOX-based EEPROM cell array structures without GBL of the present invention. But unlike the 4^{th} objective, the preferable erase and erase voltages are coupled directly from SLs to the selected cells' channel regions along with the floating of selected SLs to effectively reduce the voltage drop between gate and channel of EEPROM cells so that FN-tunneling effect would not happen or drastically reduced. Like the traditional EEPROM, The desired erase Vt is set to be −2.0V which is negative below 0V.

The seventh (7^{th}) object of this invention discloses many novel sets of positive erase and erase inhibit bias voltage plus program and program inhibit voltage combinations coupled directly from BLs or SLs for WLs, CGs, BLs and SLs for the selected and unselected bytes in the selected page (or WL) and unselected pages (or WLs) of the preferable 2T FLOTOX-based EEPROM cell array structures without GBL of the present invention. But the preferable erase Vt is set either −2.0V or +2.0V and the program Vt is set to be either +2.0V or −2.0V as claimed in the above 3^{rd} objective through 6^{th} objective.

The eighth (8^{th}) object of this invention discloses many novel sets of positive erase and erase inhibit bias voltage plus program and program inhibit voltage combinations coupled directly from BLs or SLs for WLs, CGs, BLs and SLs for the selected and unselected bytes in the selected page (or WL) and unselected pages (or WLs) of the preferable 2T FLOTOX-based EEPROM cell array structures with GBL of the present invention. But the preferable erase Vt is set either −2.0V or +2.0V and the program Vt is set to be either +2.0V or −2.0V as claimed in the above 3^{rd} objective through 6^{th} objective.

The ninth (9^{th}) object of this invention discloses a novel preferable 2T Flotox-based EEPROM array architecture addressing for higher memory density application. The EEPROM array comprises of a plurality of long pages. Each long page is further divided into a plurality of sectors. Each sector comprises of a plurality of bytes with one shared SL in x-direction along with only one common GBL, which is physically connected to the drain of a Byte-select HV NMOS transistor with its gate tied to WLn to generate the desired common CGn voltage for proper program, erased and read operations. In this architecture, the voltage of CGn for the local sector would have a Vt drop below +16V during program or erase operation. All the desired program, program-inhibit, erase and erase-inhibit voltages are set to be positive only.

The tenth (10^{th}) object of this invention discloses a novel preferable 2T Flotox-based EEPROM array architecture addressing for higher memory density application. The EEPROM array comprises of a plurality of long pages. Each long page is further divided into a plurality of sectors. Each sector comprises of a plurality of bytes without one shared SL but replaced by eight (8) separate SLs in y-direction along with only one common GBL, which is physically connected to the drain of a Byte-select HV NMOS transistor with its gate tied to WLn to generate the desired common CGn voltage for proper program, erased and read operations. In this architecture, the voltage of CGn for the local sector would have a Vt drop below 16V during program or erase operation. All the preferable program, program-inhibit, erase and erase-inhibit voltages are similarly set to be positive only.

As opposite to above 1^{st} to 10^{th} objectives using all positive voltages for erase, erase-inhibit, program and program inhibit operations, the eleventh (11^{th}) object of this invention discloses new preferable combination sets of program and program-inhibit voltages with the desired negative voltages, VNN. The VNN voltages ranging from −1 to −8V coupled to the common gate of selected bytes to allow the less HV applied to cells' channels during the program and program-inhibit operations. As a result, the channel lengths of EEPROM cells can be further reduced and the risk of the cells' punch-through can be reduced. The proper negative bias on the selected gate would not sacrifice the 1M P/E cycles spec down to single byte;

As opposite to above 1^{st} to 11^{th} objectives using either positive-only or associated negative voltages for erase, erase-inhibit, program and program inhibit operations for both erase and program in unit of byte or page for EEPROM memory, the twelfth (12^{th}) object of this invention discloses new preferable combination sets of program and program-inhibit voltages for erase in unit of multiple pages and blocks but still keep program operation in unit of single byte and page of EEPROM memory.

As opposite to above 1^{st} to 12^{th} objectives using either positive-only or associated negative voltages for erase, erase-inhibit, program and program inhibit operations for both erase and program in unit of byte or page for EEPROM memory, the thirteenth (13^{th}) object of this invention discloses new preferable combination sets of program and program-inhibit voltages for erase and program in unit of single bit of EEPROM memory.

The fourteenth (14^{th}) object of this invention discloses a novel preferable hybrid NVM array architecture that integrates the Flotox-based 2T EEPROM memory for byte-alterable data storage and the Flotox-based 2T NOR memory for page-alterable code storage on a same die for the most cost-effective and flexible NVM design. Both NOR and EEPROM comprise of a plurality of sectors. Each sector is further comprises of a plurality of pages. And each page is further comprises of a plurality of bytes. Each byte is preferably comprises of eight vertical BLs and one shared horizontal SL without or with one GBL or comprises of eight vertical BLs and eight vertical SLs without or with one GBL. As a result, the x-pitch of EEPROM array is made identical to the x-pitch of NOR array. Therefore, the flexible memory partition between NOR and EEPROM can be achieved. The defined Vts and FN tunneling schemes for erase. Erase-inhibit, program and program-inhibit operations for three on-chip NVM memories can be flexibly defined respectively to keep the respective desired P/E endurance cycle specs.

The fifteenth (15^{th}) object of this invention discloses a preferable circuit of X-decoder of a novel hybrid NVM array architecture that integrates the Flotox-based 2T EEPROM memory for byte-alterable data storage and the Flotox-based 2T NOR memory for page-alterable code storage on a same die for the most cost-effective and flexible NVM design. The X-decoder has 3 levels of WL decoding scheme. And the logic of the disclosed X-decoder design allows the selection of flexible number of WLs to be selected for erase operation to save the erase time drastically. The number of WLs to be flexibly selected for erase is set to be 2ⁿ, where n value is set to be 1 to 3 for each block.

### DETAILED EXPLANATION OF THE PRESENT INVENTION

FIG. 1A, 10, shows a typical Flotox-based 2T EEPROM cell circuit of both prior art and the present invention. It comprises of two HV NMOS transistors such as 1-poly BL-ST transistor and 2-poly floating-gate FT transistor. The top BL-ST transistor is called the Bitline-Select transistor and is used to protect the bottom FT storage cell from being disturbed when 16V is applied to BL during the program operation. The source of FT is denoted as SL, and the drain of the BL-ST is denoted as BL. The gate of BL-ST is denoted as WL, while the gate of FT is denoted as CG. Note, WL stands for word line and CG stands for Control-gate of the floating-transistor. This 2T EEPROM cell typical has cell size of 100λ² and is the largest NVM cell size so far. The on-chip operation needs maximum positive 16V VPP1 as shown in the attached tables.

FIG. 1B, 12, shows the cross-sectional view of the 2T EEPRPM cell shown in FIG. 1A. The CG on top is formed by the Poly2 layer used in peripheral devices. The floating-gate layer, FG, of FT is made of Poly1. The gate of BL-ST can be made of either Poly 1 or Poly2 layer. The selection of either Poly1 or Poly 2 is subject to the preferable process. A deep BN layer is formed to surround the tunneling window at the drain side of the FT transistor for longer life of P/E endurance cycles. Similarly, another BN+ layer is also formed at the source side of FT to make sure no electric disconnection of SL to the source node of FT below FG. All BL-ST and FT transistors are formed on top of P-substrate.

FIG. 1C, 14, shows a Flotox-based 1T NOR cell circuit of the present invention. It comprises one HV 2-poly floating-gate FT transistor only without a BL-ST transistor connected on top as shown in FIG. 1A. Without the top BL-ST transistor of FT, FT storage cell will not be protected from being disturbed when 16V is applied to BL during the program operation. Therefore a bias condition to reduce the BL program disturb is proposed by the present invention. The source of FT is also denoted as SL, and the drain of FT is denoted as BL along with the gate of FT is denoted as WL.

FIG. 1C's 1T NOR cell's bias condition is the same as FIG. 1A's 2T EEPROM cell, except it does not have BL-ST, and its FT's gate's name is changed from CG to WL. Therefore, the bias condition of FIG. 1E˜2B can be all applicable to FIG. 1C's cell, except the column ‘WL’ need to be removed, and the column ‘CG’ need to be renamed to ‘WL’.

The FIG. 1D, 16, shows the cross-sectional view of the 1T NOR cell shown in FIG. 1C. The FT cell of FIG. 1D is exactly identical to the FT of FIG. 1A but the drain node of BL layer is directly connected BL instead.

FIG. 2A, 18, shows a Flotox-based 0.5T NAND string cell circuit of the present invention. The NAND string comprises of N Flotox-based 2-poly FTs connected in series with the top node denoted as BL and the source node denoted as SL. Unlike the traditional NAND string, the top and bottom BL-ST transistors are not required. Each gate of FTn is connected to the corresponding WLn. Whole N FT transistors are formed on top of P-substrate.

The FIG. 2B, 20, shows the cross-sectional view of the 1T NOR cell shown in FIG. 2A. The FT cell of FIG. 2B is made exactly identical to the FT of FIG. 1A but the drain node of BL layer is directly connected BL instead.

FIG. 1E shows a set of regular positive bias conditions for operating the single 2T EEPROM cell shown in FIG. 1A. The bias conditions are disclosed for five key operations such as Erase, Erase-Inhibit, Program, Program-Inhibit and Read. The bias conditions have to be properly coupled to four key nodes of each 2T EEPROM cell for the preferable operations. The four nodes include WL, CG, BL and SL with P-substrate being tied to ground level. The Inhibit voltage is preferably coupled from BL.

FIG. 1F shows a set of bias conditions for operating the single 2T EEPROM cell shown in FIG. 1A. But the negative HV VNN1, positive VVP1, VPP2, and VPP5 are combined for another program scheme of the present invention. The bias conditions are also disclosed for five key operations such as Erase, Erase-Inhibit, Program, Program-Inhibit and Read. The bias conditions have to be properly coupled to four key nodes of each 2T EEPROM cell for the preferable operations. The four nodes include WL, CG, BL and SL with P-substrate being tied to ground level.

FIG. 1G shows a set of bias conditions for operating the single 2T EEPROM cell shown in FIG. 1A. But the negative HV VNN1 and positive VVP1 and, VPP2 and VPP5 are combined for another program scheme of the present invention. The bias conditions are also disclosed for five key operations such as Erase, Erase-Inhibit, Program, Program-Inhibit and Read. The bias conditions have to be properly coupled to four key nodes of each 2T EEPROM cell for the preferable operations. The four nodes include WL, CG, BL and SL with P-substrate being tied to ground level.

FIG. 1G shows further another set of regular positive bias conditions for operating the single 2T EEPROM cell shown in FIG. 1A. The bias conditions are disclosed for five key operations such as Erase, Erase-Inhibit, Program, Program-Inhibit and Read. The bias conditions have to be properly coupled to four key nodes of each 2T EEPROM cell for the preferable operations. The four nodes include WL, CG, BL and SL with P-substrate being tied to ground level.

The major difference between FIG. 1G from FIG. 1E is the preferable Inhibit voltage is coupled from SL instead of the present invention.

FIG. 1H shows further another set of regular positive bias conditions for operating the single 2T EEPROM cell shown in FIG. 1A. The major difference between FIG. 1H from FIG. 1E is the preferable program and erase operations are reversed. The erase Vt become is VtL but the program Wt becomes VtH of the present invention.

FIG. 1I shows further another set of regular positive bias conditions for operating the single 2T EEPROM cell shown in FIG. 1A.

The major difference between FIG. 1I from FIG. 1E is the preferable program and erase operations are performed in unit of bit as oppose to the erase and program operation in unit of byte shown on FIGS. 1E, 1B, 1C and 2A. This bit-write feature shows no separate erase and program operation. Erase can be program and vice versa.

Further explanation of the present invention is continued below.

As explained above, the FLOTOX-based 2T EEPROM NMOS Non-Volatile-Memory, NVM, has been extensively used in market place for more than three decades since its first introduction in 1980. The byte-alterable function is the most popular application spec to meet along with a stringent endurance requirement of more than 1 million cycles per byte. The change of single byte data of EEPROM to the desired value is traditionally referred as a byte-write operation. The course of the traditional byte-write operation involves two sub-steps that involve HV stress and operation.

The first sub-step of byte-write is to carry out a FN byte-erasure operation, in which the eight selected cells' Vt are collectively increased to a desired positive value such as +2.0V, regardless of their initial Vts or the stored data of “1” or “0”. Right after byte-erase, it is then automatically followed by a second sub-step of FN byte-program. The FN byte-program would selectively decrease part or all the eight selected cells' Vt from +2.0V to a desired negative value below 0V such as −2.0V. The FN byte-erasure operation is designed to apply a preferable +16.0V to the gates of the eight selected cells to favor the electrons injection from FT cells' channel region to FT cells' floating-gate layer to achieve a high Vt value above +2.0V. The cell's Vt of +2.0V is referred as a non-conduction state storing a binary data of “1.” After the successful FN byte-erasure, all eight selected cells' Vt should be collectively increased above the set value of +2.0V. The time for erase in unit of byte, page or sectors takes about 1 mS similarly in today's EEPROM production record.

By contrast, the subsequent byte-program operation is to apply +16.0V reversely to the selected FN cells' tunneling channel region along a grounded gate for inducing the FN-tunneling effect. As a consequence, the selected cells' Vt is decreased to a lower desired value of −2.0V. The cell's Vt of −2.0V is referred as a conduction state storing a binary data of “0.” In a single FN byte-erasure, all eight FT cells are erased collectively and simultaneously, while the byte-program only the selected cells out of eight are programmed. After program, the electrons are expelled out from the floating-gate layer into the channel regions of all selected programmed cells, thus the Vt is decreased. The time of either byte-program or page program takes about 1 mS similarly due to the low FN program current.

A completion of a successful byte-write operation means all the selected eight EEPROM cells have gone through both FN erase and FN program operations, regardless of their initial Vt states of “1” (VtH) or “0” (VtL). After the completion of first step of a byte-erasure done in about 1 mS, all eight cells' data become “1.” After a byte-program operation, some selected cells of “1” data would be programmed into “0” data done in about 1 mS. Both EEPROM Program and Erasure operations are employing the low-current FN channel tunneling scheme that is suitable for the erasure size in units of byte, page and sector. The most important erasure and program size of 2T FLOTOX-based EEPROM is performed in unit of single byte with a very high P/E endurance cycles under a single LV VDD supply in today's broad EEPROM memory design.

FIG. 3A shows a part of an array circuit of two pages of traditional Flotox-based 2T EEPROM array. Each page comprises of (N+1) bytes. Each byte further comprises of eight regular bitlines such as BL [0]-BL [7] and one GBLn and one vertical SLn, which shared by a plurality of vertical bytes in EEPROM array. The source nodes of eight cells in each byte are connected by a horizontal SL made of N-active layer, which may be formed with BN+ layer. The GBL is connected to the drain node of a Byte-Select transistor denoted as N1a with its gate tied to WL0 or N1b with its gate tied to WL1. The source node of N1a is denoted as CG0 and the source node of N1b is denoted as CG1.

The CG0 is coupled to the common gate of the upper byte with their eight drains respectively connected to BL[0] to BL[7] through eight BL select transistors with gate tied to CG0 and eight source nodes are connected to SL0 in Byte 0. The CG1 is coupled to the common gate of the bottom byte with their drains connected to BL[0] to BL[7] through eight BL select transistors with the common gate tied to CG1 and the eight source nodes connected to SL0. The line of SL0 is shared by the upper and bottom bytes in Byte 0. Similarly, SLN is shared by the upper and bottom bytes in Byte N and one GBLN is also required in the last byte in the page of prior art.

There are at least five major drawbacks in designing the traditional EEPROM array circuit as shown in FIG. 1.

On top of it, the first drawback is the high layout overhead of the undesired adding of one GBL connected to one HV Byte-select NMOS transistor of per each byte of EEPROM array. Due to difficult connection between the source node of N1a or N1b and the common gate of EEPROM floating-gate devices in each byte, the pitch of adding one GBL and one Byte-select transistor per byte would typically take about 2 to 3 BL widths in x-direction and thus increase the effective x-pitch of single byte payout from 8 BLs' widths to about 10 or 11 BLs' widths. That is the undesired increase in layout overhead from 25% to 38%.

The second drawback is a must to reserve the precious layout room for an additional vertical column of one SLn VSS line with one BL width per byte as shown in FIG. 3A of traditional EEPROM array. This SLn BL also increases the effective byte width of EEPROM array from 8 BLs to 9 BLs by another 12.5% in X-dimension. Typically in circuit design, the SLn is designed to be a virtual VSS line and is shard by the multiple vertical bytes located in different pages but is not shared by any adjacent bytes in the same selected page for preventing the leakage from the select byte to N unselected bytes in the same page for safe byte or page program operation.

The third drawback is the concern of channel punch-through when 16V HV is applied to the channel region of eight floating-gate cells of the selected byte through the BL-select transistor connected in series with the floating-gate cell of each 2T EEPROM cell during FN byte-program operation. For 0.18 um EEPROM technology today, the channel length of each Floating-gate cell and each BL-select enhancement transistor are kept larger than 0.6 um and is very difficult to be further scaled down. As a result, the cell size migration below 0.18 um in y-dimension encountering a great challenge.

The fourth drawback of the array in FIG. 3A is the desired highest 16V VPP voltage cannot be fully passed to CG0 or CG1 for faster byte-erase operation in 1 mS. The CGn voltage on the selected byte would have a Vt drop below the voltage applied to WLn during the erase operation. For example, CG0 voltage is one Vt below 16V applied on WL0 during erase operation. The Vt drop is due to the circuit Byte-select transistor of N1a being configured like a Voltage-follower. The drain node of the N1a is connected to 16V coupled from GBL0 and its gate is 16V too coupled from WL0 during byte-program. As a result, CG0 voltage is about 14V that is one Vt below VPP 16V. This Vt is increased from about 0.8V without a body-effect to a value around 2.0V with a 14V body-effect. Both N1a and N1b devices are formed right on top of P-substrate and their bulks are tied to VSS node. The Vt-drop to obtain only 14V on CGo or CG1 would greatly decrease the erase efficiency. Therefore, a Native device is commonly used to replace the enhancement of N1a or N1b. But again, the Native device width and channel length are big from most of the layout design rules. As a result, an improvement over the byte-select transistor in the EEPROM array layout is always needed.

The fifth drawback of the array in FIG. 3A is the voltage of the common virtual-ground node of SLn of the select byte of EEPROM would be increased to the highest level when all eight cells' Vt are at −2.0V, which is the conducting state. Total eight cells current would be increased to about 250 uA for 30 uA each during read operation in wide VDD operation. This high current would possibly increase the SLn node voltage to around 0.5V. This would cause read failure due to low read margin between the gate voltage of the selected cells and their VtL if VDD is operating below 1.8V. Normally, VtL could be increased to near 0V level after many program and erase cycles. As a conclusion, a need to operate EEPROM cells in read operation independent of pattern of the written data in wide VDD environment is needed.

In some particular applications, a bit-alterable EEPROM is demanded. We do not classify it as another major drawback in addition to above five. But this invention also discloses a novel method to provide a set of bias conditions to enable bit-alterable function to enhance the EEPROM functions. The details of the new invention would be explained below in accordance with the drawings and tables attached in this application.

FIG. 3B and FIG. 3C show a set of bias conditions of the program and erase operations for those selected bytes and non-selected bytes in the selected page and non-selected pages of prior art. The VPP HV is defined as the highest positive voltage that can be generated on-chip for both program and erase operations. Typically, in today's EEPROM technology, VPP is tuned to be around +16.0V. None of any negative voltages have even been used in traditional EEPROM design due to no HV NMOS devices are made available within the triple P-well within a deep N-well on top of P-substrate as today's NOR flash process. The detailed explanation of operating the traditional 2T Flotox-based EEPROM cell array can be found everywhere in many published patent applications of prior art and so is skipped here for the simpler description of the present invention.

FIG. 4A shows a new embodiment of a pair of 2-WL circuits of the part of first 2T FLOTOX-based EEPROM cell array of the present invention. Each WL circuit comprises of (N+1) bytes and each vertical common SL is shared by many pairs of two vertical bytes such as one upper byte and one bottom byte. For example, the vertical BL of SL0 is connected to 16 source nodes of two vertically adjacent bytes in FIG. 1A. The gate of eight 1-poly BL-select transistors of upper byte is connected to a common signal of WL0. The common gate of eight Floating-gate transistors below the BL-select transistors of 2T EEPROM cells is connected to a common signal denoted as CG0. Each drain node of the 2-poly Floating-gate storage transistor is connected to the respective source node of BL-select transistor. Similarly, the eight gates of eight 2-poly Floating-gate storage transistor of bottom byte is connected to CG1 and the eight gates of BL-select transistor is connected to WL1 with eight source nodes sharing SL0 with upper byte. In this novel architecture of the present invention, no GBL and the Byte-select transistor of N1a or N1b are needed as shown in FIG. 1. Thus the substantial overhead of GBL added in each byte of traditional EEPROM array as shown FIG. 1 is completely eliminated. As a result, a huge saving in silicon area plus the same 1M P/E cycles can be accomplished by the new cell array shown in FIG. 4A. Now, the detailed explanation to achieve the same 1M P/E endurance cycles of prior art will be disclosed below.

Unlike FIG. 1A, no extra GBL is required in addition to the regular eight (8) regular BLs in the byte layout.

Since GBL is no longer needed, thus the additional Select Transistor, N1a or N1b, is also removed. As a result, any single byte of EEPROM layout just needs eight BLs plus one vertical SLn. The whole page of EEPROM array is now comprised of multiple bytes cascaded in x-direction. All the gates of 1-poly BL-Select transistors in the same page are connected to one common signal line of WLn running in horizontal direction, and similarly, all the control gates of 2-poly floating-gate transistors are connected together to a signal line of CGN without Byte-Select transistors such as N1a and N1b. One big advantage of these novel byte-architectures, the floating-gate voltage of CGN has been increased about 2.0V because the Vt drop of N1a or N1b is fully eliminated. As a result, the higher voltage of CGN would result in larger coupling voltage from cell's Poly 2-gate to Poly1-floating layer so that the faster erase time can be achieved.

FIG. 4B shows a set of bias conditions for the selected byte and the unselected bytes in the same selected WL during the FN erase operation for FIG. 4A, the 2T Flotox-based EEPROM cell array of the present invention. There are four key control bias voltages for operating each 2T EEPROM cell. These four control signals are coupled to the four terminals of 2T EEPROM cell. These four terminals include the first terminal of drain node, which is connected to BL, and the second and third terminals of two gate nodes. The top gate is connect to WL, which is the gate of 1-poly BL-select transistor and the bottom gate is connected to CG, which is the gate of the 2-poly Floating-gate of EEPROM cell. The fourth terminal of EEPROM cell is the source node, SL.

The bias conditions set in the FIG. 4B show the proper erase and program conditions down to byte level. But in fact, the byte-level bias condition has to meet the fundamental bit-level EEPROM cell's bias condition in erase, read and program operations. The breakdown of write operation of the selected bytes and non-select bytes of the present invention is further explained below. Note, the number of select bytes Na and non-select bytes, Nb, are flexible. The total number of bytes N+1 is expressed in the following equation for FIG. 4A. When Na is increased, then Nb would be decreased in same amount. The sum of total bytes in each page is constant.

Na+Nb=N+1, where 1≦Na or Nb≦N+1

The other signal names are explained below:

a) VPP1: The highest on-chip voltage, which is 16V,

b) VPP2: The BL inhibit voltage, which ranges from 8V-16V.

c) VPP3: The CG inhibit voltage, which ranges from 0V-8V.

During the page-erase operation, the bias conditions for EEPROM bytes in a select page comprising of WL0 and CG0 are preferably setting WL0=CG0=VPP1 along with 0V on the select bytes' BLs for erase and with VPP2 on the non-select bytes' BLs for erase inhibit. All SLs, SL0-SLN, are preferable left floating to avoid the punch-though leakage current or enhance the punch-through immunity capability.

It should be noted that the entries in FIGS. 4B and 4C: CG=0V/Vdd, and BL [0:7]=0V/Vdd actually mean that either ‘0V or Vdd’ can be used in this case but only voltage (0V or Vdd) will be applied. However, for FIG. 4C, BL [0:7]=VPP1/FL, has a different meaning. It means the selected BLs for programming data ‘0’ are applied with VPP1, and the BLs for data ‘1’ is left floating (FL) for program-inhibit.

For those unselected bytes in the non-select pages comprising of a plurality of WL1 and CG1, are preferably setting WL1=VPP3 and CG1=0V along with 0V on the select bytes' BLs for erase and with VPP2 on the non-select bytes' BLs for erase inhibit. All SLs, SL0-SLN, are preferable left floating to avoid the punch-though leakage current or enhance the punch-through immunity capability. The reason to apply VPP2 of 8V-16V to the BL[0]-BL[7] of non-selected bytes is to reduce to the cells' channel region of the non-selected bytes with VPP1 16V on the CG0. The VPP2 of BL[0]-BL[7] are coupled to the all channel region through Byte-select transistors with their gate being coupled to VPP1 of 16V. As a result, the effective channel voltages would be kept same voltage of VPP2 as the inhibit voltages on BLn because 16V is almost double of VPP2 to allow VPP2 being fully passed without drop.

Since the typical coupling ratio from Poly2 to Poly1 in EEPROM cell is 60%, thus the effective voltage drop between the P1-floating layers would be 9.6V, but the coupling ratio from channel to Poli1-layer is about 20%. Thus when 16V on poly2 and 8V on channel, then the final voltage on Ploy1 is 16V×0.6+8V×0.2=10.8V. Therefore, the tunneling-window voltage drop between poly1 and channel region would be 10.8V-8V=2.8V. The 2.8V is the result of the lowest VPP2 bias condition and is something like the voltage bias in high 5V VDD operation on the cell's gate that proves to have enough margin allowing the infinite read cycles with no material disturb to cell's Vt. The higher VPP2 but below VPP1 is superior in Erase-inhibit performance. Extropolately, the effective BL-Inhibit voltage of VPP2 should allow the infinite erase inhibit cycles meeting the spec of 1M P/E cycles.

On the contrary, the WL-Inhibit voltage in page-erase operation is achieved by applying a preferable VPP3 on the WL of the non-select pages such as WL1 of the second page. Since VPP3 ranges from 0V to 8V so that the voltage drop between the edge of gate and drain of unselect WL1 is about 16V to 8V (VPP2−VPP3=16V−0V=16V or 16V−8V=8V). This is to drastically reduce the level of Byte-erase disturbance of non-selected cells in the non-selected vertical bytes in the multiple non-selected pages. In real experiment, VPP3 below 5V is more preferable but the decision is more subject to the silicon P/E cycle performance that may vary in different fabs.

As oppose to FIG. 4B, FIG. 4C shows another set of bias conditions for the selected bytes and the unselected bytes in the selected and unselected pages during the FN page Program and Program-Inhibit operations for FIG. 4A of the present invention.

During the page-program operation, the bias conditions for EEPROM bytes in a select page comprising of WL0 and CG0 are preferably setting WL0=VPP1 and CG0=0V along with “floating at 0V” on the select bytes' BLs for program-inhibit to keep “1” data and with VPP1 to program “0” data to remove the electrons out of floating gate. Besides, for the remaining unselected program cells in the selected page, the voltages on BL[0] to BL[7] should be kept floating for Program-Inhibit.

For those unselected bytes in the non-select pages comprising of a plurality of WL1 and CG1, are preferably setting WL1=VPP3 and CG1=0V or VDD along with floating voltage on the selected BLs along with VPP1 on the non-select bytes' BLs for Program-Inhibit. Like page-erase operation, all SLs, SL0-SLN, are preferable left floating to avoid the punch-though leakage current or enhance the punch-through immunity capability. The reason to apply VPP3 of 8V-16V to the WLs of non-selected pages is to reduce to the HV voltage drop between the edge of WL and BL of non-select cells in the non-select pages so that the unselected cells' Vt would not be degraded so that 1M P/E cycles can be achieved like traditional EEPROM array.

FIG. 5A shows another new embodiment of a pair of 2-WL circuits of the part of 2T FLOTOX-based EEPROM cell array of the present invention. Similarly, each WL or page comprises of (N+1) bytes and each vertical common SL is shared by a plurality of pairs made of two vertical adjacent bytes such as one upper byte and one bottom byte. Like FIG. 4A, for example, the vertical SL0 has one BL pitch and is being connected to 16 source nodes of two vertically adjacent bytes in FIG. 5A. The gates of eight 1-poly BL-select, BL-ST, transistors of upper byte is connected to a common signal of WL0. The common gate of eight Floating-gate transistors, FT, below BL-ST of 2T EEPROM cells are connected to a common signal denoted as CG0. The difference between FIG. 5A and FIG. 3A are two. In this novel architecture of the present invention, no GBL and the FT-ST transistor such as N1a or N1b are needed as shown in FIG. 1. Instead, each EEPROM cell has one dedicated pair of vertical BL and SL connecting to respective drain and source and running perpendicular to WL and CG. As a result, this new EEPROM byte layout architecture ends up with eight SLs such as SLn[0]-SLn[7] and eight BLS such as BLn[0]-BLn[7].

There are two major advantages of this new embodiment as compared to the traditional EEPROM byte scheme as shown in FIG. 1.

The first advantage is the single byte-area reduction in x-dimension, in which the saving is about 40%. Firstly, this is mainly due to the big and relaxed EEPROM cell size in layout plus the availability of multiple metal layers. Therefore, there is still a room to add eight SLs on top of eight existing BLs with upper metals so that no any extra room needed in x-pitch of a byte. Secondly, the additional GBL and SL take about 3 BL pitch overhead out of 8 BLs.

The second advantage of adding eight SLs for eight respective BLs is to completely eliminate the BL punch-through leakage issue between the adjacent BLs in the selected byte that shares the common SL as shown in FIG. 3A during the byte-program operation. During the byte-program operation in FIG. 3A byte architecture, it requires to apply VPP1 to the selected cells' drain nodes through the selected BLs of selected bytes for program and 0V to the deselected cells' BLs for program-Inhibit. When punch-through happens on the selected BLs, the VPP1 on the selected BLs would leak to the 0V of the deselected BLs. As a result, the program operation would fail or slow down out of spec. When each EEPROM bit has its own separate dedicated BL and SL and no sharing SL in between adjacent bits in same selected byte, the VPP1 voltage on the BL in the selected bits would flow back to its own SL. Thus the program operation VPP1 voltage would not be lowered down and FN program operation is being secured without failure.

Like FIG. 4A, the whole page of EEPROM array now consists of multiple bytes cascade in x-direction. All the gates of select transistors in a page are connected to one common signal WLn, and all the control gates of EEPROM cell are connected together to CGN without any Byte-select transistor N1a or N1b. Similarly to FIG. 4A, one big advantage is the gate voltage of CGN has been increased about 2.0V because the Vt drop of N1a is being eliminated. As a result, the higher gate voltage of CGN would perform faster erase time.

FIG. 5B shows a set of bias conditions for the selected byte and the unselected bytes in the selected pages and unselected pages during the FN Erase and Erase-Inhibit operations for FIG. 5A, the new 2T Flotox-based EEPROM cell array of the present invention. The bias conditions are set to be different for one selected byte and the remaining unselected bytes on the same page so that the least program and erase disturbance can be achieved for maintaining longer endurance cycles.

During the page-erase operation, the bias conditions for EEPROM bytes in a select page comprising of WL0 and CG0 are preferably setting at VPP1 such that WL0=CG0=VPP1 along with 0V on the select bytes' BLs for Erase and with VPP2 on the unselect bytes' BLs for Erase-Inhibit in the same selected page. All SLs, SL0-SLN, are preferable left floating to avoid the punch-though leakage current or enhance the punch-through immunity capability.

For those unselected bytes in the non-select pages comprising of a plurality of WL1 and CG1, are preferably setting at a value so that WL1=VPP3 and CG1=0V along with 0V on the select bytes' BLs for erase and with VPP2 on the unselect bytes' BLs for erase inhibit. All SLs, SL0-SLN, are preferable left floating to avoid the punch-though leakage current or enhance the punch-through immunity capability. Like FIG. 4A, the reason to apply VPP2 of 8V-16V to the BL[0]-BL[7] of non-selected bytes is to reduce to the cells' channel region of the non-selected bytes with VPP1 16V on the CG0. The VPP2 of BL[0]-BL[7] are coupled to the all channel region through Byte-select transistors with their gate being coupled to VPP1 of 16V. As a result, the effective channel voltages would be kept same voltage of VPP2 as the inhibit voltages on BLn because 16V is almost double of VPP2 to allow VPP2 being fully passed without drop.

On the contrary, the WL-Inhibit voltage in page-erase operation is achieved by applying a preferable VPP3 on the WL of the unselect pages such as WL1 of the second page. Since VPP3 ranges from 0V to 8V so that the voltage drop between the edge of gate and drain of unselect WL1 is about 16V to 8V (VPP2−VPP3=16V−0V=16V or 16V−8V=8V). This is to drastically reduce the level of Byte-erase disturbance of unselected cells in the unselected vertical bytes in the multiple unselected pages. In real experiment, VPP3 below 5V is more preferable but the decision is more subject to the silicon P/E cycle performance that may vary in different fabs.

As oppose to FIG. 5B, FIG. 5C shows another set of bias conditions for the selected bytes and the unselected bytes in the selected and unselected pages during the FN page Program and Program-Inhibit operations for FIG. 5A of the present invention.

During the page-program operation, the bias conditions for EEPROM bytes in a select page comprising of WL0 and CG0 are preferably setting WL0=VPP1 and CG0=0V along with “floating at 0V” on the select bytes' BLs for program-inhibit to keep “1” data and with VPP1 to program “0” data to remove the electrons out of floating gate. Besides, for the remaining unselected program cells in the selected page, the voltages on BL[0] to BL[7] should be kept floating for Program-Inhibit.

For those unselected bytes in the unselect pages comprising of a plurality of WL1 and CG1, are preferably setting WL1=VPP3 and CG1=0V or VDD along with floating voltage on the selected BLs along with VPP1 on the unselect bytes' BLs for Program-Inhibit. Like page-erase operation, all SLs, SL0-SLN, are preferable left floating to avoid the punch-though leakage current or enhance the punch-through immunity capability. The reason to apply VPP3 of 8V-16V to the WLs of unselected pages is to reduce to the HV voltage drop between the edge of WL and BL of unselect cells in the unselect pages so that the unselected cells' Vt would not be degraded so that 1M P/E cycles can be achieved like traditional EEPROM array.

FIG. 6A EEPROM array architecture is the derivative of FIG. 5A and of FIG. 4A when memory density increase is required. This can be done by keeping the same page length size in x-dimension but instead increasing the number of vertical pages. Another way to do that is to keep the number of pages constant in y-dimension, but instead each page length size is increased in X-dimension as shown in FIG. 6A. Each new longer length of page is preferably comprised of a plurality of sectors. Each sector in one page is further comprised of only one common GBL and one byte-select transistor (N1a) and K+1 bytes sharing with one vertical SL per byte as shown in FIG. 4A.

The major difference between FIG. 4A and FIG. 6A is the voltage level of CGn. In FIG. 4A, CGN is fully coupled to VPP1 16V directly in erase operation without any Vt drop to keep the faster program time because the cell array does not have addition Byte-select transistor like N1a. But in FIG. 6A, the CGN is coupled to VPP1-Vt of N1a during page erase operation. The voltage of VVP1-Vt is about 14V coupled to CGn in FIG. 6A circuit. In order to keep the same erase speed, the Byte-select transistor of Native device with less Vt will make the voltage of local CGn in each sector close to VPP1. Thus, the EEPROM array of FIG. 6A should have the same P/E cycle performance as the one shown in FIG. 4A. But since K+1 bytes share one GBL, the area overhead increase of the layout of FIG. 6A is still minimal as compared to the conventional one shown in FIG. 1.

FIG. 6B illustrates a larger page with (K+1) sectors according the circuit shown in FIG. 6A.

The total number of bytes in this larger page size is increased from (N+1) bytes one sector in FIG. 4A to K+1 sectors of (K+1)×(N+1) bytes shown in FIG. 6A. The key operations of each sector are kept identical as the only one sector of (N+1) bytes in FIG. 4A. Thus the detailed description is skipped here for simpler explanation of the present invention.

Similar to Table2a, FIG. 6C shows a set of bias conditions for the selected byte and the unselected bytes in the same selected but larger WL page size during the FN erase operation for FIG. 6A, the 2T Flotox-based EEPROM cell array of the present invention. The bias conditions of Erase and Erase-Inhibit are preferably set to be different for the selected bytes and unselected bytes in the selected sector and the unselect bytes in the unselected sectors on the unselected pages. In this method, both program and erase disturbance is drastically reduced, thus the same longer P/E endurance cycles can be met.

As opposite to FIG. 6C, FIG. 6D shows another set of bias conditions for the selected byte and the unselected bytes in the selected sector or unselected sectors of the selected larger page during the FN program operation for FIG. 6A, the 2T Flotox-based EEPROM cell array of the present invention. The bias conditions are set to be different for the selected bytes and the remaining unselected bytes on the same selected sectors or unselected sectors of the selected and unselect larger page so that the least program and erase disturbance can be achieved.

FIG. 7A EEPROM array architecture is the further another derivative of FIG. 6A by only changing the common SL for each byte to individual SL for each BL. Memory density is also increased by increasing the page length in X-direction.

The difference between FIG. 6A and FIG. 7A is the SL. In FIG. 6A, the SL is shared between two vertical bytes, while in FIG. 7A is no shared SL. Instead, total eight pairs of eight vertical BLs and eight vertical SLs are connected respectively to eight drains and sources of single byte of eight 2T EEPROM cells. The EEPROM array of FIG. 7A should have the same P/E cycle performance as the one shown in FIG. 5A.

FIG. 7B shows a large page with [K+1] Sectors according the circuit of FIG. 7A.

Like FIG. 6A, the total number of bytes in this larger page size is increased from (K+1) bytes in one sector in FIG. 5A to (K+1)×(N+1) bytes in (K+1) sectors as shown in FIG. 7A. The key operations of each sector comprising of (N+1) bytes in one page is designed to be the same as (N+1) bytes of one page in FIG. 4A.

Similar to FIG. 5B and FIG. 5C, FIG. 7C and FIG. 7D show a set of bias conditions for the selected byte and the unselected bytes in the selected pages and unselected pages but having larger page size during the FN Erase, Erase-Inhibit, Program and Program-Inhibit operations for FIG. 7A, the 2T Flotox-based EEPROM cell array in higher density of the present invention. The bias conditions are set to be different for the selected bytes in the selected sectors and the remaining unselected bytes in the unselected sectors in the selected page or the remaining unselected sectors of unselected pages so that the least program and erase disturbances can be achieved for maintaining longer endurance cycles.

Like FIG. 6A, the detailed descriptions of Program, Program-Inhibit, Erase and Erase-Inhibit are skipped here for simpler explanation without losing the scope and spirit of the present invention.

FIG. 8A is the another preferable derivative circuit of FIG. 4A, in which it shows a similar page but without being divided into sectors of the 2T FLOTOX-based EEPROM cell array of the present invention. Each page comprises of (N+1) bytes and all vertical bytes are sharing one common vertical SL. The reason we cannot have sector circuit like FIG. 6A is because the negative gate voltage, VNN1, cannot be connected to any Byte-Select NMOS device that is not made in a triple P-well within a deep N-well on top of P-substrate. In traditional EEPROM array, it does not have any triple P-well NMOS device. Thus, the larger page size in higher density cannot be divided into a plurality of smaller sectors like the approach shown in FIG. 6A array circuit that only uses positive VPP voltage only.

Similarly to the prior art of EEPROM cell array, in this novel EEPROM array organization, each page has (N+1) independent bytes with a layout being cascaded in X-direction and (N+1) independent SLs that is connected to the common source nodes of all vertical bytes running in Y-direction.

In order to achieve the same high-density of a large page size comprising of (K+1) sectors with each sector comprising of (N+1) bytes like FIG. 6A, this invention can expend the page size by cascading total (N+1)×(K+1) bytes in one large page without any GBLs and Byte-select transistor N1a. The program negative VNN1 voltage is coupled to the whole length of CGn. In this way, one advantage of this larger page size of FIG. 8A ends with a smaller size silicon area than the one in FIG. 6A. But the disadvantage of the large page of FIG. 8A is, its P/E endurance cycles would be inferior to the one of FIG. 6A.

The difference between FIG. 6A and FIG. 8A is the FN program bias condition. In FIG. 6A, only the positive HV voltages were used for FN Program, Program-Inhibit and FN Erase and Erase-Inhibit operations in selected and unselected bytes of selected and unselected pages. But In FIG. 8A, a novel medium negative HV, VNN1, is proposed for the FN Program and Program-Inhibit operations. In traditional FN program, the gate of FT is biased at 15V for program along with channel of FT at 0V or floating for program-Inhibit. Since 15V needs to be applied to the drain nodes of the selected cells, the big voltage drop between the drain node and source nodes during FN program operation would prohibit the EEPROM cell's channel length from being scaled down. As opposite to the traditional approach, a negative MHV is applied to the gate of FT, thus the HV program voltage on the drain node of the selected programmed cells can be reduced to achieve the same FN tunneling window voltages thus effect between the FT's gate and the channel. As a result, the cell's channel length can be further reduced and the BL programmed disturbance is also drastically reduced. Plus, the EEPROM chip can generate the required negative voltage between −1.0V to −7.0V without a need of triple P-well (TPW) HV NMOS devices in the peripheral area. The required negative MHV voltage has been proven to be generated on-chip by using the existing PMOS-diode and capacitor charge pump circuit. The required negative program voltages for FT's gate of the selected bytes in the selected sectors of the selected page can passed to the selected single CG or selected multiple CG with preferable negative voltages, ranging from −1V to −8V. In this case, the required BL program voltage of VPP1 in traditional EEPROM bias conditions can be reduced to VPP5, which preferably ranges from 8V to 10V. As a result, almost one half of the BL program voltage can be used, thus the EEPROM cell's scaling can be achieved below 0.13 um with small cell pitch in y-dimension.

Like FIG. 6C, the FIG. 8B shows a similar set of positive-only HV bias conditions for the selected bytes and the unselected bytes of the selected and unselected large pages during the FN Erase and Erase-Inhibit operations for FIG. 8A, the 2T Flotox-based EEPROM cell array of the present invention. The bias conditions are set to be different for selected bytes and the unselected bytes of selected and unselected sectors in selected and unselected pages so that the least program and erase disturbance can be achieved for maintaining longer endurance cycles.

As opposite to FIG. 8B, FIG. 8C shows another new set of bias conditions of both positive and negative HV combination for the selected bytes and the unselected bytes in the selected page and unselected large pages during the FN program operation for FIG. 8A.

FIG. 9A is like FIG. 5A, it shows a similar pair of 2-WL circuits of another 2T FLOTOX-based EEPROM cell array of the present invention.

Each WL comprises of (N+1) bytes and each byte is sharing one common SL for two vertical adjacent bytes. Similarly to the prior art of EEPROM cell array, in this novel EEPROM array organization, each page has (N+1) independent bytes with a layout being cascaded in X-direction and eight pairs of eight BLs and eight SLs in a single byte of a page without a GBL and VSS to save area.

The difference between FIG. 5A and FIG. 9A is the FN program bias condition. In FIG. 5A, only the positive HV were used for both FN program and FN erase operations, regardless of in unit of byte or page. But In FIG. 9A, a novel medium negative HV, VNN1, is proposed for the FN page program. In traditional FN program, the gate is biased at 0V along with 0V for BL for the unselected programmed bits and at HV of 15V for the selected programmed bits. Since 15V needs to be applied to the drain nodes of the selected cells, the big voltage drop across between the drain node and source nodes during FN program operation would prohibit the EEPROM cell's channel length from being scaling down. As opposite to the traditional approach, a negative VNN1 is applied to the gate, thus the lower HV program voltage, VPP5, on the drain node of the selected programmed cells can be used to achieve the same FN tunneling effect. As a result, the cell's channel length and lower BVDS device of cell can be used, thus the BL programmed disturbance is also drastically reduced. Plus, the lower cell's channel voltages of VPP5 would reduce tremendously generating pairs of hot holes and electrons around the tunneling window so that the longer P/E endurance cycles can be achieved.

Like FIG. 5B, the FIG. 9B shows a similar set of positive-only HV bias conditions for the selected byte and the unselected bytes in the same selected WL during the FN erase operation for FIG. 8A, the 2T Flotox-based EEPROM cell array of the present invention. The bias conditions are set to be different for the selected bytes and the unselected bytes on the selected and unselected pages so that the least program and erase disturbance can be achieved for maintaining longer endurance cycles.

As opposite to FIG. 9B, FIG. 9C shows another new set of bias conditions of both positive and negative HV combination for the selected byte and the unselected bytes in the same selected WL during the FN program operation for FIG. 9A.

Note, from FIG. 4A through FIG. 9A, all the erase-Inhibit voltage or Program-Inhibit voltages are coupled from selected BLs to the channels of selected cells and keep their corresponding SLs floating to prevent the selected cells' channels from punch-through. But another preferable sets of bias conditions for FIG. 10A and FIG. 11A show that the Erase-Inhibit and Program-Inhibit voltages are instead coupled from the selected SLs and the corresponding BLs are left floating. The rest of description of FIG. 10A and FIG. 11A should be the similar to the ones for FIG. 4A through 7. Therefore, the details of operations of FIG. 8A and FIG. 11A are skipped here.

FIG. 10A, 118, is a derivative of FIG. 4A. It shows a similar pair of 2-page circuits of another 2T FLOTOX-based EEPROM cell array of the present invention. Each page comprises of (N+1) bytes and each byte is sharing one common SL. Similarly to the prior art of EEPROM cell array, in this novel EEPROM array organization, each WL has (N+1) independent bytes with a layout being cascaded in X-direction and (N+1) independent SLs that is connected to the common source nodes of all bytes running in Y-direction.

The difference between FIG. 4A and FIG. 10A is the FN erase bias condition. In FIG. 4A, the BL erase and BL erase inhibit voltage are coupled from eight BLs. On the contrary, in FIG. 10A, the erase and erase inhibit voltages of respective selected bytes and unselected bytes are coupled from the respective SLs. In this embodiment of the bias conditions, HV on the WLn used in FIG. 4A, is not used in FIG. 10A. Thus the control signals for erase operation in FIG. 10A is simpler than FIG. 4A.

Like FIG. 4B, the FIG. 10B shows a similar set of positive-only HV bias conditions for the selected byte and the unselected bytes in the same selected WL during the FN erase operation for FIG. 10A, the 2T Flotox-based EEPROM cell array of the present invention. The bias conditions are set to be different for one selected byte and the remaining unselected bytes on the same WL so that the least program and erase disturbance can be achieved for maintaining longer endurance cycles.

As opposite to FIG. 10B, FIG. 10C shows another new set of bias conditions of positive only HV for the selected byte and the unselected bytes in the same selected WL during the FN program operation for FIG. 10A, the 2T Flotox-based EEPROM cell array of the present invention. Similarly, like FIG. 4C, the new bias conditions FIG. 10C are set to be different for one selected byte and the remaining (N) unselected bytes on the same WL so that the least program and erase disturbance can be achieved.

FIG. 11A is the derivative of FIG. 5A. It shows a similar pair of 2-page circuits of another 2T FLOTOX-based EEPROM cell array of the present invention. Unlike FIG. 10A, FIG. 11A has shared common SL in each byte, each page similarly comprises of (N+1) bytes but each byte has eight separate SLs. The difference between FIG. 5A and FIG. 11A is the FN erase bias condition. In FIG. 5A, the BL erase and BL erase inhibit voltages are coupled from eight BLs. On the contrary, in FIG. 11A, the erase and erase inhibit voltages of respective selected bytes and unselected bytes are coupled from the respective eight SLs. In this embodiment of the bias conditions, HV on the WLn used in FIG. 4A, is not used in FIG. 11A. Thus the control signals for erase operation in FIG. 10A is simpler than FIG. 5A.

Like FIG. 5B, the FIG. 11B shows a similar set of positive-only HV bias conditions for the selected byte and the unselected bytes in the same selected WL during the FN erase operation for FIG. 10A, the 2T Flotox-based EEPROM cell array of the present invention. The bias conditions are set to be different for one selected byte and the remaining unselected bytes on the same WL so that the least program and erase disturbance can be achieved for maintaining longer endurance cycles.

As opposite to FIG. 11B, FIG. 10C shows another new set of bias conditions of positive only HV for the selected byte and the unselected bytes in the same selected page during the FN program operation for FIG. 10A, the 2T Flotox-based EEPROM cell array of the present invention. Similarly, like FIG. 5C, the new bias conditions FIG. 10C are set to be different for one selected byte and the remaining (N) unselected bytes on the same WL so that the least program and erase disturbance can be achieved. FIG. 10C also comprises program inhibit conditions.

FIG. 12A is the derivative of FIG. 11A but the definition of FN erase and FN program are reversed for the EEPROM array that comprises of a plurality of pages and each page further comprises of (N+1) bytes of the present invention. Each byte of eight 2T EEPROM cells comprises of eight pairs of eight vertical BLs and eight vertical SLs without any GBL and Byte-select transistors. In other words, the erase negative Vt in FIG. 11A would become the program Vt in FIG. 12A. Similarly, the positive program Vt in FIG. 11A becomes the erase Vt of FIG. 12A.

The FIGS. 12B and 12C show the reversed bias conditions of reversed FN erase and program operations to achieve the reversed Vts for the present invention in the preferable EEPROM array. The erased Vt is set to be negative of about −2.0V and the programmed Vt is set to be positive of around +2.0V. The FN erase and program speed in FIG. 12A should be the same as the cells shown in FIG. 3A through 9.

FIG. 13A is the derivative embodiment of FIG. 11A but the FN erase and FN program operations are performed in unit of single bit, rather than single byte or page. Like traditional EEPROM Vts, the erase Vt value is set to be positive around +2.0V, while the program Vt value is set to be negative around −2.0V.

The FIGS. 13B and 13C are to show the bias conditions of FN erase and program operations in unit of bit in the preferable EEPROM cell array that has no shared SL in every byte of EEPROM array of the present invention.

FIG. 14A shows the preferable EEPROM array comprising of multiple [K+1] pages arranged in y-direction of the present invention. Each page comprises of (N+1) bytes cascaded in x-direction. The page circuit is based on the circuit of FIG. 4A without any overheads of extra GBLs but share SLs of the present invention. The goal of this new EEPROM array is set to achieve the same 1M P/E cycles in unit of byte as the traditional EEPROM array requiring one GBL per each byte.

The erase operation of this novel EEPROM array can be flexibly performed in any desired pages with same time due to the small current is consumed during the FN page erase operation. As a result, the erase time can be greatly reduced in unit of flexible number of pages.

FIG. 14B shows a preferable set of bias voltage condition for flexibly erasing the selected [K+1] pages without inducing any severe Vt disturbance to the rest of EEPROM cells in the unselected pages in the same EEPROM memory array.

FIG. 15A, 128, shows another preferable EEPROM array of the present invention and it is the derivative of FIG. 14A but each byte cells do not share the common SL.

Similarly to FIG. 14A, this new array comprises of multiple pages arranged in y-direction. And each page comprises of (N+1) bytes cascaded in x-direction without having a shared SL in each byte.

FIG. 15B discloses a preferable bias condition for flexibly erasing any number of selected blocks and pages without inducing the disturbance to the unselected pages and blocks to drastically reduce the erase time. The fundamental page circuit of FIG. 15A comprises of the circuit of FIG. 5A.

FIG. 16 prior art, 130, shows two NVM memory blocks comprising of the prior-art hybrid Flotox-based EEPROM and Flotox-based Flash memory arrays within one chip of the present invention. Traditional EEPROM array needs to have one GBL and Byte select transistor for each byte to perform the byte-alterable data storage. With contrast, Flash array does not have GBL and Byte select transistor and it is mainly used for block-alterable code storage. Because of no GBL and Byte select transistor, each byte's pitch of the Flash array is smaller than the EEPROM array. As a result, EEPROM memory density and NOR Flash density are separately fixed for respective memory sizes. Even the page buffer design has to be separated into two for respective EEPROM and Flash memories. There is no flexibility of memory density of respective EEPROM and Flash.

FIG. 17, 132, shows two separate NVM memory blocks and decoders of the hybrid Flotox-based EEPROM and Flotox-based NOR Flash memory arrays within one chip of the present invention. Unlike the traditional EEPROM array, every single byte of each page of NOR Flash array does not need one GBL for byte-alterable data storage as the page of NOR Flash array for the block-alterable code storage.

As a result, the byte pitch of NOR Flash can be kept identical with the byte-pitch of EEPROM of the present invention. Therefore, in the physical array layout, EEPROM and NOR Flash memory can be placed on top of each other with perfect match in x-direction.

Both NOR and EEPROM comprise of a plurality of sectors. Each sector is further comprises of a plurality of pages. And each page is further comprises of a plurality of bytes. Each byte preferably comprises eight vertical BLs and one shared horizontal SL without or with one GBL or comprises of eight vertical BLs and eight vertical SLs without or with one GBL. As a result, the x-pitch of EEPROM array is made identical to the x-pitch of NOR array. Therefore, the flexible memory partition between NOR and EEPROM can be achieved. The defined Vts and FN tunneling schemes for erase. Erase-inhibit, program and program-inhibit operations for three on-chip NVM memories can be flexibly defined respectively to keep the respective desired P/E endurance cycle specs

FIG. 18 shows one exemplary circuit block of X-decoder of hybrid Flotox-based EEPROM and Flash arrays for data and code storages on one chip. There are nine (9) address inputs such as A0-A8 and 512 row outputs of WL[00:511]. The X-decoder has three (3) pre-decoders, X-PRE.

The X-decoder has 3 levels of WL decoding scheme. And the logic of the disclosed X-decoder design allows the selection of flexible number of WLs to be selected for erase operation to save the erase time drastically. The number of WLs to be flexibly selected for erase is set to be 2ⁿ, where n value is set to be 1 to 3 for each block.

FIG. 19A shows one exemplary circuit block of X-PRE decoder of hybrid Flotox-based EEPROM and Flash arrays for data and code storages on one chip. The three inputs are A[0], A[1] and A[2]. The eight (8) outputs are XT[0]-XT[7].

FIG. 19B shows one exemplary logic values to allow the selection of the flexible numbers of WLs or pages. The flexible numbers of WLs or pages are set to be 1, 2, 4 and 8 in each block.

FIG. 20A shows the circuit 1T Flotox-based NOR array of the present invention with FIG. 20B showing the preferable Vt distribution.

It is a preferable 2-poly NMOS NOR array which comprises N+1 pages or rows such as WL0-WLN of the present invention. Each row, WLN, comprises K+1 bits of 1T1b NOR cells that are formed in one row of N+1 paired columns of K+1 columns of BLs such as BL0-BLK and K+1 columns of SLs such as SL0-SLK. The reason to call it 1T1b is because it has no 1T Select transistor connected with 1T storage cell like 2T1b EEPROM cell.

This 1T1b NMOS NOR array of FIG. 20A is used for the purpose of the Page- and block-alterable code storage of the present invention. Unlike the NOR prior art, it is based on the same on-chip Flotox-based EEPROM process that is used to make the conventional 2T1b EEPROM cell and array for the purpose of the byte-alterable Data storage.

Each 1T1b NOR cell has 4 electric terminals such as the Drain node connected to BLK, Gate node connected to WLN, Source node connected to SLK and the Bulk connected to P-substrate, which is always coupled to VSS at all time, regardless of Read, Program and Erase operations.

As like the regular NOR memory array, the common gates of N rows are connected to WL0-WLN which are driven by the row decoders. Similarly, some BLs of BL0-BLK are selectively connected to Sense amplifiers through column decoders which are not shown in FIG. 20A. For 8-bit CPU, then 8 bits out from BL0-BLK are selected during byte-read and byte-write operations. During read operation, all BLs of BL0-BLK are coupled to VSS. The total number of NOR cell bits is (N+1)×(K+1) in FIG. 20A.

FIG. 20B shows the preferable graph of 1T1b NOR's two Vt distributions. Both Vt0 and Vt1 values are preferably set to be positive due to the 1T1b NOR cell has no Select transistor connected in series to prevent BL leakage during read. Thus no negative Vt is allowed in this 1T1b NOR cell array.

The Vt0 values is preferably set to be a narrow distribution between 0.5V to 1.0V along with a wide Vt1 with the minimum value of 3.0V. The WLN voltage is preferably set to be VDD without any boost for 1.8V low-current read operation. The 1.8V VDD gate voltage is set to be right between the maximum of Vt0 of 1.0V and the minimum of Vt1 of 3V. Therefore, the accurate binary read data can be distinguished with sufficient delta Vt margin.

In this 1T1b NOR cell, the erase operation is to increase cell's Vt. In contrast, the program operation is to decrease the cell's Vt as identical to the EEPROM cell's write scheme on the same chip. Both Erase and Program operations are employing low-current FN-channel tunneling schemes, thus a low-current erase and program operations can be performed in unit of page and block.

FIG. 20C shows a preferable set of biased voltage conditions of Erase, Program and Read operations of the Selected and Unselected of the 1T1b Flotox-based NOR cells of the present invention.

As explained above, the Erase operation is to increase the selected NOR cells' Vt to Vt1, while the Program operation is to decrease the selected NOR cells ‘Vt to Vt0. For those unselected NOR cells’ Vt should be inhibited from increasing and decreasing in Vt.

To increase cell's Vt to Vt1, the plurality of electrons have to be attracted to the floating-gate poly1 layer from the NOR cell's channel region at the tunnel-thin-oxide window area. Thus the Selected WL is coupled to the highest positive value of VPP1, along with BL and SL coupling to VSS. The VPP1 is set to a value between +15.0V to +18.0V in today's flotox-based EEPROM technology. The unselected WLs should be coupled to VSS so that the Vts of unselected cells would not be disturbed during the program.

By contrast, the program operation is to decrease the selected 1T1b NOR cells' Vt to Vt0 from Vt1. In this case, the electrons in floating-gate would be expelled to the channel through the tunneling window area. In order to achieve the desired program operation, the selected gates of the cells are coupled to VSS along with channel's voltage biased at VPP1. To set the channel voltage to a value of VPP1, the selected cells' BLs should be set to be VPP1. The gates or WLs of the unselected cells should be coupled to VPP2 with SLs left floating or same voltage to avoid the channel punch-through during the program operation.

In order to have an optimal biased voltage to get the least disturbance to unselected NOR cells in the array, the gates of unselected cells should be set a value of VPP2, which can be set ½ of VPP1 or 6.0V to 10V. Since the VPP2 gate and VPP1 BL difference is almost ½ of VPP1 that is about 7.5V, thus the field is not strong enough to induce the FN tunneling effect. Thus the unselected cells in the unselected pages or rows would not be affected at all after about 1 mS program time.

All unselected BLS and SLs are left floating so that the cells' Vt remains unchanged. During the read operation, the Selected WL voltage is set to be VDD, which is about 1.8V to 3.0V and the selected BLs are set be below 1.0V with selected SLs are set to be VSS.

FIG. 20D shows another set of biased conditions for the selected and unselected Erase, program and read operations as seen in FIG. 20C. The difference in program is to set the unselected BLs' voltage to be VPP2, rather than 0V for the unselected program voltage.

FIG. 20E further shows another set of biased conditions for the selected and unselected Erase, program and read operations as seen in FIG. 20C and FIG. 20D. The difference in program is to set the unselected BLs' voltage to be VPP3, rather than 0V or VPP2 as seen in above two tables for the unselected program voltage. The reason to set VPP3 is to make the least optimal BL and WL disturbances because VPP3 is set to be ½ of VPP2 of value between 3V-5V if VPP2 is 6V-10V.

FIG. 20F shows another preferable set of program, erase and read operations of the 1T1b NOR cell array of the present invention.

The only one difference between FIG. 20F and FIG. 20C is the Program operating conditions. In this new embodiment, the erase operation remains the same as above to use the VPP1 that is the positive voltage but the program operation uses a negative gate voltage of VNN1, which is set to a value between −3.0V to −10V. Normally, −3V to −5V is more preferable to ensure the endurance 1M cycles without making disturbance to the unselected NOR cells' Vt in the selected WL.

Since the gate is biased at VNN rather than VSS, thus the BLs program voltage can be reduced from traditional VPP1 to lower positive value of VPP2, which is around 6V to 10V to induce the identical FN tunneling effect to reduce selected cells' Vt to Vt0 within the predetermined program time of 1 mS. The voltage of the SLs are left floating to avoid the channel punch-through for the selected NOR cells.

FIG. 21A shows the 0.5T Flotox-based NAND array of the present invention. FIG. 21A shows a preferable NAND array that is comprised of a plurality of N+1 NAND strings without a top and a bottom selected transistors as the transitional NAND string. Each string is comprised of N+1 1T1b flotox-based NOR cell of the present invention. Each string has N+1 gates coupled to N+1 WLs such as WL0 to WLN, running in X-axis direction as perpendicular to BLs and SLs.

All NAND string flash cells are formed on top of P-substrate.

Unlike the traditional NAND cell string, the BL and SL of each string are two separate metals running vertically in parallel as the NOR cell array of the present invention. No common SLs laid in X-direction.

The preferable program operation is performed in unit of page progressively from the string bottom to the string top after erasing whole block successfully that causes the cells' Vt to Vt0 as NOR cell.

The advantage without any top and bottom select transistors in each NAND string of the present invention is to get the less string silicon area for cost reduction. But the disadvantage is that the cell's Vt must be limited to only positive values for both Vt0 and Vt1 to avoid the BL leakage induced from the unselected strings in the same selected BLs and SLs.

Another disadvantage is to have a higher BL and SL program stress that will reduce the P/E cycles. But under the Vt leveling technique as used in traditional NAND string array, the NAND string array can still work in a window that can be accepted.

FIG. 21B shows another preferable NAND array which is comprised of a plurality of similar N+1 NAND strings by adding only one top selected transistor, N1k. Similarly, each string is comprised of N+1 1T1b flotox-based NOR cell of the present invention.

Each string has N+1 gates coupled to identical N+1 WLs such as WL0 to WLN as FIG. 21A but the gate of Select transistor is coupled to SGN, which is also running in X-direction. All NAND string flash cells and Selected transistors are formed on the top of common P-substrate.

The advantage with a one top Select transistor is to allow the flash cell's Vt to be negative. So the unselected strings in the NAND array can be shut off by grounding SGK without having any BL leakage during the read operation.

The erase operation can be performed in a block that comprises a plurality of K+1 NAND strings collectively. The program is still preferable to be performed in unit of page and from the string bottom to the string top as proposed in FIG. 21A.

FIG. 21C further shows another embodiment of preferable NAND string that comprised of a plurality of similar N+1 NAND strings by adding only one top and one bottom selected transistors, N1K and N2K. Similarly, each string is comprised of N+1 1T1b flotox-based NOR cell and two NMOS N1K and N2K with gates tied to SG1 and SG2 of the present invention. Both SLs and BLs are also running vertically in y-direction.

The operations of Program, erase and read are similar to the above two embodiments.

FIG. 21C further shows another embodiment of preferable NAND string that comprised of a plurality of similar N+1 NAND strings by adding only one top and one bottom selected transistors, N1K and N2K. Similarly, each string is comprised of N+1 1T1b flotox-based NOR cell and two NMOS N1K and N2K with gates tied to SG1 and SG2 of the present invention. Both SLs and BLs are also running vertically in y-direction.

The operations of Program, erase and read are similar to the above two embodiments.

FIG. 22A shows another embodiment of the NAND string array of the present invention. The NAND string is configured more like the traditional NAND that has a vertical BLs but horizontal common SL without the top and bottom Select transistors. The program, erase and read operation can be the same as above.

The drawback is the punch-through concern in page program operation. The program BL and SL disturbance in each unselected NAND strings. As a result, least P/E cycles would happen in this kind of NAND string array.

FIG. 22B shows a further embodiment of the NAND string array of the present invention. It is configured like the embodiment of FIG. 22a but adding one top Select transistor N1K to each string.

FIG. 22C shows another NAND string but adding one top and one bottom Select transistors, N1K and N2K.

FIG. 23A shows the preferable NAND cell's Vt in NAND string of the present invention. One is Vt0, which is the erased Vt with a negative Vt value below −1.0V, and one preferable programmed Vt with a positive Vt above 0.5V but below 1.0V. The Erase Vt distribution can be wide because it is performed in unit of big block collectively. But the programmed Vt1 is preferably set to be narrower distribution between 0.5V to 1.0V due to it is performed in unit of smaller page size and performed in bit-by-bit which is under the full control of on-chip state-machine design. For those unselected flash cells in the selected string, a Vpass voltage has to be coupled to unselected WLs. In this case, we set to be 1.8V, which is larger then the Vt1 maximum of 1.0V.

In read operation, the gate voltage of selected WLn is set to be 0V, which is the value between the Vt0 negative value and small positive Vt1 above 0.5V but below 1.0V.

FIG. 23B shows the reverse program and erase Vt from FIG. 23A. The erase is set to be the highest Vt above 3.0V.

But the program is to decrease the Vt of the selected flash cells to the desired negative Vt0 and smaller positive Vt1 as shown above. The read selected WL voltage is still set to be 0V and the gate voltage of unselected gates is coupled to the Vpass voltage of 1.8V for easier low 1.8V operation.

FIG. 23C shows the bias conditions for 1^{st} Vt distribution according to FIG. 23A. It uses the negative gate voltage to erase the entire block to negative Vt (<-1V), and then used positive gate voltage to program the selected bits' data to positive Vt (between 0.5 to 1.0V).

In Erase, all the WLs re applied with negative high voltage VNN2 (−15 to −18V) and all the BL are applied with 0V. This causes FN tunneling to extract the electrons from the cells' floating gate to P-substrate thus reduces the cells' Vt.

In Program, the selected WL is applied with positive high voltage VPP1 (15 to 18V). The programming is performed WL by WL sequentially from the bottom WL (near the SL) to the top WL (near the BL). The WL on top of the selected WL (called un-programmed WL) and the SG1 are applied with VPP1 to pass the BL voltage to the selected cell. The selected BL is applied with 0V that causes FN tunneling to inject electrons from the P-substrate to the cell's floating gate thus increases the cells' Vt. The unselected BL is applied with VPP2 (6V to 10V) to reduce the electrical field between the cell's floating gate and P-substrate thus inhibits the FN tunneling happening. All the WLs below the selected WL (called programmed WL because they have been previously programmed by the sequence) are applied with either 0V or VPP3 (3V to 5V) to avoid programming. The reason of using VPP3 is to reduce the electrical field of unselected BL that is applied with VPP2, thus reduce the disturbance of the unselected cells.

In Read, the selected WL is applied with Vread (0V) and the selected BL is applied with <1.0V and the BL is connected to the sensing circuit. If the selected cell's Vt is in erased state (<1.0V), it will be turned on and conduct current, thus ‘on-cell’ state is read. If the selected cell's Vt is in programmed state (0.5 to 1.0V), it will be turned off and ‘off-cell’ state is read. All the other WL are applied with Vpass (1.8V to 5.0V) to make all the other cells on the same string turned on regardless their Vt in erased or programmed state, thus the BL current can be solely determined by the selected cell's Vt.

FIG. 23D shows another bias conditions for 1^{st} Vt distribution according to FIG. 23A. The difference between FIG. 23D and FIG. 23C is the Erase condition. Unlike the FIG. 23C using negative gate voltage in erase, FIG. 23D uses positive voltage only to do erasing, thus no need to generate the on-chip negative voltage.

In Erase, the selected WL is applied with 0V, and the selected BL is applied with positive high voltage VPP1 (15V to 18V). All the WL above the selected WL (i.e. un-programmed WL) and SG1 are applied with VPP1 to pass the BL voltage to the selected cell. This BL high voltage will causes FN tunneling to extract the electrons from the cells' floating gate to the drain-side diffusion of the cell, thus reduces the cells' Vt. All the WLs below the selected WL (i.e. programmed WL) are applied with either 0V or VPP3 (3V to 5V) to avoid erasing and reduce the disturbance.

The Program and Read operations of FIG. 23D are the same as FIG. 23C.

FIG. 23E shows another bias conditions for the 2^{nd} Vt distribution according to FIG. 23B. In this Vt distribution, the erase and program operations are reversed from the 1^{st} Vt distribution of FIG. 23A. The Erase operation is to increase the cell's Vt and the Program operation is to decrease the cell's Vt.

In Erase, all the WL in the selected block are applied with positive high voltage VPP1 (15V to 18V) and all the selected BL are applied with 0V. This causes FN tunneling to inject the electrons from the P-substrate to the cells' floating gate, thus increases the cells' Vt.

In Program, the selected WL is applied with 0V, and the selected BL is applied with positive high voltage VPP1 (15V to 18V). All the WL above the selected WL (i.e. un-programmed WL) and SG1 are applied with VPP1 to pass the BL voltage to the selected cell. This BL high voltage will causes FN tunneling to extract the electrons from the cells' floating gate to the drain-side diffusion of the cell, thus reduces the cells' Vt. On the contrary, the selected BL are applied with VPP2 (6V to 10V) to avoid the programming, while also reduces the disturbance of the cells on the un-programmed WL. All the WLs below the selected WL (i.e. programmed WL) are applied with either 0V to avoid programming.

The Read operation of FIG. 23E is the same as FIG. 23C.

FIG. 23F shows another bias conditions for 2^{nd} Vt distribution according to FIG. 23B. The difference between FIG. 23F and FIG. 23E is the Program condition. Unlike the FIG. 23E using positive voltage in programming only, FIG. 23F uses negative gate voltage to do programming, thus allows lower BL voltage being applied.

In Program, the selected WL is applied with negative high VNN1 (−3V to −10V). Because of the negative gate voltage, the selected BL can be applied with a relatively lower BL voltage VPP2 (6V to 10V). The un-program WL and SG1 are applied with VPP2 to pass the BL voltage to the selected cell. This bias condition will cause FN tunneling to extract the electrons from the cells' floating gate to the drain-side diffusion of the cell, thus reduces the cells' Vt. The unselected BL are applied with 0V to inhibit the program operation.

The Erase and Read operations are the same as FIG. 23E.

FIG. 24 shows a combo flotox-based NOR array that comprises of 1T1b NOR, 2T1b EEPROM and N+2 T NAND string of the present invention. The 1T1b is used to store the page or block-alterable code. The 2T1b is used to store the byte and page alterable Data, which the N+2 T NAND string uses to store the huge block of data.

All three NVMs are using the same flotox-based EEPROM process. Thus three NVMs can be formed on the same IC die for providing the most flexible flotox-based hybrid code and data storage with the highest endurance cycles.

While the invention has been particularly shown and described with reference to the preferred embodiments thereof, it will be understood by those skilled in the art that various changes in form and details may be made without departing from the spirit and scope of the invention.

What is claimed is:

1. A FLOTOX (FT) based 1 T EEPROM NOR cell circuit, comprising:
not more than one high voltage (HV) floating gate FT transistor without requiring a bit-line select transistor, having a gate, a drain and a source, wherein a drain of the FT transistor is connected to a bit line, a source is connected to a source line and a gate is connected to word line;
wherein a bias condition reduces bit line program disturb.

2. The 1 T EEPROM NOR cell of claim 1 formed on top of a P-substrate, one gate of said transistor;
a floating gate underneath said gate, and a tunnelling oxide layer underneath of each of floating gates;
a first Boron-Nitride (BN+) region in the P-substrate connected to the source line; and a second Boron-Nitride (BN+) region in the P-substrate connected to the bit line.

3. A negative gate program to bias for operating a 2T EEPROM cell performed in unit of byte comprising a bit line select (BL-ST) transistor and a floating gate Fowler-Nordheim (FN) transistors, wherein the source of the FN is denoted as source line (SL), the drain of the FN-transistor is denoted as bit line, the gate of the BL-ST is denoted as word-line (WL), and the gate of the FN-transistor is denoted as control gate (CG) with P-substrate tied to ground level:
biasing for Erase operation is performed by applying VPP1 voltage to WL and to CG, floating voltage to SL and 0V to BL;
biasing for Erase inhibit operation is performed by applying VPP1 voltage to WL and to CG, floating voltage to SL and VPP2 voltage to BL;
biasing for Program operation is performed by applying VPP1 voltage to WL, VNN1 voltage to CG, VPP5 voltage to BL, and floating voltage to SL;
biasing for Program inhibit operation is performed by applying VPP1 voltage to WL, VNN1 voltage to CG, and floating voltage to BL and SL; and
biasing for Read operation is performed by applying Vdd voltage to WL, Vread voltage to CG, a voltage smaller than 1.0 V to BL, and 0V to SL;
wherein VPP1=16V, VPP2=8-16V, Vpp5=8-10 V, and Vread=1.8-3.0V.

4. A source line erase-inhibit program to bias for operating a 2T EEPROM cell performed in unit of byte comprising a bit line select (BL-ST) transistor and a floating gate Fowler-Nordheim (FN) transistors, wherein the source of the FN is denoted as source line (SL), the drain of the FN-transistor is denoted as bit line, the gate of the BL-ST is denoted as word-line (WL), and the gate of the FN-transistor is denoted as control gate (CG) with P-substrate tied to ground level:
biasing for Erase operation is performed by applying VPP1 voltage to WL and to CG, floating voltage to BL and 0V to SL;
biasing for Erase inhibit operation is performed by applying VPP1 voltage to WL and to CG, floating voltage to BL and VPP2 voltage to SL;
biasing for Program operation is performed by applying VPP1 voltage to WL, 0V to CG, VPP1 voltage to BL, and floating voltage to SL;
biasing for Program inhibit operation is performed by applying VPP1 voltage to WL, 0V to CG, and floating voltage to BL and SL; and
biasing for Read operation is performed by applying Vdd voltage to WL, Vread voltage to CG, a voltage smaller than 1.0 V to BL, and 0V to SL;
wherein VPP1=16V, VPP2=8-16V, and Vread=1.8-3.0 V.

5. A method to bias for operating a 2T EEPROM cell, wherein preferable program and erase operations are reversed, performed in unit of byte comprising a bit line select (BL-ST) transistor and a floating gate Fowler-Nordheim (FN) transistors, wherein the source of the FN is denoted as source line (SL), the drain of the FN-transistor is denoted as bit line, the gate of the BL-ST is denoted as word-line (WL), and the gate of the FN-transistor is denoted as control gate (CG) with P-substrate tied to ground level:
biasing for Erase operation is performed by applying VPP1 voltage to WL and to BL, floating voltage to SL, and 0V to CG;
biasing for Erase inhibit operation is performed by applying VPP1 voltage to WL, 0V to CG, floating voltage to SL and to BL;
biasing for Program operation is performed by applying VPP1 voltage to WL and to CG, 0V to BL, and floating voltage to SL;
biasing for Program inhibit operation is performed by applying VPP1 voltage to WL and to CG, and VPP2 voltage to BL, and floating voltage to SL; and
biasing for Read operation is performed by applying Vdd voltage to WL, Vread voltage to CG, a voltage smaller than 1.0 V to BL, and 0V to SL;
wherein VPP1=16V, VPP2=8-16V, and Vread=1.8-3.0 V.

6. A bit-erase bias method for operating a 2T EEPROM cell performed in unit of bit comprising a bit line select (BL-ST) transistor and a floating gate Fowler-Nordheim (FN) transistors, wherein the source of the FN is denoted as source line (SL), the drain of the FN-transistor is denoted as bit line, the gate of the BL-ST is denoted as word-line (WL), and the gate of the FN-transistor is denoted as control gate (CG) with P-substrate tied to ground level:
biasing for Erase operation is performed by applying VPP1 voltage to WL and to CG, floating voltage to SL and 0V to BL;
biasing for Erase inhibit operation is performed by applying VPP1 voltage to WL and to CG, floating voltage to SL and VPP2 voltage to BL;
biasing for Program operation is performed by applying VPP1 voltage to WL and to BL, 0V to CG, and floating voltage to SL;
biasing for Program inhibit operation is performed by applying VPP1 voltage to WL, 0V to CG, and floating voltage to SL and to BL; and
biasing for Read operation is performed by applying Vdd voltage to WL, Vread voltage to CG, a voltage smaller than 1.0 V to BL, and 0V to SL;
wherein VPP1=16V, VPP2=8-16V, and Vread=1.8-3.0 V.

7. A two-transistor (2T) FLOTOX-based EEPROM cell array comprising:
a matrix of a plurality of 2T FLOTOX EEPROM cells arranged in word-line circuits, which are arranged in rows and columns, each word line circuit comprising N+1 bytes, wherein each 2T-cell comprises:
a select transistor (ST); and
a floating gate Fowler-Nordheim (FN) transistor having a drain merged with a source of the associated select transistor;
a plurality of bit lines, each bit line associated with one column of the 2T FLOTOX EEPROM cells such that each bit line is connected to the drains of the 2T FLOTOX EEPROM cells of the associated column;
a plurality of vertical common source lines, each common source line is shared by a multitude of pairs of two vertical bytes and is connected to all source nodes of the multitude of the pairs of two vertical bytes represented by the floating gate transistors;
a plurality of word lines, each word line associated with one row of the 2T FLOTOX EEPROM cells and connected to the gates of the select transistors of the associated row of two-transistor FLOTOX EEPROM cells and perpendicular to the bit lines and the source lines;
a plurality of common signal lines, each common signal line associated with one row of the 2T FLOTOX EEPROM cells and connected to the gates of the floating gate transistors of the associated row of two-transistor FLOTOX EEPROM cells and perpendicular to the bit lines and the source lines;
wherein no byte-select transistors and no global bit lines are needed and a whole page of the EEPROM array comprises multiple bytes cascaded in x-direction.

8. The two-transistor (2T) FLOTOX-based EEPROM cell array of claim 7, wherein a method to bias for Erase and Erase-Inhibit conditions in unit of page comprising the select (ST) transistors and the floating gate (FN) transistors, wherein the word lines are denoted by WL, the control gates by CG, the bit lines of a byte having n bytes are denoted as BL[0:n] and the common source lines for vertical bytes are denoted as source line (SL):
biasing for Erase and Erase-inhibit condition for selected page and selected bytes is performed by applying VPP1 voltage to WL and to CG, floating voltage to SL, and 0V to BL;
biasing for Erase and Erase inhibit operation for selected pages and unselected bytes is performed by applying VPP1 voltage to WL and to CG, floating voltage to SL and VPP2 voltage to BL;
biasing for Erase and Erase-inhibit condition for unselected pages and selected bytes is performed by applying VPP3 voltage to WL, floating voltage to SL, and 0V to BL and CG; and
biasing for Erase and Erase-inhibit condition for unselected pages and unselected bytes is performed by applying VPP3 voltage to WL, floating voltage to SL, VPP2 voltage to BL, and 0V to CG;
wherein all the erase-Inhibit voltage are coupled from selected BLs to the channels of selected cells and keep their corresponding SLs floating to prevent the selected cells' channels from punch-through and VPP1 is about 16V, VPP2 is about 8-16 V, and VPP3 is about 0-8V.

9. The two-transistor (2T) FLOTOX-based EEPROM cell array of claim 7, wherein a method to bias for Program and Program-Inhibit conditions in unit of page comprising the select (ST) transistors and the floating gate (FN) transistors, wherein the word lines are denoted by WL, the control gates by CG, the bit lines of a byte having n bytes are denoted as BL[0:n] and the common source lines for vertical bytes are denoted as source line (SL):
biasing for Program and Program-inhibit condition for selected page and selected bytes is performed by applying VPP1 voltage to WL and to BL, floating voltage to SL, and 0V to CG;
biasing for Program and Program-Inhibit operation for selected page and unselected bytes is performed by applying VPP1 voltage to WL, floating voltage to SL and to BL, and 0V to CG;
biasing for Program and Program-Inhibit condition for unselected pages and selected bytes is performed by applying VPP3 voltage to WL, floating voltage to SL, 0V to CG; and VPP1 voltage to BL; and
biasing for Program and Program-Inhibit condition for unselected pages and unselected bytes is performed by applying VPP3 voltage to WL, floating voltage to SL and BL, and 0V to CG;
wherein all the Program-Inhibit voltages are coupled from selected BLs to the channels of selected cells and keep their corresponding SLs floating to prevent the selected cells' channels from punch-through and wherein VPP1 is about 15-18V, and VPP3 is about 0-8V.

10. The two-transistor FLOTOX-EEPROM cell array of claim 7, wherein each page length is increased in x-direction, wherein each page comprises a plurality of sectors, each sector in a page comprising only one common global bit line, one byte select transistor, and all (k+1) bytes of a sector are sharing one vertical source line per byte, wherein the total number of bytes of a page is increased to (K+1)×(N+1).

11. The two-transistor (2T) FLOTOX-based EEPROM cell array of claim 10, wherein a method to bias for Erase and Erase-Inhibit conditions in unit of page comprising the select (ST) transistors and the floating gate (FN) transistors, wherein the word lines are denoted by WL, the global bit lines are denoted as GBL, the bit lines of a byte having n bytes are denoted as BL[0:n] and the common source lines for vertical bytes are denoted as source line (SL):
biasing for Erase and Erase-inhibit condition for selected page and selected bytes in a selected sector is performed by applying VPP1 voltage to WL and to GBL, floating voltage to SL, and 0V to BL;
biasing for Erase and Erase inhibit operation for selected pages and unselected bytes in a selected sector is performed by applying VPP1 voltage to WL and GBL, floating voltage to SL, and VPP2 voltage to BL;
biasing for Erase and Erase-inhibit condition for unselected pages and selected bytes in a selected sector is performed by applying VPP3 voltage to WL, floating voltage to SL, 0V to BL, and VPP1 voltage to GBL;
biasing for Erase and Erase-inhibit condition for unselected pages and unselected bytes in a selected sector is performed by applying VPP3 voltage to WL, floating voltage to SL, and VPP2 voltage to BL, and VPP1 voltage to GBL;
biasing for Erase and Erase-inhibit condition for selected page and unselected bytes in an unselected sector is performed by applying VPP1 voltage to WL, 0V to GBL and to BL, and floating voltage to SL; and
biasing for Erase and Erase-inhibit condition for unselected pages and unselected bytes in an unselected sector is performed by applying VPP3 voltage to WL, floating voltage to SL, and 0V to BL and to GBL;
wherein all the erase-Inhibit voltages are coupled from selected BLs to the channels of selected cells and keep their corresponding SLs floating to prevent the selected cells' channels from punch-through and wherein VPP1 is about 15-18V, VPP2 is about 6-18 V, and VPP3 is about 0-8V.

12. The two-transistor (2T) FLOTOX-based EEPROM cell array of claim 10, wherein a method to bias for Program and Program-Inhibit conditions in unit of page comprising the select (ST) transistors and the floating gate (FN) transistors, wherein the word lines are denoted by WL, the global bitlines are denoted as GBL, the bit lines of a byte having n bytes are denoted as BL[0:n] and the common source lines for vertical bytes are denoted as source line (SL):
biasing for Program and Program Inhibit condition for selected page and selected bytes in a selected sector is performed by applying VPP1 voltage to WL and to BL, floating voltage to SL, and 0V to GBL;
biasing for Program and Program Inhibit condition for selected page and unselected bytes in a selected sector is performed by applying VPP1 voltage to WL, 0V to GBL, and floating voltage to SL and BL;
biasing for Program and Program Inhibit condition for unselected pages and selected bytes in a selected sector is performed by applying 0V to WL and GBL, floating voltage to SL, and VPP1 voltage to BL;
biasing for Program and Program Inhibit condition for unselected pages and unselected bytes in a selected sector is performed by applying 0V to WL and to GBL, and floating voltage to SL and to BL;
biasing for Program and Program Inhibit condition for selected pages and unselected bytes in an unselected sector is performed by applying VPP1 voltage to WL, floating voltage to SL and to BL, and 0V to GBL;
biasing for Program and Program Inhibit condition for unselected pages and unselected bytes in an unselected sector is performed by applying 0V to WL and to GBL, and floating voltage to SL and to BL;
wherein all the Program-Inhibit voltages are coupled from selected BLs to the channels of selected cells and keep their corresponding SLs floating to prevent the selected cells' channels from punch-through and wherein VPP1 is about 15-18V, and VPP3 is about 0-8V.

13. The two-transistor (2T) FLOTOX-based EEPROM cell array of claim 10, wherein instead of shared source lines eight vertical source lines are connected to eight sources of a single byte of eight 2T EEPROM cells.

14. The two-transistor (2T) FLOTOX-based EEPROM cell array of claim 13, wherein a method to bias for Erase and Erase-Inhibit conditions in unit of page comprising the select (ST) transistors and the floating gate (FN) transistors, wherein the word lines are denoted by WL, the global bit lines are denoted as GBL, the bit lines of a byte having n bytes are denoted as BL[0:n] and the common source lines for vertical bytes are denoted as source line (SL):
biasing for Erase and Erase-inhibit condition for selected page and selected bytes in a selected sector is performed by applying VPP1 voltage to WL and to GBL, floating voltage to SL, and 0V to BL;
biasing for Erase and Erase inhibit operation for selected pages and unselected bytes in a selected sector is performed by applying VPP1 voltage to WL and GBL, floating voltage to SL, and VPP2 voltage to BL;
biasing for Erase and Erase-inhibit condition for unselected pages and selected bytes in a selected sector is performed by applying VPP3 voltage to WL, floating voltage to SL, 0V to BL, and VPP1 voltage to GBL;
biasing for Erase and Erase-inhibit condition for unselected pages and unselected bytes in a selected sector is performed by applying VPP3 voltage to WL, floating voltage to SL, and VPP2 voltage to BL, and VPP1 voltage to GBL;
biasing for Erase and Erase-inhibit condition for selected page and unselected bytes in an unselected sector is performed by applying VPP1 voltage to WL, 0V to GBL and to BL, and floating voltage to SL; and
biasing for Erase and Erase-inhibit condition for unselected pages and unselected bytes in an unselected sector is performed by applying VPP3 voltage to WL, floating voltage to SL, and 0V to BL and to GBL;
wherein all the erase-Inhibit voltages are coupled from selected BLs to the channels of selected cells and keep their corresponding SLs floating to prevent the selected cells' channels from punch-through VPP1 is about 15-18V, VPP2 is about 6-18 V, and VPP3 is about 0-8V.

15. The two-transistor (2T) FLOTOX-based EEPROM cell array of claim 13, wherein a method to bias for Program and Program-Inhibit conditions in unit of page comprising the select (ST) transistors and the floating gate (FN) transistors, wherein the word lines are denoted by WL, the global bitlines are denoted as GBL, the bit lines of a byte having n bytes are denoted as BL[0:n] and the common source lines for vertical bytes are denoted as source line (SL):
biasing for Program and Program Inhibit condition for selected page and selected bytes in a selected sector is performed by applying VPP1 voltage to WL and to BL, floating voltage to SL, and 0V to GBL;
biasing for Program and Program Inhibit condition for selected page and unselected bytes in a selected sector is performed by applying VPP1 voltage to WL, 0V to GBL, and floating voltage to SL and BL;
biasing for Program and Program Inhibit condition for unselected pages and selected bytes in a selected sector is performed by applying VPP3 voltage to WL, floating voltage to SL, 0V to GBL, and VPP1 voltage to BL;
biasing for Program and Program Inhibit condition for unselected pages and unselected bytes in a selected sector is performed by applying VPP3 voltage to WL, 0V to GBL, and floating voltage to SL and to BL;
biasing for Program and Program Inhibit condition for selected pages and unselected bytes in an unselected sector is performed by applying VPP1 voltage to WL, floating voltage to SL and to BL, and 0V to GBL;
biasing for Program and Program Inhibit condition for unselected pages and unselected bytes in an unselected sector is performed by applying VPP3 voltage to WL, 0V to GBL, and floating voltage to SL and to BL;
wherein all the Program-Inhibit voltages are coupled from selected BLs to the channels of selected cells and keep their corresponding SLs floating to prevent the selected cells' channels from punch-through and wherein VPP1 is about 15-18V and VPP3 is about 0-8V.

16. The two-transistor FLOTOX-EEPROM cell array of claim 7, wherein each page has (N+1) independent bytes with a layout being cascaded in x-direction in one large page wherein each page length is increased in x-direction, wherein all vertical bytes are sharing one common vertical source line with totally (N+1) independent source lines connected to the common source nodes of all vertical bytes running in Y-direction.

17. The two-transistor (2T) FLOTOX-based EEPROM cell array of claim 16, wherein a method to bias for Erase and Erase-Inhibit conditions in unit of page comprising the select (ST) transistors and the floating gate (FN) transistors, wherein the word lines are denoted by WL, the control gates by CG, the bit lines of a byte having n bytes are denoted as BL[0:n] and the common source lines for vertical bytes are denoted as source line (SL):
biasing for Erase and Erase-inhibit condition for selected page and selected bytes is performed by applying VPP1 voltage to WL and to CG, floating voltage to SL, and 0V to BL;
biasing for Erase and Erase inhibit operation for selected pages and unselected bytes is performed by applying VPP1 voltage to WL and to CG, floating voltage to SL and VPP2 voltage to BL;
biasing for Erase and Erase-inhibit condition for unselected pages and selected bytes is performed by applying VPP3 voltage to WL, floating voltage to SL, and 0V to BL and to CG; and
biasing for Erase and Erase-inhibit condition for unselected pages and unselected bytes is performed by applying VPP3 voltage to WL, floating voltage to SL, VPP2 voltage to BL, and 0V to CG;
wherein all the Erase-Inhibit voltage are coupled from selected BLs to the channels of selected cells and keep their corresponding SLs floating to prevent the selected cells' channels from punch-through and wherein VPP1 is about 16V, VPP2 is about 6-18 V, and VPP3 is about 0-8V.

18. The two-transistor (2T) FLOTOX-based EEPROM cell array of claim 16, wherein a method to bias for Program and Program-Inhibit conditions in unit of page comprising the select (ST) transistors and the floating gate (FN) transistors, wherein the word lines are denoted by WL, the control gates by CG, the bit lines of a byte having n bytes are denoted as BL[0:n] and the common source lines for vertical bytes are denoted as source line (SL):
biasing for Program and Program-inhibit condition for selected page and selected bytes is performed by applying VPP1 voltage to WL, floating voltage to SL, VPP5 voltage to BL, and VNN1 voltage to CG;
biasing for Program and Program-Inhibit operation for selected page and unselected bytes is performed by applying VPP1 voltage to WL, floating voltage to SL and to BL, and VNN1 voltage to CG;
biasing for Program and Program-Inhibit condition for unselected pages and selected bytes is performed by applying VPP3 voltage to WL, floating voltage to SL, 0V to CG; and VPP5 voltage to BL; and
biasing for Program and Program-Inhibit condition for unselected pages and unselected bytes is performed by applying VPP3 voltage to WL, floating voltage to SL and BL, and 0V to CG;
wherein all the Program-Inhibit voltages are coupled from selected BLs to the channels of selected cells and keep their corresponding SLs floating to prevent the selected cells' channels from punch-through and VPP1 is about 16V, VNN1=−1-−8V, VPP5=8V-10V, and VPP3 is about 0-8V.

19. The two-transistor (2T) FLOTOX-based EEPROM cell array of claim 7, wherein a method to bias for Erase and Erase-Inhibit conditions are set to be different for the selected bytes and the unselected bytes on the selected and unselected pages so that the least program and erase disturbance can be achieved, comprising the select (ST) transistors and the floating gate (FN) transistors, wherein the word lines are denoted by WL, the control gates by CG, the bit lines of a byte having n bytes are denoted as BL[0:n] and the common source lines for vertical bytes are denoted as source line (SL):
biasing for Erase and Erase-inhibit condition for selected page and selected bytes is performed by applying VPP1 voltage to WL and to CG, floating voltage to SL, and 0V to BL;
biasing for Erase and Erase inhibit operation for selected pages and unselected bytes is performed by applying VPP1 voltage to WL and to CG, floating voltage to SL and VPP2 voltage to BL;
biasing for Erase and Erase-inhibit condition for unselected pages and selected bytes is performed by applying VPP3 voltage to WL, floating voltage to SL, and 0V to BL and to CG; and
biasing for Erase and Erase-inhibit condition for unselected pages and unselected bytes is performed by applying VPP3 voltage to WL, floating voltage to SL, VPP2 voltage to BL, and 0V to CG;
wherein all the erase-Inhibit voltages are coupled from selected BLs to the channels of selected cells and keep their corresponding SLs floating to prevent the selected cells' channels from punch-through and wherein VPP1 is about 16V, VPP2 is about 6-16 V, and VPP3 is about 0-8V.

20. The two-transistor (2T) FLOTOX-based EEPROM cell array of claim 7, wherein a method to bias for Program and Program-Inhibit conditions of both positive and negative HV combination for the selected byte and the unselected bytes in the same selected WL during the FN program operation, comprising the select (ST) transistors and the floating gate (FN) transistors, wherein the word lines are denoted by WL, the control gates by CG, the bit lines of a byte having n bytes are denoted as BL[0:n] and the common source lines for vertical bytes are denoted as source line (SL):
biasing for Program and Program-inhibit condition for selected page and selected bytes is performed by applying VPP1 voltage to WL, floating voltage to SL, VPP5 voltage to BL, and VNN1 voltage to CG;
biasing for Program and Program-Inhibit operation for selected page and unselected bytes is performed by applying VPP1 voltage to WL, floating voltage to SL and to BL, and VNN1 voltage to CG;
biasing for Program and Program-Inhibit condition for unselected pages and selected bytes is performed by applying VPP3 voltage to WL, floating voltage to SL, 0V to CG; and VPP5 voltage to BL; and
biasing for Program and Program-Inhibit condition for unselected pages and unselected bytes is performed by applying VPP3 voltage to WL, floating voltage to SL and BL, and 0V to CG;
wherein all the Program-inhibit voltages are coupled from selected BLs to the channels of selected cells and keep their corresponding SLs floating to prevent the selected cells' channels from punch-through and wherein VPP1 is about 16V, VNN1=−1-−8V, VPP5=8V-10V, and VPP3 is about 0-8V.

21. The two-transistor (2T) FLOTOX-based EEPROM cell array of claim 7, wherein a method to bias for Erase and Erase-Inhibit conditions in unit of page comprising the select (ST) transistors and the floating gate (FN) transistors, wherein the word lines are denoted by WL, the control gates by CG, the bit lines of a byte having n bytes are denoted as BL[0:n] and the common source lines for vertical bytes are denoted as source line (SL):
biasing for Erase and Erase-inhibit condition for selected page and selected bytes is performed by applying VPP3 voltage to WL, floating voltage to BL, 0V to SL, and VPP1 voltage to CG;
biasing for Erase and Erase inhibit operation for selected pages and unselected bytes is performed by applying VPP3 voltage to WL, VPP1 voltage to CG, floating voltage to BL, and VPP2 voltage to SL;
biasing for Erase and Erase-inhibit condition for unselected pages and selected bytes is performed by applying VPP3 voltage to WL, floating voltage to is BL, 0V to CG and to SL; and
biasing for Erase and Erase-inhibit condition for unselected pages and unselected bytes is performed by applying VPP3 voltage to WL, floating voltage to BL, VPP2 voltage to SL, and 0V to CG;
wherein the Erase-Inhibit voltages are coupled from the selected SLs and the corresponding BLs are left floating to prevent the selected cells' channels from punch-through and wherein VPP1 is about 15-18V, VPP2 is about 6-18 V, and VPP3 is about 0-8V.

22. The two-transistor (2T) FLOTOX-based EEPROM cell array of claim 7, wherein a method to bias for Program and Program-Inhibit conditions in unit of page comprising the select (ST) transistors and the floating gate (FN) transistors, wherein the word lines are denoted by WL, the control gates by CG, the bit lines of a byte having n bytes are denoted as BL[0:n] and the common source lines for vertical bytes are denoted as source line (SL):
biasing for Program and Program-inhibit condition for selected page and selected bytes is performed by applying VPP1 voltage to WL and to BL, floating voltage to SL, and 0V voltage to CG;
biasing for Program and Program-Inhibit operation for selected page and unselected bytes is performed by applying VPP1 voltage to WL, floating voltage to SL and BL, and 0V voltage to CG;
biasing for Program and Program-Inhibit condition for unselected pages and selected bytes is performed by applying VPP3 voltage to WL, floating voltage to SL, 0V to CG; and VPP1 voltage to BL; and
biasing for Program and Program-Inhibit condition for unselected pages and unselected bytes is performed by applying VPP3 voltage to WL, floating voltage to SL and BL, and 0V to CG;
wherein all the Program-Inhibit voltages are coupled from the selected SLs and the corresponding BLs are left floating to prevent the selected cells' channels from punch-through and wherein VPP1 is about 16V and VPP3 is about 0-8V.

23. A two-transistor (2T) FLOTOX-based EEPROM cell array comprising:
a matrix of a plurality of 2T FLOTOX EEPROM cells arranged in word-line circuits, which are arranged in rows and columns, each word line circuit comprising N+1 bytes, each EEPROM cell having one dedicated pair of vertical bit line and common source line connecting to respective drain and source and running perpendicular to WL and CG wherein each 2T-cell comprises:
a select transistor (ST); and
a floating gate Fowler-Nordheim (FN) transistor having a drain merged with a source of the associated select transistor;
said plurality of bit lines, each bit line associated with one column of the 2T FLOTOX EEPROM cells such that each bit line is connected to the drains of the 2T FLOTOX EEPROM cells of the associated column;
a plurality of vertical common source lines, each common source line associated with one column shared of the 2T FLOTOX EEPROM cells such that each source line is connected to the sources of the 2T FLOTOX EEPROM cells of the associated column;
a plurality of word lines, each word line associated with one row of the 2T FLOTOX EEPROM cells and connected to the gates of the select transistors of the associated row of two-transistor FLOTOX EEPROM cells and perpendicular to the bit lines and the source lines;
a plurality of common signal lines, each common signal line associated with one row of the 2T FLOTOX EEPROM cells and connected to the gates of the floating gate transistors of the associated row of two-transistor FLOTOX EEPROM cells and perpendicular to the bit lines and the source lines;
wherein no byte-select transistors and no global bit lines are needed and a whole page of the EEPROM array comprises multiple bytes cascaded in x-direction.

24. The two-transistor (2T) FLOTOX-based EEPROM cell array of claim 23, wherein a method to bias for Erase and Erase-Inhibit conditions in unit of page comprising the select (ST) transistors and the floating gate (FN) transistors, wherein the word lines are denoted by WL, the control gates by CG, the bit lines of a byte having n bytes are denoted as BL[0:n] and the common source lines for vertical bytes are denoted as source line (SL):
biasing for Erase and Erase-inhibit condition for selected page and selected bytes is performed by applying VPP1 voltage to WL and to CG, floating voltage to SL, and 0V to BL;
biasing for Erase and Erase inhibit operation for selected pages and unselected bytes is performed by applying VPP1 voltage to WL and to CG, floating voltage to SL and VPP2 voltage to BL;
biasing for Erase and Erase-inhibit condition for unselected pages and selected bytes is performed by applying VPP3 voltage to WL, floating voltage to SL, and 0V to BL and CG; and
biasing for Erase and Erase-inhibit condition for unselected pages and unselected bytes is performed by applying VPP3 voltage to WL, floating voltage to SL, VPP2 voltage to BL, and 0V to CG;
wherein all the Erase-Inhibit voltages are coupled from selected BLs to the channels of selected cells and keep their corresponding SLs floating to prevent the selected cells' channels from punch-through and wherein VPP1 is about 15-18V, VPP2 is about 6-18 V, and VPP3 is about 0-8V.

25. The two-transistor (2T) FLOTOX-based EEPROM cell array of claim 23, wherein a method to bias for Program and Program-Inhibit conditions in unit of page comprising the select (ST) transistors and the floating gate (FN) transistors, wherein the word lines are denoted by WL, the control gates by CG, the bit lines of a byte having n bytes are denoted as BL[0:n] and the common source lines for vertical bytes are denoted as source line (SL):
biasing for Program and Program-inhibit condition for selected page and selected bytes is performed by applying VPP1 voltage to WL and to BL, VPP4 voltage to SL, and 0V to CG;
biasing for Program and Program-Inhibit operation for selected page and unselected bytes is performed by applying VPP1 voltage to WL, floating voltage to BL, VPP4 voltage to SL, and 0V to CG;
biasing for Program and Program-Inhibit condition for unselected pages and selected bytes is performed by applying VPP3 voltage to WL, VPP4 voltage to SL, 0V to CG, and VPP1 voltage to BL; and
biasing for Program and Program-Inhibit condition for unselected pages and unselected bytes is performed by applying VPP3 voltage to WL, floating voltage to BL, VPP4 voltage to SL, and 0V to CG;
wherein all the Program-Inhibit voltages are coupled from selected BLs to the channels of selected cells and keep their corresponding SLs floating to prevent the selected cells' channels from punch-through and wherein VPP1 is about 15-18V, VPP3 is about 0-8V, and VPP4 is about 0-8V.

26. The two-transistor (2T) FLOTOX-based EEPROM cell array of claim 23, wherein a method to bias for Erase and Erase-Inhibit conditions in unit of page comprising the select (ST) transistors and the floating gate (FN) transistors, wherein the word lines are denoted by WL, the control gates by CG, the bit lines of a byte having n bytes are denoted as BL[0:n] and the common source lines for vertical bytes are denoted as source line (SL):
biasing for Erase and Erase-inhibit condition for selected page and selected bytes is performed by applying VPP3 voltage to WL, floating voltage to BL and SL, and VPP1 voltage to CG;
biasing for Erase and Erase inhibit operation for selected pages and unselected bytes is performed by applying VPP3 voltage to WL, VPP1 voltage to CG, floating voltage to BL, and VPP2 voltage to SL;
biasing for Erase and Erase-inhibit condition for unselected pages and selected bytes is performed by applying VPP3 voltage to WL, floating voltage to BL and SL, and 0V to CG; and
biasing for Erase and Erase-inhibit condition for unselected pages and unselected bytes is performed by applying VPP3 voltage to WL, floating voltage to BL, VPP2 voltage to SL, and 0V to CG;
wherein the Erase-Inhibit voltages are coupled from the selected SLs and the corresponding BLs are left floating to prevent the selected cells' channels from punch-through and wherein VPP1 is about 16V, VPP2 is about 6-16 V, and VPP3 is about 0-8V.

27. The two-transistor (2T) FLOTOX-based EEPROM cell array of claim 23, wherein a method to bias for Program and Program-Inhibit conditions in unit of page comprising the select (ST) transistors and the floating gate (FN) transistors, wherein the word lines are denoted by WL, the control gates by CG, the bit lines of a byte having n bytes are denoted as BL[0:n] and the common source lines for vertical bytes are denoted as source line (SL):
biasing for Program and Program-inhibit condition for selected page and selected bytes is performed by applying VPP1 voltage to WL and to BL, floating voltage to SL, and 0V voltage to CG;
biasing for Program and Program-Inhibit operation for selected page and unselected bytes is performed by applying VPP1 voltage to WL, floating voltage to SL and BL, and 0V voltage to CG;
biasing for Program and Program-Inhibit condition for unselected pages and selected bytes is performed by applying VPP3 voltage to WL, floating voltage to SL, 0V to CG; and VPP1 voltage to BL; and
biasing for Program and Program-Inhibit condition for unselected pages and unselected bytes is performed by applying VPP3 voltage to WL, floating voltage to SL and BL, and 0V to CG;
wherein all the Program-Inhibit voltages are coupled from the selected SLs and the corresponding BLs are left floating to prevent the selected cells' channels from punch-through and wherein VPP1 is about 16V, and VPP3 is about 0-8V.

28. The two-transistor (2T) FLOTOX-based EEPROM cell array of claim 23, wherein a method to bias for Erase and Erase-Inhibit conditions in unit of page comprising the select (ST) transistors and the floating gate (FN) transistors, wherein the word lines are denoted by WL, the control gates by CG, the bit lines of a byte having n bytes are denoted as BL[0:n] and the common source lines for vertical bytes are denoted as source line (SL):
biasing for Erase and Erase-inhibit condition for selected page and selected bytes is performed by applying VPP1 voltage to WL and BL, floating voltage to SL, and 0V to CG;
biasing for Erase and Erase inhibit operation for selected pages and unselected bytes is performed by applying VPP1 voltage to WL, 0V to CG, and floating voltage to SL and to BL;
biasing for Erase and Erase-inhibit condition for unselected pages and selected bytes is performed by applying VPP3 voltage to WL, floating voltage to SL, VPP1 voltage to BL, and 0V to CG; and
biasing for Erase and Erase-inhibit condition for unselected pages and unselected bytes is performed by applying VPP3 voltage to WL, floating voltage to BL and to SL, and 0V to CG;
wherein the Erase-Inhibit voltages are coupled from the selected SLs and the corresponding BLs are left floating to prevent the selected cells' channels from punch-through and wherein VPP1 is about 16V and VPP3 is about 0-8V.

29. The two-transistor (2T) FLOTOX-based EEPROM cell array of claim 23, wherein a method to bias for Program and Program-Inhibit conditions in unit of page comprising the select (ST) transistors and the floating gate (FN) transistors, wherein the word lines are denoted by WL, the control gates by CG, the bit lines of a byte having n bytes are denoted as BL[0:n] and the common source lines for vertical bytes are denoted as source line (SL):
biasing for Program and Program-inhibit condition for selected page and selected bytes is performed by applying VPP1 voltage to WL and to CG, floating voltage to SL, and 0V voltage to BL;
biasing for Program and Program-Inhibit operation for selected page and unselected bytes is performed by applying VPP1 voltage to WL and to CG, floating voltage to SL, and VPP2 voltage to BL;
biasing for Program and Program-Inhibit condition for unselected pages and selected bytes is performed by applying VPP3 voltage to WL, floating voltage to SL, 0V to CG and to BL; and
biasing for Program and Program-Inhibit condition for unselected pages and unselected bytes is performed by applying VPP3 voltage to WL, floating voltage to SL, VPP2 voltage to BL and 0V to CG,
wherein the Program-Inhibit voltages are coupled from the selected SLs and the corresponding BLs are left floating to prevent the selected cells' channels from punch-through and wherein VPP1 is about 16V, VPP2 is about 8-16V, and VPP3 is about 0-8V.

30. The two-transistor (2T) FLOTOX-based EEPROM cell array of claim 23, wherein a method to bias for Erase and Erase-Inhibit conditions in unit of single bit comprising the select (ST) transistors and the floating gate (FN) transistors, wherein the word lines are denoted by WL, the control gates by CG, the bit lines of a byte having n bytes are denoted as BL[0:n] and the common source lines for vertical bytes are denoted as source line (SL):
biasing for Erase and Erase-inhibit condition for selected page and selected bytes is performed by applying VPP1 voltage to WL and to CG, floating voltage to SL, and 0V to BL;
biasing for Erase and Erase inhibit operation for selected pages and unselected bytes is performed by applying VPP1 voltage to WL and CG, VPP2 voltage to BL, and floating voltage to SL;
biasing for Erase and Erase-inhibit condition for unselected pages and selected bytes is performed by applying VPP3 voltage to WL, floating voltage to is SL, and 0V to BL and CG; and
biasing for Erase and Erase-inhibit condition for unselected pages and unselected bytes is performed by applying VPP3 voltage to WL, floating voltage to SL, VPP2 voltage to SL, and 0V to CG;
wherein the Erase-Inhibit voltages are coupled from the selected SLs and the corresponding BLs are left floating to prevent the selected cells' channels from punch-through and wherein VPP1 is about 15-18V, VPP2 is about 6-18V, and VPP3 is about 0-8V.

31. The two-transistor (2T) FLOTOX-based EEPROM cell array of claim 23, wherein a method to bias for Program and Program-Inhibit conditions in unit of bit comprising the select (ST) transistors and the floating gate (FN) transistors, wherein the word lines are denoted by WL, the control gates by CG, the bit lines of a byte having n bytes are denoted as BL[0:n] and the common source lines for vertical bytes are denoted as source line (SL):
biasing for Program and Program-inhibit condition for selected page and selected bytes is performed by applying VPP1 voltage to WL and to BL, floating voltage to SL, and 0V voltage to CG;
biasing for Program and Program-Inhibit operation for selected page and unselected bytes is performed by applying VPP1 voltage to WL, floating voltage to SL and BL, and 0V voltage to CG;
biasing for Program and Program-Inhibit condition for unselected pages and selected bytes is performed by applying VPP3 voltage to WL, floating voltage is to SL, 0V to CG; and VPP1 voltage to BL; and
biasing for Program and Program-Inhibit condition for unselected pages and unselected bytes is performed by applying VPP3 voltage to WL, floating voltage to SL and BL, and 0V to CG;
wherein all the Program-Inhibit voltages are coupled from the selected SLs and the corresponding BLs are left floating to prevent the selected cells' channels from punch-through and wherein VPP1 is about 15-18V and VPP3 is about 0-8V.

32. The two-transistor FLOTOX-EEPROM cell array of claim 7, comprising (K+1) pages arranged in y-direction, each page comprising (N+1) bytes cascaded in x-direction wherein multiple pages can be selected or deselected.

33. The two-transistor (2T) FLOTOX-based EEPROM cell array of claim 32, wherein a method to bias for Erase condition for flexibly erasing the selected [K+1] pages, comprising the select (ST) transistors and the floating gate (FN) transistors, wherein the word lines are denoted by WL, the control gates by CG, the bit lines of a byte having n bytes are denoted as BL[0:n] and the common source lines for vertical bytes are denoted as source line (SL):
biasing for Erase for selected page and selected bytes is performed by applying VPP1 voltage to WL and CG, floating voltage to SL, and 0V to BL;
biasing for Erase for unselected page and selected bytes is performed by applying VPP3 voltage to WL, floating voltage to SL, and 0V to CG and to BL;
wherein VPP1 is about 15-18V and VPP3 is about 0-8V.

34. The two-transistor (2T) FLOTOX-based EEPROM cell array of claim 23, comprising (K+1) pages arranged in y-direction, each page comprising (N+1) bytes cascaded in x-direction wherein multiple pages can be selected or deselected.

35. The two-transistor (2T) FLOTOX-based EEPROM cell array of claim 34, wherein a method to bias for Erase condition for flexibly erasing any number of selected blocks and pages without inducing the disturbance to the unselected pages and blocks to drastically reduce the erase time, comprising the select (ST) transistors and the floating gate (FN) transistors, wherein the word lines are denoted by WL, the control gates by CG, the bit lines of a byte having n bytes are denoted as BL[0:n] and the common source lines for vertical bytes are denoted as source line (SL):
biasing for Erase for selected page and selected bytes is performed by applying VPP1 voltage to WL and CG, floating voltage to SL, and 0V to BL;
biasing for Erase for unselected page and selected bytes is performed by applying VPP3 voltage to WL, floating voltage to SL, and 0V to CG and to BL;
wherein VPP1 is about 15-18V and VPP3 is about 0-8V.

36. A combination of a hybrid FLOTOX-based EEPROM memory and a Flotox-based NOR Flash memory array integrated for data and code storages within one IC chip, wherein the byte pitch of NOR Flash memory can be kept identical with the byte-pitch of EEPROM memory and therefore, in the physical array layout, EEPROM and NOR Flash memory can be placed on top of each other with perfect match in x-direction and wherein every single byte of each page of the NOR flash memory array does not need one GBL for byte-alterable data storage as the page of NOR Flash array for the block-alterable code storage and wherein the combination comprises one common X-decoder and one common page buffer.

37. The combination of a hybrid FLOTOX-based EEPROM memory and a Flotox-based NOR Flash memory array of claim 36 wherein a flexible partition can be implemented between both memory arrays.

38. The combination of a hybrid FLOTOX-based EEPROM memory and a Flotox-based NOR Flash memory array of claim 36 wherein said x-decoder has three level of decoding scheme wherein the logic of the X-decoder design allows the selection of flexible number of word lines to be selected for erase operation to save the erase time drastically wherein the number of word lines can be flexibly selected for erase is set to be 2ⁿ, where n value is set to be 1 to 3 for each block.

39. The combination of a hybrid FLOTOX-based EEPROM memory and a Flotox-based NOR Flash memory array of claim 36 wherein both NOR and EEPROM comprising a plurality of sectors, each sector further comprising a plurality of pages and each page comprising a plurality of bytes, each byte preferably comprising eight vertical BLs and one shared horizontal SL without a global bit line (GBL).

40. The combination of a hybrid FLOTOX-based EEPROM memory and a Flotox-based NOR Flash memory array of claim 36 wherein both NOR and EEPROM comprising a plurality of sectors, each sector further comprising a plurality of pages and each page comprising a plurality of bytes, each byte preferably comprising eight vertical BLs and one shared horizontal SL with a global bit line (GBL).

41. The combination of a hybrid FLOTOX-based EEPROM memory and a Flotox-based NOR Flash memory array of claim 36 wherein both NOR and EEPROM comprising a plurality of sectors, each sector further comprising a plurality of pages and each page comprising a plurality of bytes, each byte preferably comprising eight vertical BLs and eight vertical SLs with a global bit line (GBL).

42. The combination of a hybrid FLOTOX-based EEPROM memory and a Flotox-based NOR Flash memory array of claim 36 wherein both NOR and EEPROM comprising a plurality of sectors, each sector further comprising a plurality of pages and each page comprising a plurality of bytes, each byte preferably comprising eight vertical BLs and eight vertical SLs without a global bit line (GBL).
